(19) United States
(12) Patent Application Publication
(10) Pub. No.: US 2026/0313893 A1
(43) Pub. Date: Oct. 8, 2026

(54) THREE-DIMENSIONAL MEMORY DEVICE WITH OVERLAPPED STAIRCASES AND METHODS FOR FORMING THE SAME

(71) Applicant: Sandisk Technologies, Inc., Milpitas, CA (US)

(72) Inventors: Ruogu Matthew ZHU, San Jose, CA (US); Koichi MATSUNO, Fremont, CA (US); Jixin YU, Milpitas, CA (US); Johann ALSMEIER, San Jose, CA (US)

(21) Appl. No.: 19/173,553

(22) Filed: Apr. 8, 2025

(51) Int. Cl. H10B 43/27; H01L 23/00; H01L 25/065; H01L 25/18; H10B 41/27; H10B 80/00

(52) U.S. Cl. CPC H10B 43/27; H10B 41/27; H10B 80/00; H10W 90/00; H10W 90/792

(57) ABSTRACT

A device structure includes a first alternating stack of first insulating layers and first electrically conductive layers containing a first staircase region extending along a first horizontal direction, a second alternating stack of second insulating layers and second electrically conductive layers located over or under the first alternating stack, the second alternating stack containing a pair of second staircase regions that are laterally separated from each other along a second horizontal direction and extending along the first horizontal direction, first electrically conductive contacts contacting the first electrically conductive layers in the first staircase region, and second electrically conductive contacts contacting the second electrically conductive layers in the second staircase regions. The first staircase region laterally overlaps the pair of second staircase regions along the first horizontal direction, and the first staircase region is laterally offset from the pair of second staircase regions along the second horizontal direction.

### FIELD

The present disclosure relates generally to the field of semiconductor devices, and particularly to a three-dimensional memory device including overlapped staircases and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises a first alternating stack of first insulating layers and first electrically conductive layers comprising a first staircase region comprising a first row of stepped surfaces extending along a first horizontal direction and comprising first horizontal surface segments separated by first vertical surface segments, and a second alternating stack of second insulating layers and second electrically conductive layers located over or under the first alternating stack, the second alternating stack comprising a pair of second staircase regions that are laterally separated from each other along a second horizontal direction perpendicular to the first horizontal direction by a bridge region, wherein each of the second staircase regions comprise a second row of stepped surfaces extending along the first horizontal direction and comprising second horizontal surface segments separated by second vertical surface segments. First electrically conductive contacts contact the first electrically conductive layers in the first staircase region, and second electrically conductive contacts contact the second electrically conductive layers in the second staircase region. The first staircase region laterally overlaps the pair of second staircase regions along the first horizontal direction, the first staircase region is laterally offset from the pair of second staircase regions along the second horizontal direction, and the first staircase region is located above or below the bridge region of the second alternating stack.

According to another aspect of the present disclosure, a method of forming a device structure comprises: forming a first-tier structure including a first-tier alternating stack of first-tier insulating layers and first-tier sacrificial material layers embedding a first-tier retro-stepped dielectric material portion; forming a second-tier structure including a second-tier alternating stack of second-tier insulating layers and second-tier sacrificial material layers embedding a second-tier retro-stepped dielectric material portion; forming a first sacrificial through-via structure through the second-tier alternating stack and through the first-tier retro-stepped dielectric material portion and through a subset of the first-tier sacrificial material layers; forming a second sacrificial through-via structure through the first-tier alternating stack and through the second-tier retro-stepped dielectric material portion and through a subset of the second-tier sacrificial material layers; replacing the first-tier sacrificial material layers and the second-tier sacrificial material layers with first-tier electrically conductive layers and second-tier electrically conductive layers, respectively; and replacing the first sacrificial through-via structure and the second sacrificial through-via structure with a first through-via contact structure and a second through-via contact structure, respectively, wherein the first through-via contact structure is electrically connected to a first electrically conductive layer that replaces a topmost first-tier sacrificial material layer within the subset of the first-tier sacrificial material layers, and the second through-via contact structure is electrically connected to a second electrically conductive layer that replaces a topmost second-tier sacrificial material layer within the subset of the second-tier sacrificial material layers.

### BRIEF DESCRIPTION OF THE DRAWINGS

FIG. 1 is a vertical cross-sectional view of a first exemplary structure for forming a semiconductor die after formation of a vertically alternating sequence of first-tier continuous insulating layers and first-tier continuous sacrificial material layers according to an embodiment of the present disclosure.

FIG. 2A is a first vertical cross-sectional view of the first exemplary structure after formation of first-tier stepped cavities according to an embodiment of the present disclosure. FIG. 2B is a second vertical cross-sectional view of the first exemplary structure along the vertical plane B-B′ of FIG. 2A. The vertical plane A-A′ is the cut plane of the vertical cross-sectional view of FIG. 2A. FIG. 2C is a third vertical cross-sectional view of the first exemplary structure along the vertical plane C-C′ of FIG. 2B. FIG. 2F is a fourth vertical cross-sectional view of the first exemplary structure along the vertical plane D-D′ of FIGS. 2A and 2C. The vertical plane A-A′ is the cut plane of the first vertical cross-sectional view of FIG. 2A. The vertical plane C-C′ is the cut plane of the third vertical cross-sectional view of FIG. 2C. FIG. 2E is a top-down view of the first exemplary structure of FIG. 2A-2D.

FIGS. 3A-3C are sequential vertical cross-sectional views of a region of the first exemplary structure during thickening of physically-exposed portions of the first-tier sacrificial material layers according to an embodiment of the present disclosure.

FIG. 4A-4E are sequential vertical cross-sectional views of a region of the first exemplary structure during a sequence of processing steps that may be employed to locally thicken the physically-exposed portions of the first-tier sacrificial material layers according to an embodiment of the present disclosure.

FIG. 5A is a first vertical cross-sectional view of the first exemplary structure after formation of first-tier retro-stepped dielectric material portions according to an embodiment of the present disclosure. FIG. 5B is a second vertical cross-sectional view of the first exemplary structure along the vertical plane B-B′ of FIG. 5A. The vertical plane A-A′ is the cut plane of the vertical cross-sectional view of FIG. 5A. FIG. 5C is a third vertical cross-sectional view of the first exemplary structure along the vertical plane C-C′ of FIG. 5B. FIG. 5D is a fourth vertical cross-sectional view of the first exemplary structure along the vertical plane D-D′ of FIGS. 5A and 5C. The vertical plane A-A′ is the cut plane of the first vertical cross-sectional view of FIG. 5A. The vertical plane C-C′ is the cut plane of the third vertical cross-sectional view of FIG. 5C. FIG. 5E is a top-down view of the first exemplary structure of FIG. 5A-5D.

FIG. 6A is a first vertical cross-sectional view of the first exemplary structure after formation of various first-tier openings and various first-tier sacrificial opening fill structures according to an embodiment of the present disclosure. FIG. 6B is a second vertical cross-sectional view of the first exemplary structure along the vertical plane B-B′ of FIG. 6A. The vertical plane A-A′ is the cut plane of the vertical cross-sectional view of FIG. 6A. FIG. 6C is a third vertical cross-sectional view of the first exemplary structure along the vertical plane C C′ of FIG. 6B. FIG. 6D is a fourth vertical cross-sectional view of the first exemplary structure along the vertical plane D-D′ of FIGS. 6A and 6C. The vertical plane A-A′ is the cut plane of the first vertical cross-sectional view of FIG. 6A. The vertical plane C-C′ is the cut plane of the third vertical cross-sectional view of FIG. 6C. FIG. 6E is a top-down view of the first exemplary structure of FIG. 6A-6D.

FIG. 7A is a first vertical cross-sectional view of the first exemplary structure after formation of a vertically alternating sequence of second-tier continuous insulating layers and second-tier continuous sacrificial material layers, second-tier retro-stepped dielectric material portions, and various second-tier openings and various second-tier sacrificial opening fill structures according to an embodiment of the present disclosure. FIG. 7B is a second vertical cross-sectional view of the first exemplary structure along the vertical plane B-B′ of FIG. 7A. The vertical plane A-A′ is the cut plane of the vertical cross-sectional view of FIG. 7A. FIG. 7C is a third vertical cross-sectional view of the first exemplary structure along the vertical plane C-C′ of FIG. 7B. FIG. 7D is a fourth vertical cross-sectional view of the first exemplary structure along the vertical plane D-D′ of FIGS. 7A and 7C. The vertical plane A-A′ is the cut plane of the first vertical cross-sectional view of FIG. 7A. The vertical plane C-C′ is the cut plane of the third vertical cross-sectional view of FIG. 7C. FIG. 7E is a top-down view of the first exemplary structure of FIG. 7A-7D.

FIGS. 8A-8E are sequential vertical cross-sectional views of a region of the first exemplary structure during a sequence of processing steps that may be employed to locally thicken the physically-exposed portions of the second-tier sacrificial material layers according to an embodiment of the present disclosure.

FIG. 9A is a first vertical cross-sectional view of the first exemplary structure after formation of a vertically alternating sequence of third-tier continuous insulating layers and third-tier continuous sacrificial material layers, third-tier retro-stepped dielectric material portions, and various third-tier openings and various third-tier sacrificial opening fill structures according to an embodiment of the present disclosure. FIG. 9B is a second vertical cross-sectional view of the first exemplary structure along the vertical plane B-B′ of FIG. 9A. The vertical plane A-A′ is the cut plane of the vertical cross-sectional view of FIG. 9A. FIG. 9C is a third vertical cross-sectional view of the first exemplary structure along the vertical plane C-C′ of FIG. 9B. FIG. 9D is a fourth vertical cross-sectional view of the first exemplary structure along the vertical plane D-D′ of FIGS. 9A and 9C. The vertical plane A-A′ is the cut plane of the first vertical cross-sectional view of FIG. 9A. The vertical plane C-C′ is the cut plane of the third vertical cross-sectional view of FIG. 9C. FIG. 9E is a top-down view of the first exemplary structure of FIGS. 9A-9D.

FIG. 10 is a vertical cross-sectional view of the first exemplary structure after formation of memory openings according to an embodiment of the present disclosure.

FIG. 11A-11F illustrate sequential vertical cross-sectional views of a memory opening during formation of a memory opening fill structure according to an embodiment of the present disclosure.

FIG. 12 is a vertical cross-sectional view of the first exemplary structure after formation of memory opening fill structures according to an embodiment of the present disclosure.

FIG. 13A is a first vertical cross-sectional view of the first exemplary structure after formation of a contact-level dielectric layer and connection cavities according to an embodiment of the present disclosure. FIG. 13B is a second vertical cross-sectional view of the first exemplary structure along the vertical plane B-B′ of FIG. 13A. The vertical plane A-A′ is the cut plane of the vertical cross-sectional view of FIG. 13A.

FIG. 14 is a vertical cross-sectional view of the first exemplary structure after formation of contact via cavities according to an embodiment of the present disclosure.

FIG. 15 is a vertical cross-sectional view of the first exemplary structure after formation of annular lateral recesses around the contact via cavities according to an embodiment of the present disclosure.

FIG. 16 is a vertical cross-sectional view of the first exemplary structure after formation of annular dielectric spacers in a subset of the annular lateral recesses according to an embodiment of the present disclosure.

FIG. 17 is a vertical cross-sectional view of the first exemplary structure after formation of sacrificial through-via structures according to an embodiment of the present disclosure.

FIG. 18A is a vertical cross-sectional view of the first exemplary structure after formation of lateral isolation trenches according to an embodiment of the present disclosure. FIG. 18B is a top-down view of the first exemplary structure of FIG. 18A.

FIG. 19 is a vertical cross-sectional view of the first exemplary structure after formation of lateral recesses according to an embodiment of the present disclosure.

FIG. 20 is a vertical cross-sectional view of the first exemplary structure after formation of electrically conductive layers according to an embodiment of the present disclosure.

FIG. 21A is a vertical cross-sectional view of the first exemplary structure after formation of lateral isolation trench fill structures according to an embodiment of the present disclosure. FIG. 21B is a top-down view of the first exemplary structure of FIG. 21A. The vertical plane A-A′ is the cut plane of the vertical cross-sectional view of FIG. 21A.

FIG. 22 is a vertical cross-sectional view of the first exemplary structure after removal of the sacrificial through-via structures according to an embodiment of the present disclosure.

FIG. 23A is a vertical cross-sectional view of the first exemplary structure after formation of through-via contact structures according to an embodiment of the present disclosure. FIG. 23B is a top-down view of the first exemplary structure of FIG. 23A. The vertical plane A-A′ is the cut plane of the vertical cross-sectional view of FIG. 23A.

FIG. 24A is a first vertical cross-sectional view of the first exemplary structure after formation of drain contact via structures according to an embodiment of the present disclosure. FIG. 24B is a second vertical cross-sectional view of the first exemplary structure along the vertical plane B-B′ of FIG. 24A. The vertical plane A-A′ is the cut plane of the vertical cross-sectional view of FIG. 24A. FIG. 24C is a third vertical cross-sectional view of the first exemplary structure along the vertical plane C-C′ of FIG. 24B. FIG. 24D is a fourth vertical cross-sectional view of the first exemplary structure along the vertical plane D-D′ of FIGS. 24A and 24C. The vertical plane A-A′ is the cut plane of the first vertical cross-sectional view of FIG. 24A. The vertical plane C-C′ is the cut plane of the third vertical cross-sectional view of FIG. 24C. FIG. 24E is a top-down view of the first exemplary structure of FIGS. 24A-24D.

FIG. 25 is a schematic vertical cross-sectional view of the first exemplary structure after formation of a memory die, bonding of the memory die to a logic die, removal of the carrier substrate, and formation of source-side structures according to an embodiment of the present disclosure.

FIG. 26A is a first vertical cross-sectional view of a second exemplary structure after formation of drain contact via structures according to an embodiment of the present disclosure. FIG. 26B is a second vertical cross-sectional view of the second exemplary structure along the vertical plane B-B′ of FIG. 26A. The vertical plane A-A′ is the cut plane of the vertical cross-sectional view of FIG. 26A. FIG. 26C is a third vertical cross-sectional view of the second exemplary structure along the vertical plane C-C′ of FIG. 26B. FIG. 26D is a fourth vertical cross-sectional view of the second exemplary structure along the vertical plane D-D′ of FIGS. 26A and 26C. The vertical plane A-A′ is the cut plane of the first vertical cross-sectional view of FIG. 26A. The vertical plane C-C′ is the cut plane of the third vertical cross-sectional view of FIG. 26C. FIG. 26E is a top-down view of the first exemplary structure of FIGS. 26A-26D.

FIG. 27A is a first vertical cross-sectional view of a third exemplary structure after formation of drain contact via structures according to an embodiment of the present disclosure. FIG. 27B is a second vertical cross-sectional view of the second exemplary structure along the vertical plane B-B′ of FIG. 27A. The vertical plane A-A′ is the cut plane of the vertical cross-sectional view of FIG. 27A. FIG. 27C is a third vertical cross-sectional view of the third exemplary structure along the vertical plane C-C′ of FIG. 27B. FIG. 27D is a fourth vertical cross-sectional view of the third exemplary structure along the vertical plane D-D′ of FIGS. 27A and 27C. The vertical plane A-A′ is the cut plane of the first vertical cross-sectional view of FIG. 27A. The vertical plane C-C′ is the cut plane of the third vertical cross-sectional view of FIG. 27C. FIG. 27E is a top-down view of the third exemplary structure of FIGS. 27A-27D.

FIG. 28 is a vertical cross-sectional view of a fourth exemplary structure according to an embodiment of the present disclosure.

### DETAILED DESCRIPTION

As discussed above, embodiments of the present disclosure are directed to a three-dimensional memory device including vertically overlapped staircases in different tiers and contact via structures which contact the electrically conductive layers in the overlapped staircases, and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a “first-tier level” refers to the level that is most proximal to a growth substrate, a “second-tier level” refers to the level that is most proximal to the growth substrate of the levels that overlie the first-tier level, and a “third-tier level” refers to the level that is most proximal to the growth substrate of the levels that overlie the second-tier level, etc. A “first-tier” element refers to an element that is located within the first-tier level, a “second-tier” element refers to an element that is located within the second-tier level, a “third-tier” element refers to an element that is located within the second-tier level, etc. As used herein, a “memory level” or a “memory array level” refers to the level corresponding to a general region between a first horizontal plane (i.e., a plane parallel to the top surface of the growth substrate) including topmost surfaces of an array of memory elements and a second horizontal plane including bottommost surfaces of the array of memory elements. As used herein, a “through-stack” element refers to an element that vertically extends through a memory level.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

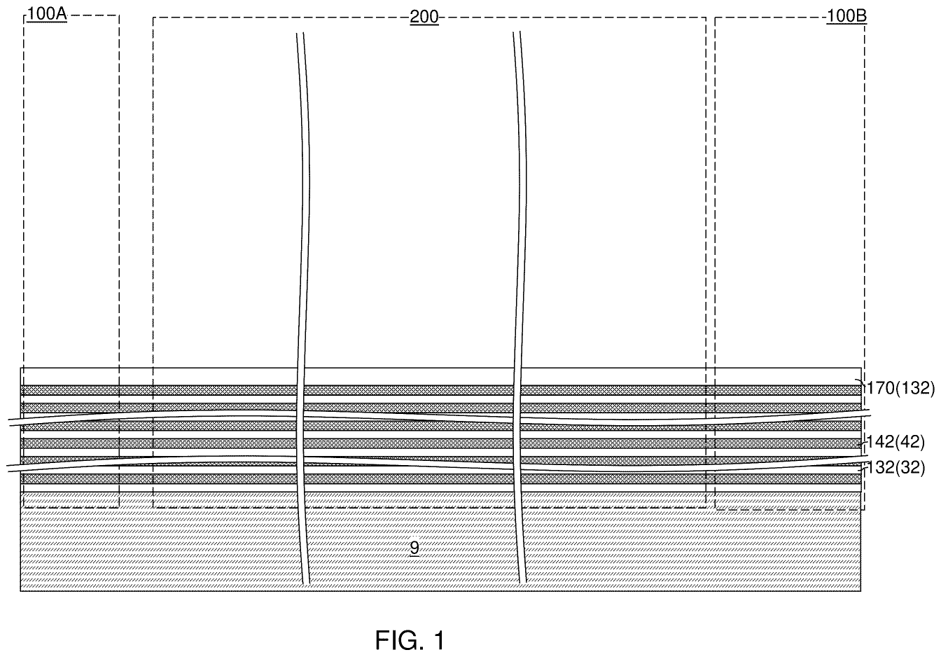

Referring to FIG. 1, a first exemplary structure according to an embodiment of the present disclosure is illustrated, which can be employed to form a two-dimensional array of memory dies formed on a substrate 9. The substrate 9 may be a commercially available wafer such as a silicon wafer. Alternatively, the substrate 9 may comprise another suitable material.

A first vertically alternating sequence of first-tier insulating layers 132 and first-tier sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. The first vertically alternating sequence of first-tier insulating layers 132 and first-tier sacrificial material layers 142 is also referred to as a first-tier alternating stack (132, 142). Generally, the first-tier insulating layers 132 are a first subset of insulating layers 32 to be formed in the first exemplary structure, and the first-tier sacrificial material layers 142 are a first subset of sacrificial material layers 42 to be formed in the first exemplary structure. As such, the first-tier alternating stack (132, 142) is one of alternating stacks (32, 42) that are formed in the first exemplary structure.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the substrate 9, and may have a uniform thickness throughout. Each of the first-tier sacrificial material layers 142 includes a sacrificial material (which may comprise a dielectric material), and continuously extends over the entire area of the substrate 9, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide. The topmost first-tier insulating layer 132 is herein referred to as a first-tier insulating cap layer 170.

The second material of the first-tier sacrificial material layers 142 is a dielectric material, which is a sacrificial material that may be removed selectively to the first material of the first-tier insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may comprise silicon nitride.

Generally, a vertically alternating sequence of unit layer stacks over a substrate. Each of the unit layer stacks comprises a first-tier insulating layer (such as a first-tier insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted. The first exemplary structure comprises a pair of memory array regions (100A, 100B) and a contact region 200 located between the pair of memory array regions (100A, 100B). The pair of memory regions (100A, 100B) may comprise a first memory array region 100A and a second memory array region 100B.

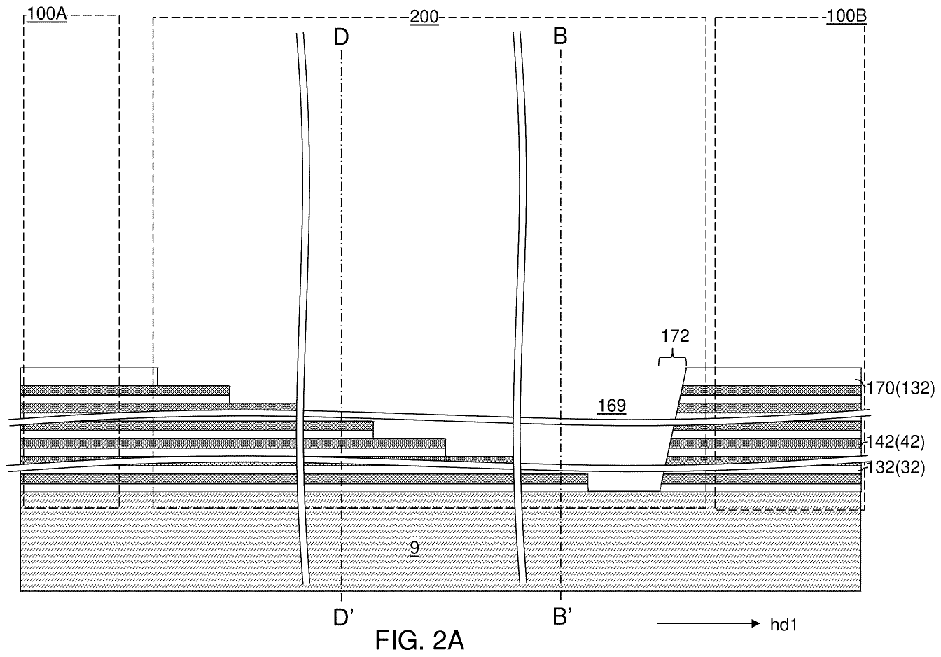

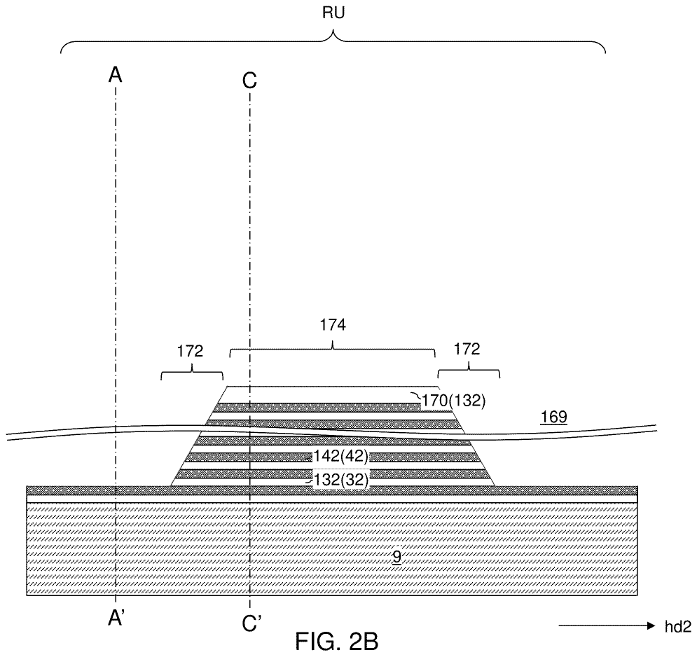

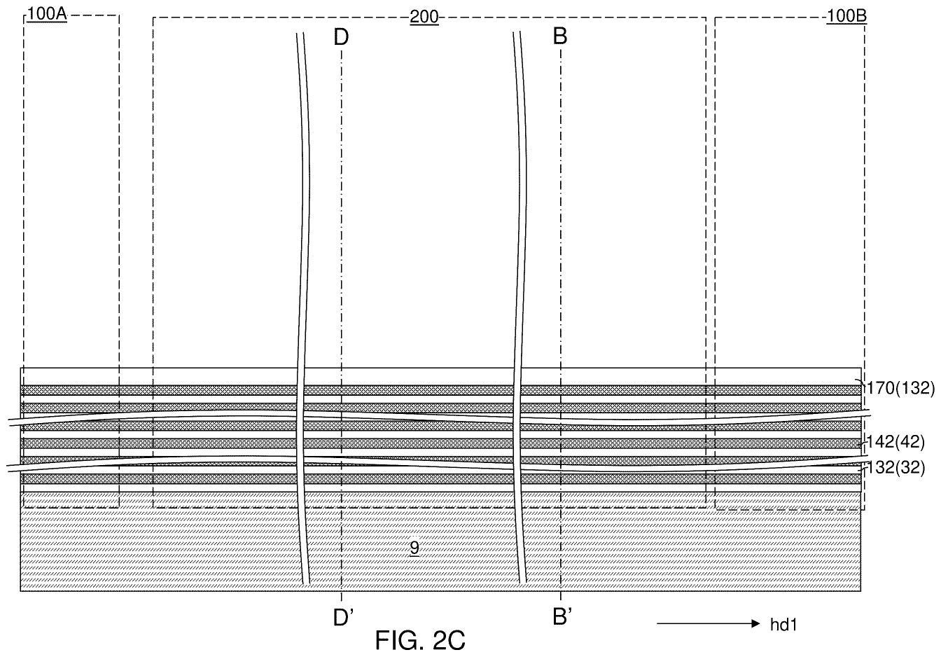

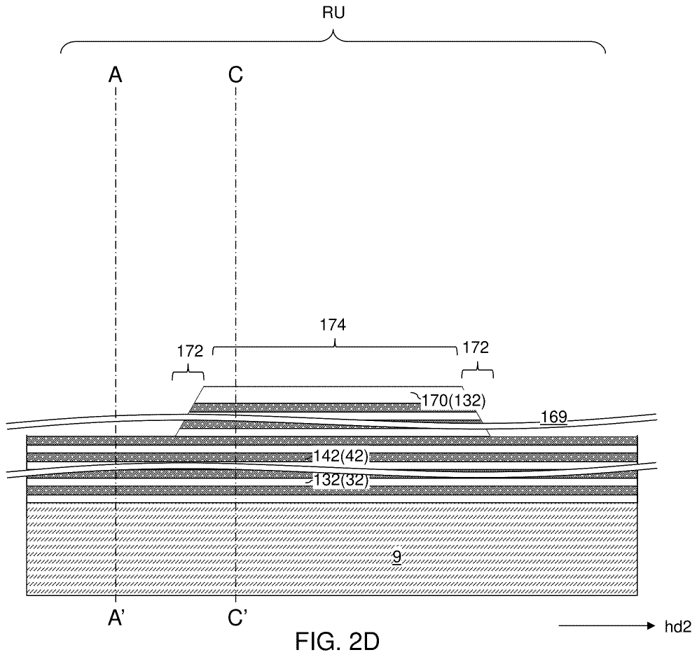

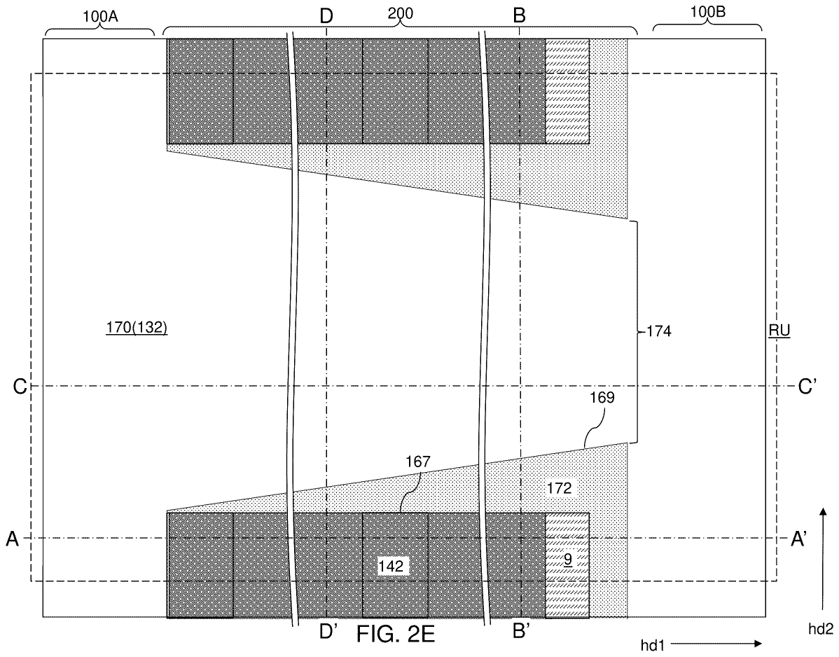

Referring to FIG. 2A-2E, first-tier stepped cavities 169 can be formed through the first-tier alternating stack (132, 142). The first-tier stepped cavities 169 can be formed in a periodic pattern within the area of the contact region 200. For example, the first memory array region 100A and the second memory array region 100B may be laterally spaced apart from each other along a first horizontal direction (e.g., word line direction) hd1. The contact region 200 may be located between the first memory array region 100A and the second memory array region 100B. The first-tier stepped cavities 169 may be laterally spaced apart along a second horizontal direction (e.g., bit line direction) hd2 that is perpendicular to the first horizontal direction hd1. In one embodiment, the first-tier stepped cavities 169 may be formed as a periodic one-dimensional array of first-tier stepped cavities 169 arranged along the second horizontal direction hd2. In this case, the pattern of the first-tier stepped cavities 169 may be a periodic repetition of a unit pattern located within a repetition unit RU. In the illustrated example, each repetition unit RU laterally extends along the first horizontal direction hd1 through the entirety of the first memory array region 100A (of which only an edge portion is illustrated), the entirety of the second memory array region 100B (of which only an edge portion is illustrated), and the contact region 200. The width of the repetition unit RU may be the same as the periodicity of the periodic one-dimensional array of first-tier stepped cavities 169. Generally, each repetition unit RU may be defined as a rectangular area having a lengthwise edge that is parallel to the first horizontal direction hd1 at any location. In the illustrated example, each repetition unit RU is defined to have lengthwise edges that coincide with two mirror symmetry vertical planes for a neighboring pair of first-tier stepped cavities 169 along the first horizontal direction hd1. In this case, each of the two mirror symmetry vertical planes extends through a respective one of the first-tier stepped cavities 169.

Generally, first-tier stepped surfaces can be formed within the first-tier stepped cavities 169 of the contact region 200 by patterning the first vertically alternating sequence (132, 142). For example, a combination of a sacrificial hard mask layer and a trimming mask layer may be employed to form the first stepped surfaces. Each first-tier stepped cavity 169 comprises a respective contiguous set of stepped surfaces of the first vertically alternating sequence (132, 142). The stepped surfaces comprise horizontal surface segments separated by vertical surface segments. The lateral extents of the first-tier sacrificial material layers 142 vary with a vertical distance from the substrate 9 in each first-tier stepped cavity 169. Each of the first-tier sacrificial material layers 142 has a respective physically exposed horizontal top surface segment within each first-tier stepped cavity 169. The lateral extent of the physically exposed top surface segments of the first-tier sacrificial material layers 142 along the first horizontal direction hd1 may be evenly divided among all of the first-tier sacrificial material layers 142. For example, if the total number of the first-tier sacrificial material layers 142 is N1, the horizontal length of the physically exposed portion of the physically exposed top surface segment of each first-tier sacrificial material layer 142 may be 1/N1 times a total stepped surface length, which may be in a range from 0.90 times the lateral spacing between the first memory array region 100A and the second memory array region 100B to 0.9999 times the lateral spacing between the first memory array region 100A and the second memory array region 100B.

The sidewalls of each first-tier staircase region 169 may be tapered. The area in which the physically exposed horizontal surface segments of the first-tier stepped surfaces of a first-tier stepped cavity 169 is located within a plan view is herein referred to as a first-tier stepped surface area (i.e., first-tier staircase region) 167. In one embodiment, each first-tier stepped surface area 167 may have a rectangular shape, and the opening in the first-tier insulating cap layer 170 may have a shape of a trapezoid having a greater width for a side proximal to a physically exposed top surface segment of the bottommost first-tier sacrificial material layer 142 than for a side that is distal from the physically exposed top surface segment of the bottommost first-tier sacrificial material layer 142. The tapered surfaces of the alternating stack (132, 142) in the first-tier stepped cavity 169 are referred to as a first-tier dummy staircase region 172. The region of the alternating stack (132, 142) extending in the second horizontal direction hd2 between adjacent first-tier stepped cavities 169 is referred to as a first-tier bridge region 174.

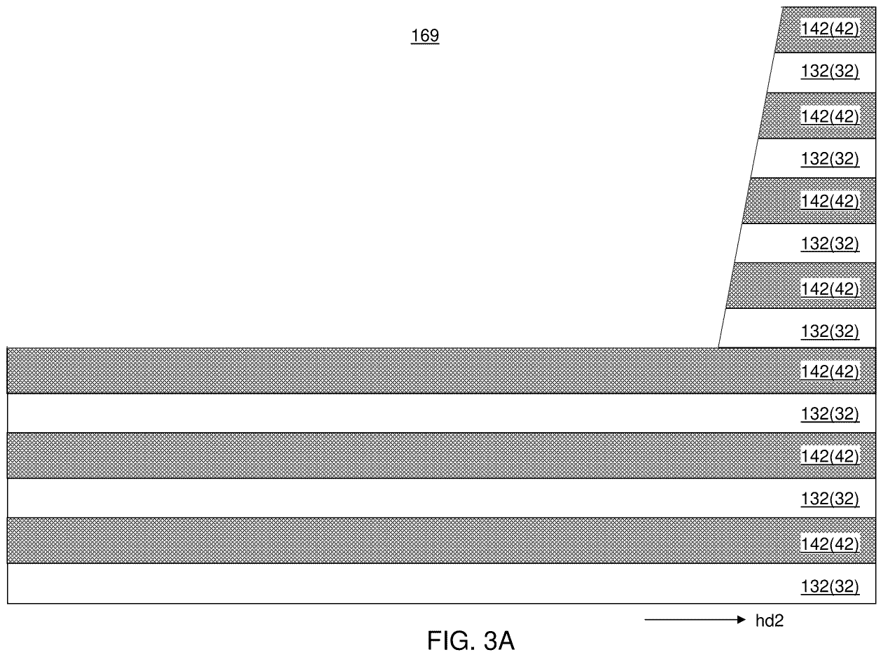

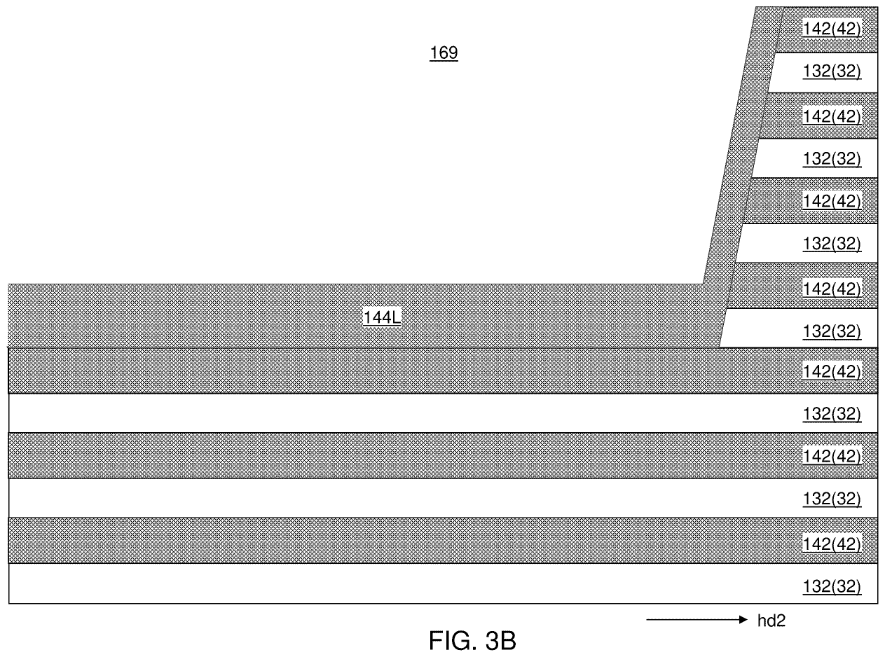

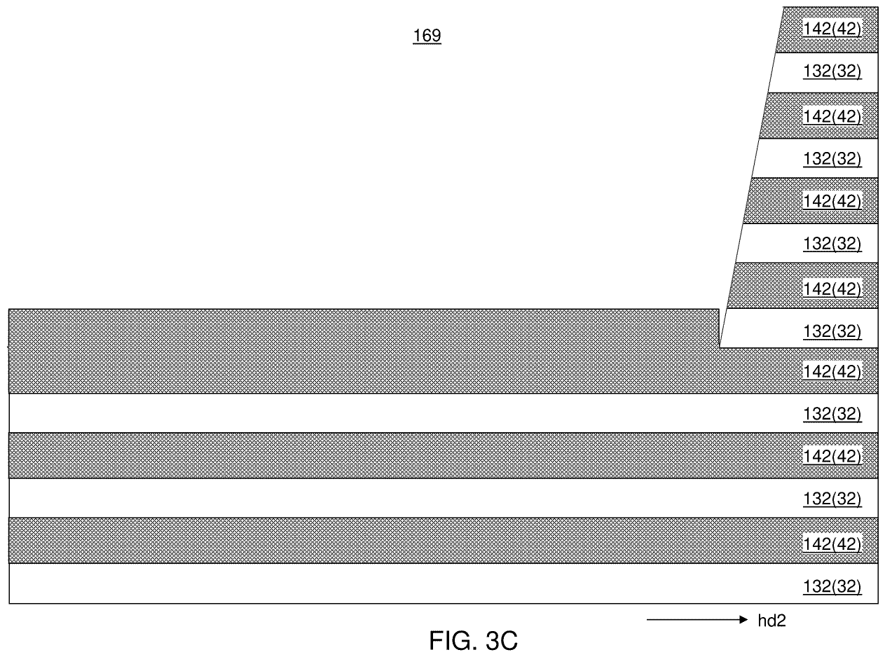

FIGS. 3A-3C are sequential vertical cross-sectional views of a region of the first exemplary structure during thickening of physically-exposed portions of the first-tier sacrificial material layers according to an embodiment of the present disclosure.

Referring to FIG. 3A, an anisotropic material deposition process can be performed to anisotropically deposit a same material as the material of the first-tier sacrificial material layers 142 to form a non-conformal sacrificial material layer 144L. In one embodiment, the first-tier sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50 % to 300 % of the thickness of each first-tier sacrificial material layer 142.

Referring to FIG. 3B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier sacrificial material layers 142 can be incorporated into the respective one of the first-tier sacrificial material layers 142.

Thus, physically-exposed portions of the sacrificial material layers 42 (such as the first-tier sacrificial material layers 142) in the staircase region can be thickened such that the thickened portions of the sacrificial material layers 142 has a thickness in a range from 125 % to 250 %, such as from 150 % to 200 %, of the unthickened portion of the first-tier sacrificial material layers 142 (which is the same as the original thickness of each first-tier sacrificial material layers 142). While an embodiment is described in which physically exposed portions of the first-tier sacrificial material layers 142 are locally thickened by anisotropic deposition and isotropic etch-back of a sacrificial material, the physically exposed portions of the first-tier sacrificial material layers 142 may be locally thickened by alternative methods that can selectively increase the thickness of physically exposed portions of the first-tier sacrificial material layers 142.

Referring to FIG. 3C, portions of the non-conformal sacrificial material layer 144L that are deposited outside the areas of the first-tier stepped cavities 169 can be removed, for example, by covering the areas of the first-tier stepped cavities 169 with patterned photoresist materials without covering sidewalls of the first-tier stepped cavities 169, and by performing an etch process that etches unmasked portions of the material of the non-conformal sacrificial material layer 144L. Physically exposed portions of the first-tier sacrificial material layers 142 may be locally thickened within the first-tier stepped cavities 169.

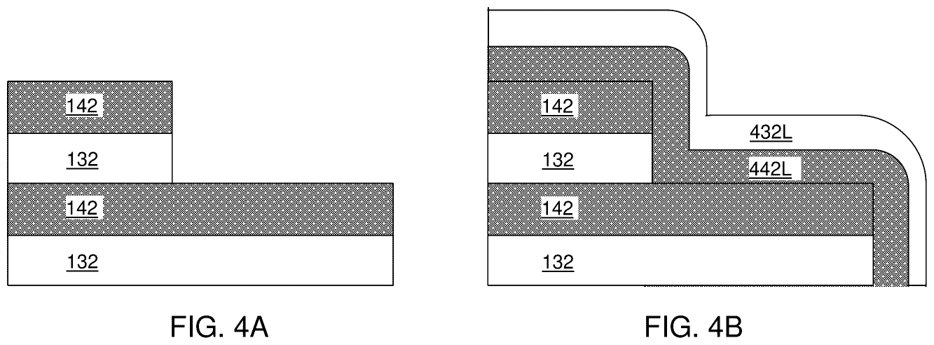

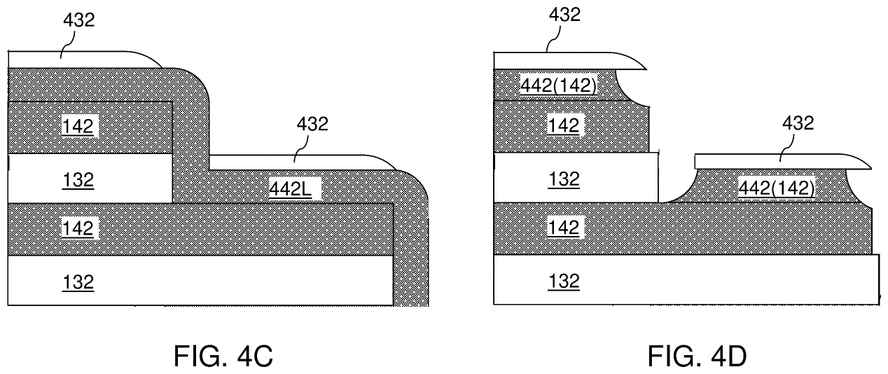

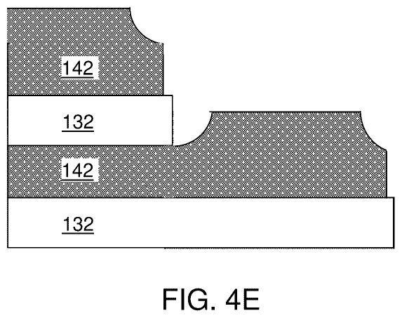

Local thickening of the physically exposed portions of the first-tier sacrificial material layers 142 may also be performed employing alternative methods. FIGS. 4A-4E are sequential vertical cross-sectional views of a region of the first exemplary structure during a sequence of processing steps that may be employed to locally thicken the physically-exposed portions of the first-tier sacrificial material layers according to an embodiment of the present disclosure.

Referring to FIG. 4A, a region of the first-tier stepped surfaces in a first-tier stepped cavity 169 after the processing steps of FIGS. 2A-2E is illustrated.

Referring to FIG. 4B, an additive sacrificial material layer 442L can be conformally deposited by a conformal deposition process such as a low pressure chemical vapor deposition process. The thickness of the additive sacrificial material layer 442L may be in a range from 40 % to 300 %, such as from 60 % to 150 %, of the thickness of each first-tier sacrificial material layer 142. The additive sacrificial material layer 442L may comprise the same material as the first-tier sacrificial material layers 142. For example, if the first-tier sacrificial material layers 142 comprise silicon nitride, the additive sacrificial material layer 442L may comprise silicon nitride.

Subsequently, a non-conformal cover material layer 432L may be anisotropically deposited. The anisotropic deposition of the non-conformal cover material layer 432L may be effected, for example, by plasma enhanced chemical vapor deposition. The non-conformal cover material layer 432L comprises a material that can function as an etch mask material for subsequently etching unmasked portions of the additive sacrificial material layer 442L. For example, the non-conformal cover material layer 432L may comprise silicon oxide. The vertical thickness of the horizontally-extending portions of the non-conformal cover material layer 432L is greater than the lateral thickness of the vertically-extending portions of the non-conformal cover material layer 432L. The difference between the vertical thickness of the horizontally-extending portions of the non-conformal cover material layer 432L and the lateral thickness of the vertically-extending portions of the non-conformal cover material layer 432L may be in a range from 1.3 to 3.0, such as from 1.5 to 2.0.

Referring to FIG. 4C, an isotropic etch process can be performed to isotropically etch the material of the non-conformal cover material layer 432L. The duration of the isotropic etch process is selected such that the etch distance of the isotropic etch process for the material of the non-conformal cover material layer 432L is greater than the lateral thickness of vertically-extending portions of the non-conformal cover material layer 432L, and is less than the vertical thickness of the horizontally-extending portions of the non-conformal cover material layer 432L. Thus, remaining portions of the non-conformal cover material layer 432L after the isotropic etch process comprise cover material plates 432 that are remaining portions of the non-conformal cover material layer 432L that overlie horizontally-extending portions of the additive sacrificial material layer 442L. The cover material plates 432 have a vertical thickness that is not greater than the difference between the vertical thickness of the horizontally-extending portions of the non-conformal cover material layer 432L and the lateral thickness of vertically-extending portions of the non-conformal cover material layer 432L, and may be in a range from 10 nm to 50 nm, although lesser and greater thicknesses may also be employed.

Referring to FIG. 4D, a selective isotropic etch process can be performed to isotropically etch unmasked portions of the additive sacrificial material layer 442L without etching the materials of cover material plates 432 or the first-tier insulating layers 132. The duration of the selective isotropic etch process may be selected such that the etch distance of the selective isotropic etch process for the material of the additive sacrificial material layer 442L is not less than the uniform thickness of the additive sacrificial material layer 442L. Thus, vertically-extending portions of the additive sacrificial material layer 442L are removed by the selective isotropic etch process, while remaining horizontally-extending portions of the additive sacrificial material layer 442L underlie a respective one of the cover material plates 432. The remaining horizontally-extending portions of the additive sacrificial material layer 442L comprise sacrificial material plates 442, which are incorporated into a respective one of the first-tier sacrificial material layers 142.

Referring to FIG. 4E, a selective etch process may be optionally performed to remove the cover material plates 432 without removing the materials of the sacrificial material plates 442 or the first-tier sacrificial material layers 142. The material of sacrificial material plates 442 may be the same as the material of the first-tier sacrificial material layers 142. Thus, the first-tier sacrificial material layers 142 incorporate the sacrificial material plates 442, and are locally thickened in the regions of the first stepped surfaces.

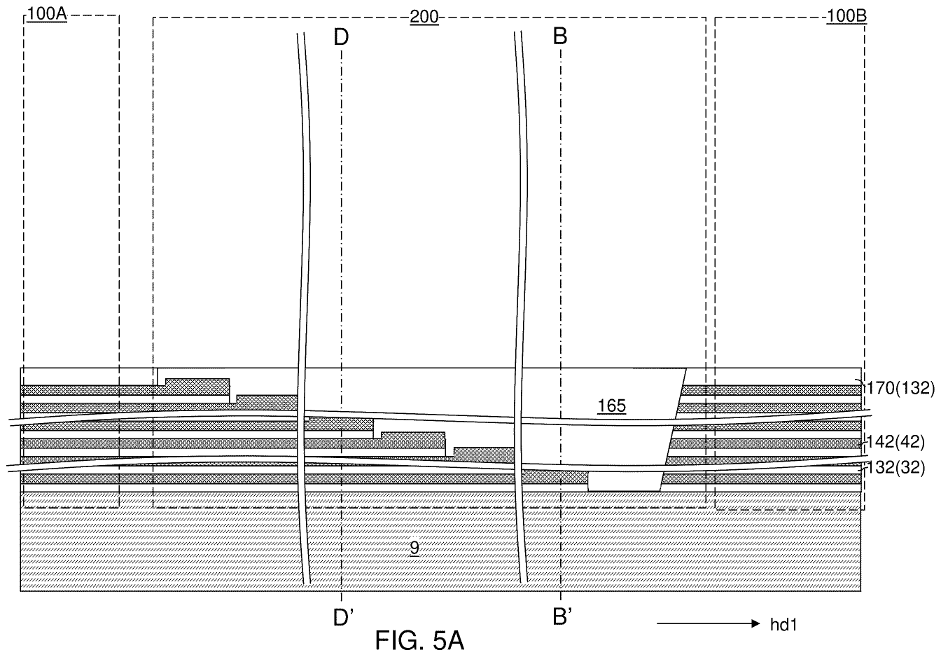

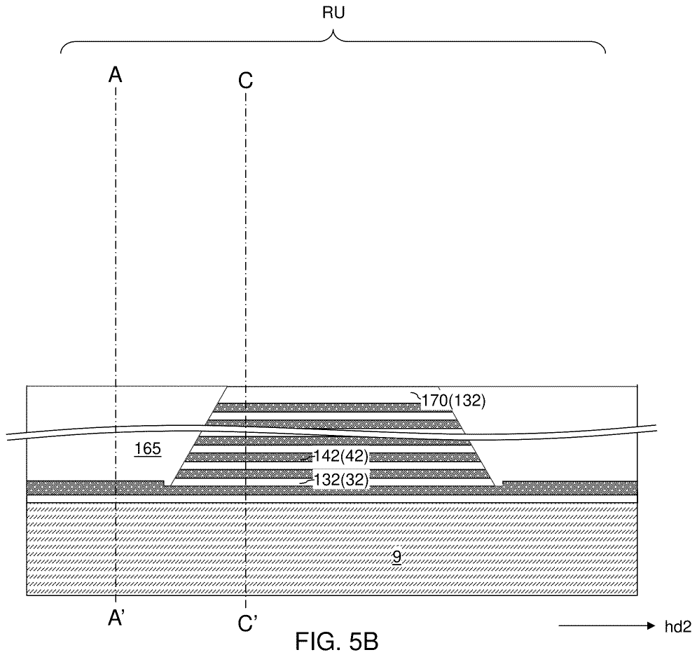

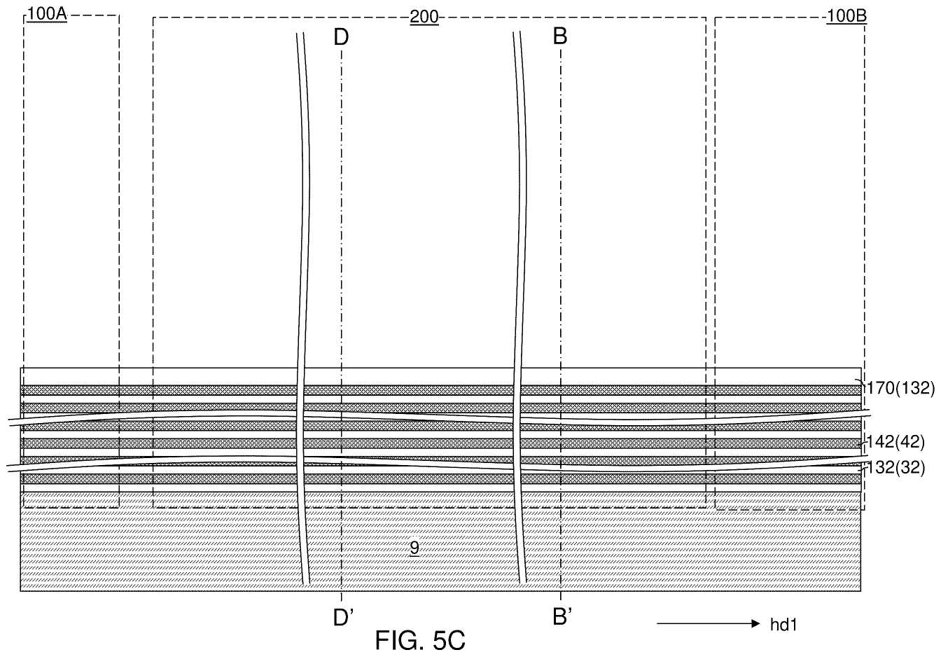

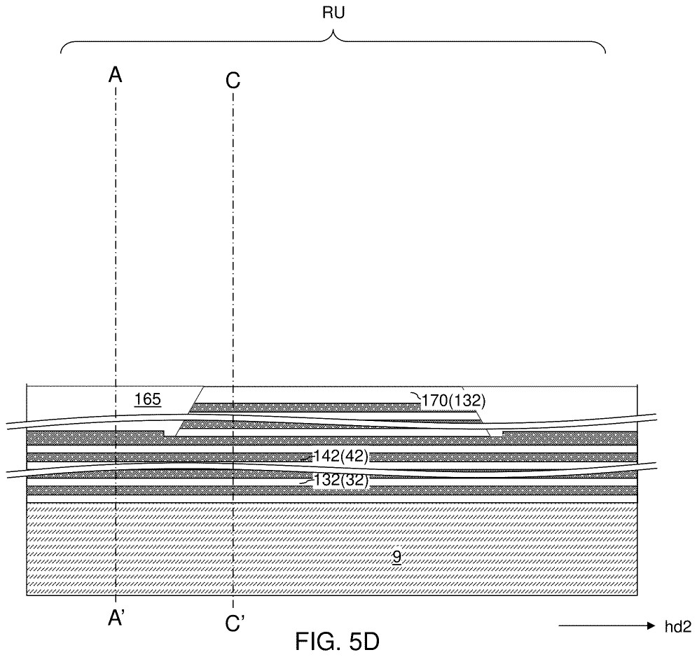

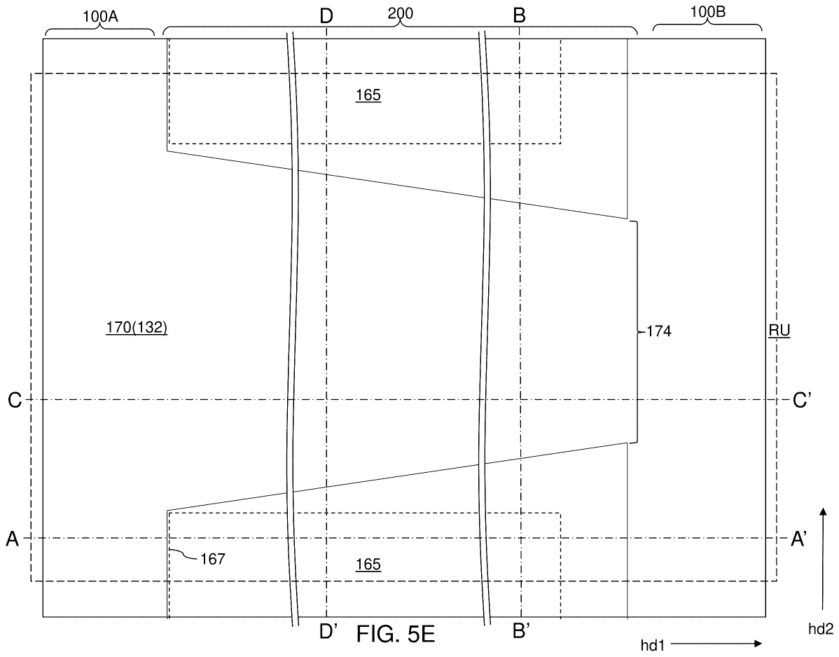

Referring to FIGS. 5A-5E, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in the contact region 200 between the first memory array region 100A and the second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

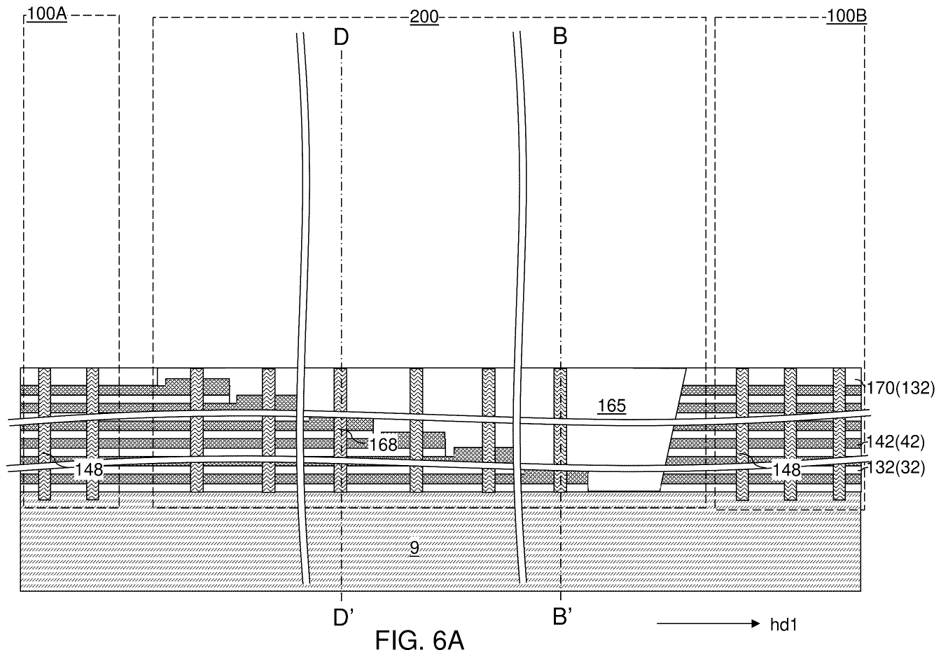

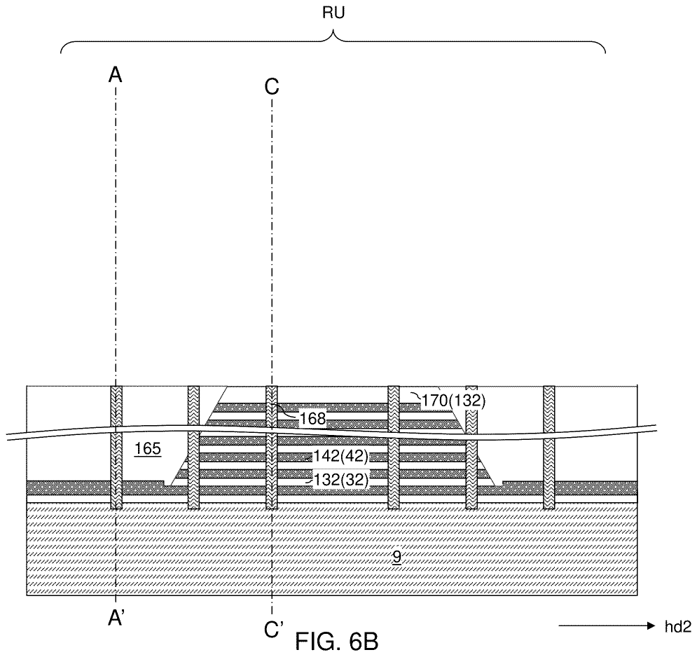

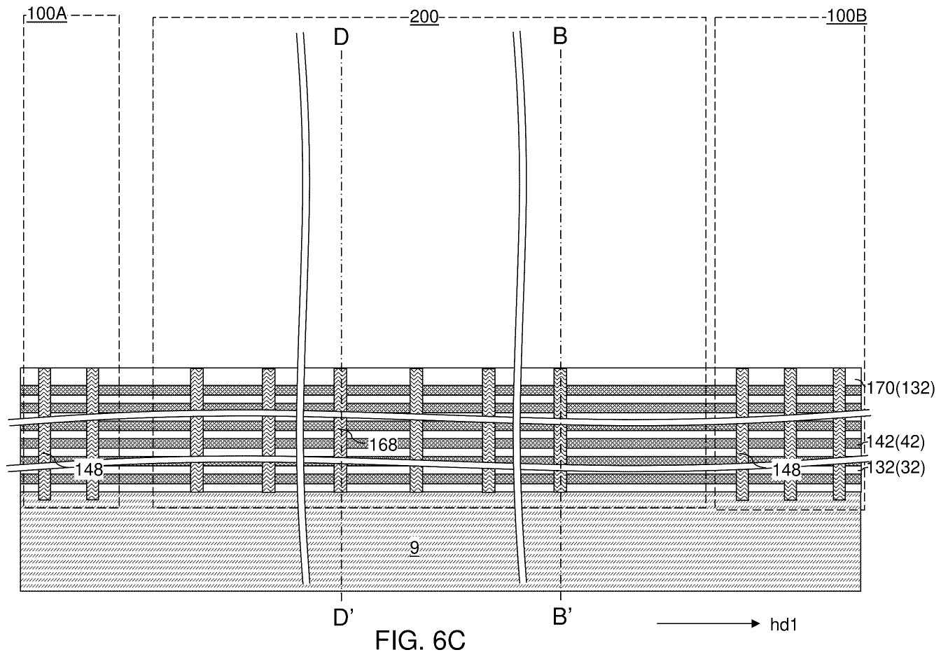

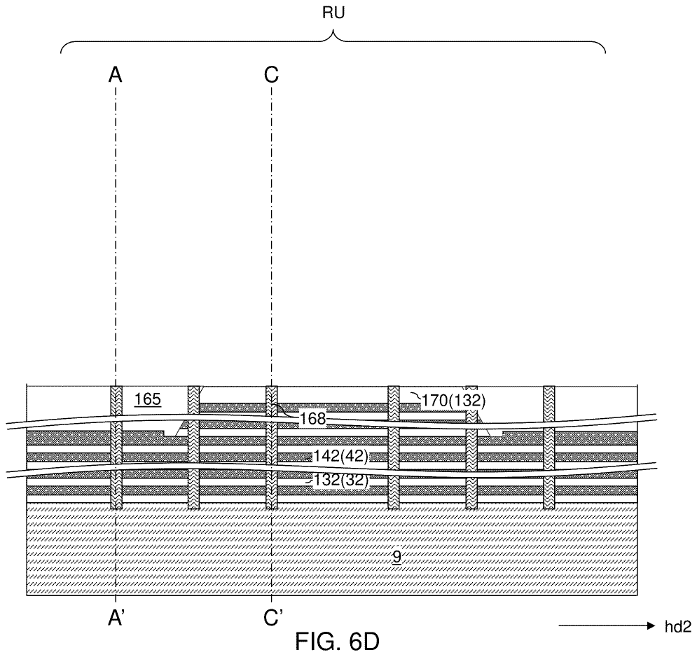

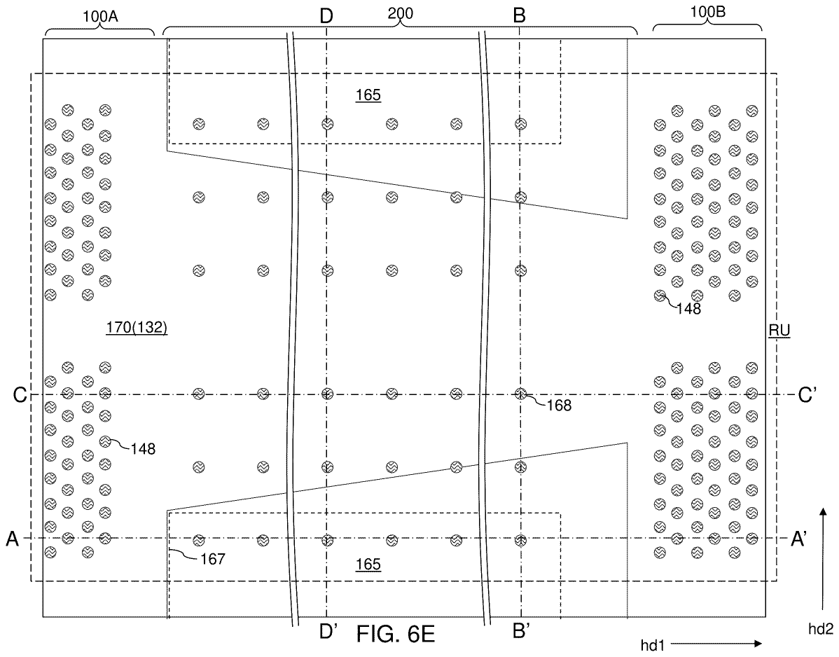

Referring to FIGS. 6A-6E, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently. The various first-tier openings may include first-tier memory openings formed in the memory array regions (100A, 100B) and first-tier support openings (not illustrated for the sake of reducing the complexity in the drawings) formed in the contact regions 200, and first-tier contact openings formed in the staircase regions 167 (which are located within the contact regions 200).

Each cluster of first-tier memory openings may be formed as a two-dimensional array of first-tier memory openings. The first-tier support openings are openings that are formed in the contact region 200, and are subsequently employed to form support pillar structures. Each first-tier contact opening is formed in a respective area in which a respective through-via contact structure is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

Sacrificial first-tier opening fill structures (148, 168) may be formed in the various first-tier openings. For example, a sacrificial first-tier fill material is concurrently deposited in each of the first-tier openings. The sacrificial first-tier fill material includes a material that may be subsequently removed selectively to the materials of the first-tier insulating layers 132 and the first-tier sacrificial material layers 142. In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

Portions of the deposited sacrificial first-tier fill material may be removed from above the topmost layer of the first vertically alternating sequence (132, 142), such as from above the first-tier insulating cap layer 170. For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure (not illustrated for the sake of reducing complexity of the drawings). Each remaining portion of the sacrificial first-tier fill material in a first-tier contact opening constitutes a sacrificial first-tier contact opening fill structure 168. The various sacrificial first-tier opening fill structures (148, 168) are concurrently formed, i.e., employing a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 168) may be coplanar with the top surface of the first-tier insulating cap layer 170. Each of the sacrificial first-tier opening fill structures (148, 168) may, or may not, include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

According to an aspect of the present disclosure, each first-tier sacrificial material layer 142 comprises a respective locally thickened portion underneath each first-tier retro-stepped dielectric material portion 165. A subset of the first-tier contact openings can be formed through a locally thickened portion of a respective first-tier sacrificial material layer 142. The sacrificial first-tier contact opening fill structures 168 may vertically extend from a horizontal plane including a top surface of the first-tier alternating stack (132, 142) at least to a horizontal plane including a bottom surface of the first-tier alternating stack (132, 142).

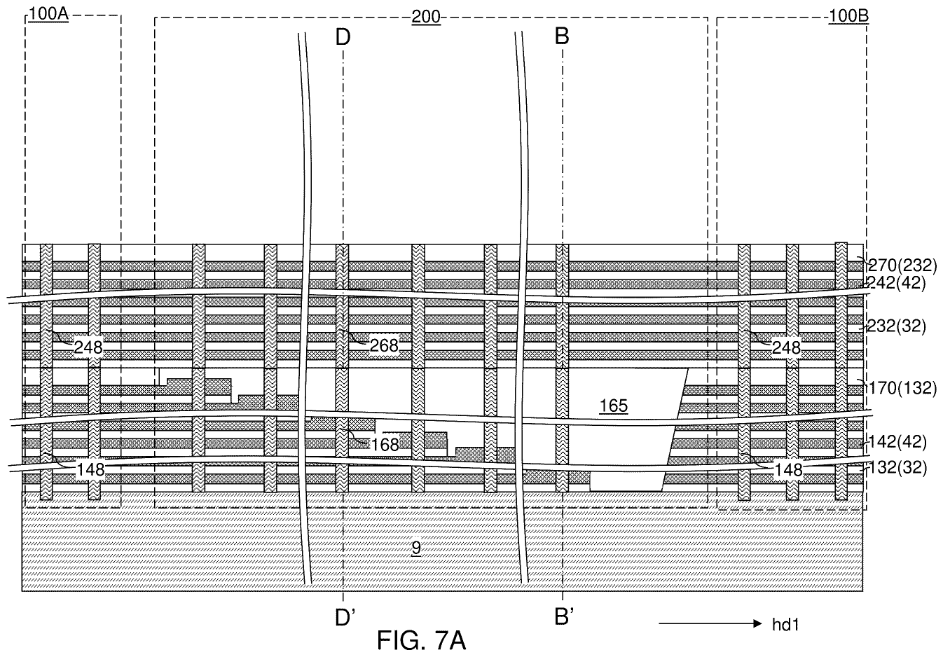

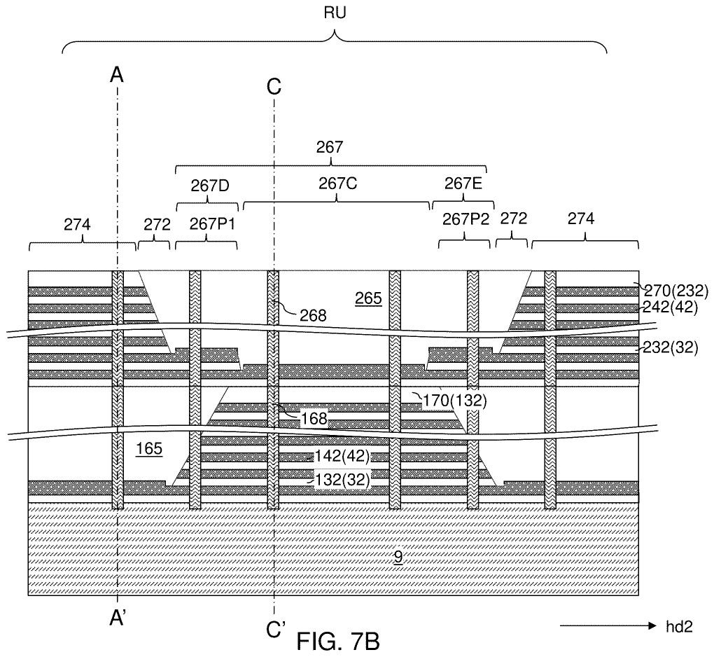

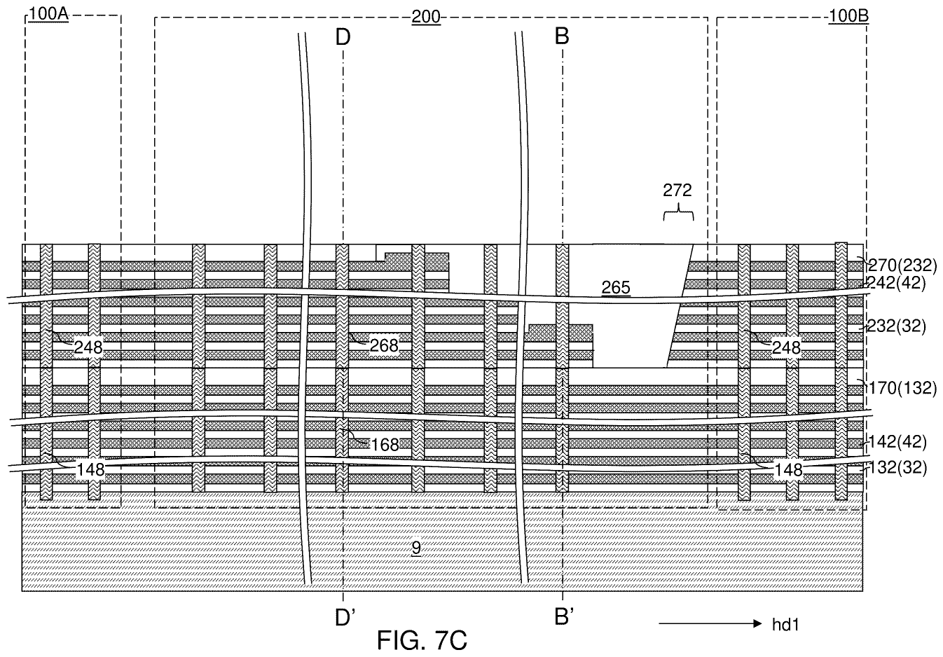

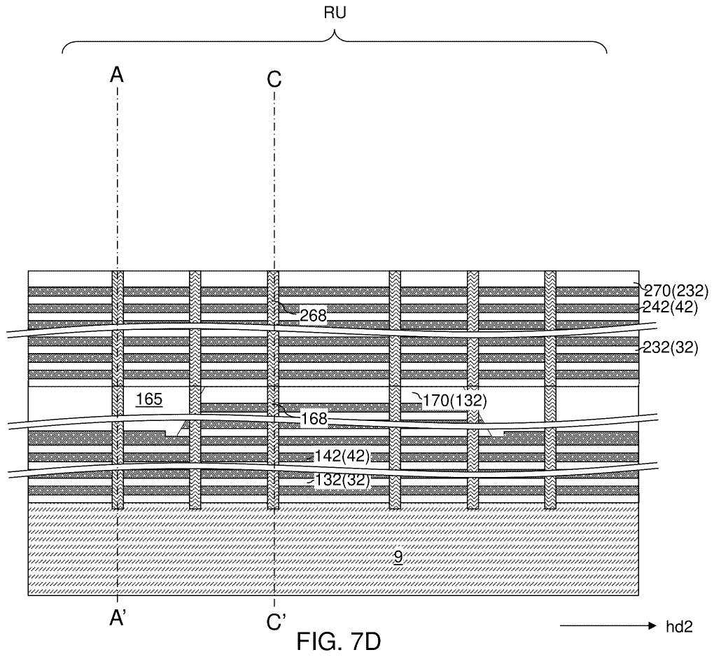

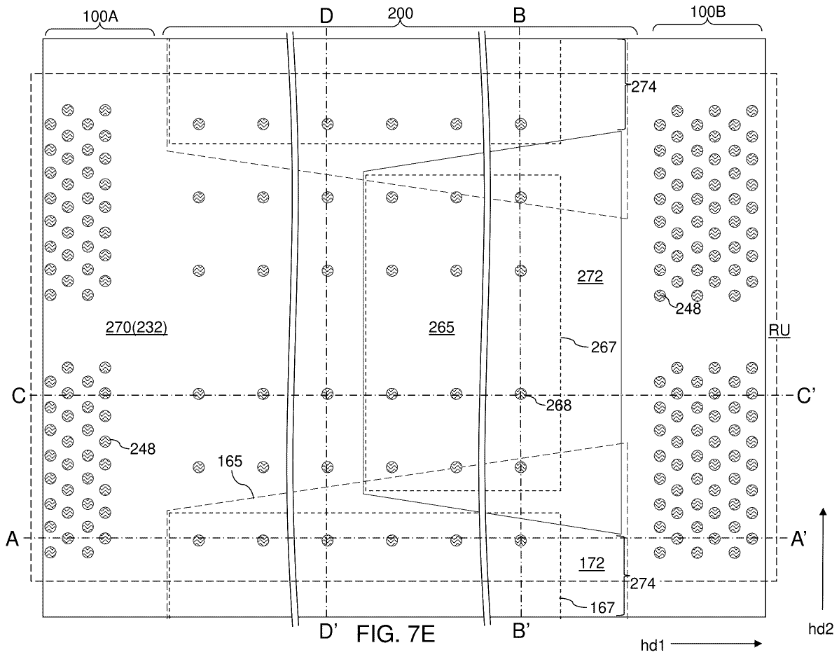

Referring to FIGS. 7A-7E, a second vertically alternating sequence of second-tier insulating layers 232 and second-tier sacrificial material layers 242 can be formed. Each of the second-tier insulating layers 232 is an insulating layer 32 that continuously extends over the entire area of the substrate 9, and may have a uniform thickness throughout. Each of the second-tier sacrificial material layers 242 is a sacrificial material layer 42 that includes a dielectric material and continuously extends over the entire area of the substrate 9, and may have a uniform thickness throughout. The second-tier insulating layers 232 can have the same material composition and the same thickness as the first-tier insulating layers 132. The second-tier sacrificial material layers 242 can have the same material composition and the same thickness as the first-tier sacrificial material layers 142. The topmost second-tier insulating layer 232 is herein referred to as a second-tier insulating cap layer 270. The second-tier insulating cap layer 270 may have a greater thickness than each of the underlying second-tier insulating layers 232.

Second stepped surfaces can be formed within each second-tier stepped cavity in the contact region 200 which will be filled with a respective second-tier retro-stepped dielectric material portions 265. For example, a combination of a sacrificial hard mask layer and a trimming mask layer may be employed to form the second stepped surfaces. Generally, the processing steps described with reference to FIGS. 2A-2E can be performed with a change in the masking pattern to form second-tier stepped cavities. Each set of second stepped surfaces may be laterally offset along the second horizontal direction hd2 relative to an adjacent and underlying set of first stepped surfaces of the first vertically alternating sequence (132, 142).

Each second-tier stepped cavity comprises a respective contiguous set of stepped surfaces of the second vertically alternating sequence (232, 242). The lateral extents of the second-tier sacrificial material layers 242 vary with a vertical distance from the substrate 9 in each second-tier stepped cavity. Each of the second-tier sacrificial material layers 242 has a respective physically exposed horizontal top surface segment within each second-tier stepped cavity. The lateral extent of the physically exposed top surface segments of the second-tier sacrificial material layers 242 along the first horizontal direction hd1 may be evenly divided among all of the second-tier sacrificial material layers 242.

In one embodiment, the lateral extent of each of the second-tier stepped cavities along the first horizontal direction hd1 may be about one half of the lateral distance between the first memory array region 100A and the second memory array region 100B. In this case, the lateral extent of each of the second-tier stepped cavities along the second horizontal direction hd2 may be about twice the lateral extent of the each of the first-tier stepped cavities 169 along the first horizontal direction hd1. For example, if the total number of the second-tier sacrificial material layers 242 is N2, the horizontal length of the physically exposed portion of the physically exposed top surface segment of each second-tier sacrificial material layer 242 may be 1/N2 times a total stepped surface length, which may be in a range from 0.45 times the lateral spacing between the first memory array region 100A and the second memory array region 100B to 0.4999 times the lateral spacing between the first memory array region 100A and the second memory array region 100B.

The sidewalls of each second-tier stepped cavity may be tapered. The area in which the physically exposed horizontal surface segments of the second-tier stepped surfaces of a second-tier stepped cavity is located within a plan view is herein referred to as a second-tier stepped surface area (e.g., second-tier staircase region) 267. According to an aspect of the present disclosure, the second-tier stepped surface areas 267 do not have any areal overlap with the first-tier stepped surface areas 167 in the plan view. In one embodiment, each second-tier stepped surface area 267 may have a rectangular shape, and the opening in the second-tier insulating cap layer 270 may have a shape of a trapezoid having a greater width for a side proximal to a physically exposed top surface segment of the bottommost second-tier sacrificial material layer 242 than for a side that is distal from the physically exposed top surface segment of the bottommost second-tier sacrificial material layer 242. The tapered surfaces of the second-tier alternating stack (232, 242) in the second-tier stepped cavity are referred to as a second-tier dummy staircase region 272. The region of the second-tier alternating stack (232, 242) extending in the second horizontal direction hd2 between adjacent second-tier stepped cavities 169 is referred to as a second-tier bridge region 274.

In one embodiment, each first-tier stepped surface area 167 may have a rectangular shape in the plan view. The lateral extent of each of the second-tier stepped surface area 267 along the first horizontal direction (e.g., word line direction) hd1 may be about one half of the lateral extent of each of the first-tier stepped surface area 167 along the first horizontal direction hd1. The lateral extent of each of the second-tier stepped surface area 267 along the second horizontal direction hd2 may be about twice of the lateral extent of each of the first-tier stepped surface area 167 along the second horizontal direction hd2. In this case, three staircases (i.e., three lanes of steps) can be formed within each second-tier stepped cavity 169 such that a central staircase is vertically offset from two peripheral staircases by a vertical level offset by a vertical distance that equals the sum of the thickness of a second-tier insulating layer 232 and a second-tier sacrificial material layer 242. In the illustrated example in FIG. 7B, the central staircase 267C is vertically offset downward relative to the two peripheral staircases 267P1 and 267P2 by a vertical distance that equals the sum of the thickness of a second-tier insulating layer 232 and a second-tier sacrificial material layer 242. The central staircase 267C and the two peripheral staircases 267P1 and 267P2 are laterally offset from each other along the second horizontal direction (e.g., bit line direction) hd2.

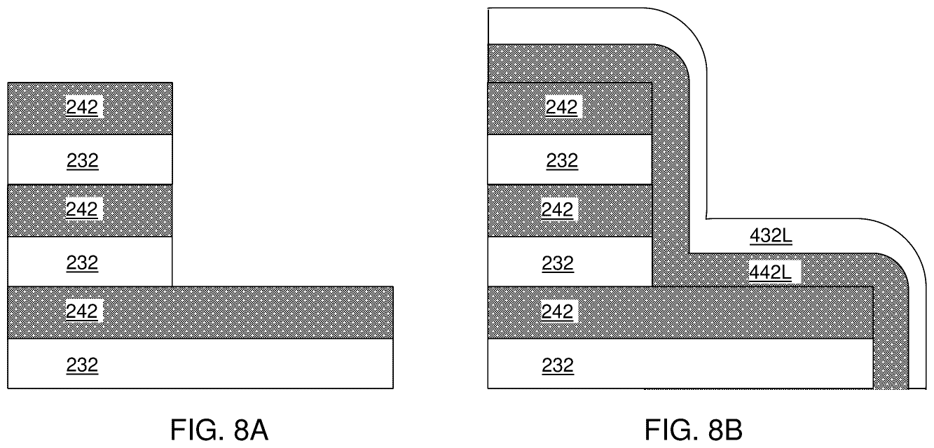

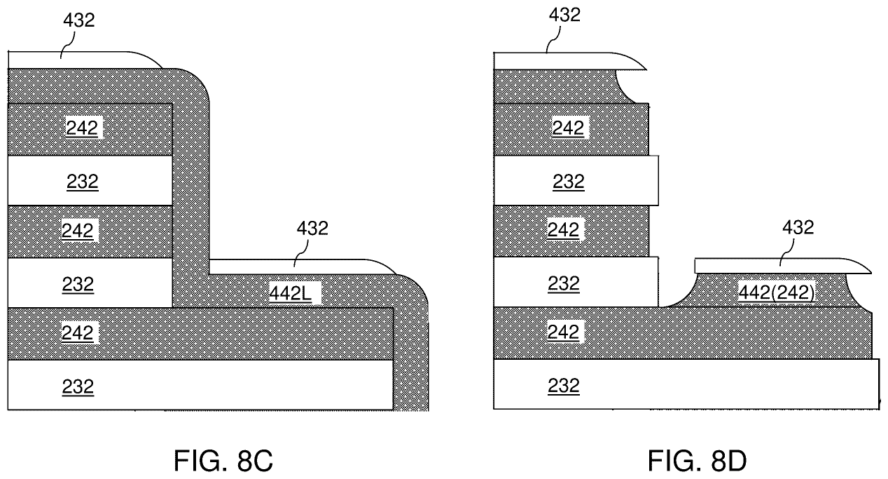

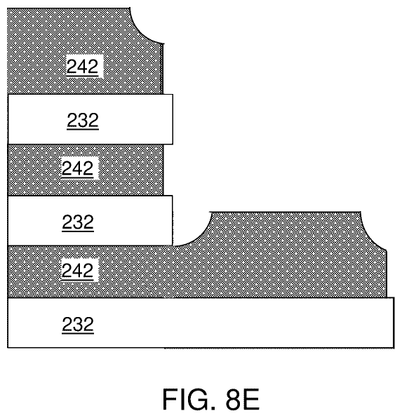

Physically-exposed portions of the second-tier sacrificial material layers 242 may be locally thickened by performing a sequence of processing steps described with reference to FIGS. 3A-3C or by performing a sequence of processing steps described with reference to FIGS. 4A-4E. FIGS. 8A-8E are sequential vertical cross-sectional views of a region of the first exemplary structure during a sequence of processing steps that may be employed to locally thicken the physically-exposed portions of the second-tier sacrificial material layers according to an embodiment of the present disclosure. The sequence of processing steps illustrated in FIG. 8A-8E illustrate the local thickening of portions of the second-tier sacrificial material layers 242 having physically exposed horizontal surfaces using the sequence of processing steps described with reference to FIGS. 4A-4E.

Referring back to FIGS. 7A-7E, a second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second-tier stepped cavity constitutes a second-tier retro-stepped dielectric material portion 265. Generally, the second-tier retro-stepped dielectric material portions 265 can be formed in the contact region 200 located between the first memory array region 100A and the second memory array region 100B. The planar top surface of each second-tier retro-stepped dielectric material portion 265 can be located within a horizontal plane including the top surface of the second-tier insulating cap layer 270.

The processing steps described with reference to FIGS. 6A-6E may be performed with necessary changes to form various second-tier openings through the second vertically alternating sequence (232, 242). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) by a second anisotropic etch process to form the various second-tier openings concurrently. The various second-tier openings may include second-tier memory openings formed in the memory array regions 200 and second-tier support openings (not illustrated for the sake of reducing the complexity in the drawings) formed in the contact regions 200, and second-tier contact openings formed in the staircase regions (which are located within the contact regions 200). Each cluster of second-tier memory openings may be formed as a two-dimensional array of second-tier memory openings. The second-tier support openings are openings that are formed in the contact region 200, and are subsequently employed to form support pillar structures. Each second-tier contact opening is formed in a respective area in which a respective through-via contact structure is to be subsequently formed. A subset of the second-tier support openings may be formed through a respective horizontally-extending surface segment of the second stepped surfaces. A subset of the second-tier contact openings is formed through a respective horizontally-extending surface segment of the second stepped surfaces.

Sacrificial second-tier opening fill structures (248, 268) may be formed in the various second-tier openings. For example, a sacrificial second-tier fill material is concurrently deposited in each of the second-tier openings. The sacrificial second-tier fill material and an optional thin etch stop liner may be the same as described above. The sacrificial second-tier fill material may be formed by a non-conformal deposition or a conformal deposition method. Portions of the deposited sacrificial second-tier fill material may be removed from above the topmost layer of the second vertically alternating sequence (232, 242), such as from above the second-tier insulating cap layer 270. For example, the sacrificial second-tier fill material may be recessed to a top surface of the second-tier insulating cap layer 270 using a planarization process. The planarization process may include a recess etch, chemical mechanical planarization (CMP), or a combination thereof. The top surface of the second-tier insulating cap layer 270 may be used as an etch stop layer or a planarization stop layer.

Remaining portions of the sacrificial second-tier fill material comprise sacrificial second-tier opening fill structures (248, 268). Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure (not illustrated for the sake of reducing complexity of the drawings). Each remaining portion of the sacrificial second-tier fill material in a second-tier contact opening constitutes a sacrificial second-tier contact opening fill structure 268. The various sacrificial second-tier opening fill structures (248, 268) are concurrently formed, i.e., during a same set of processes including the deposition process that deposits the sacrificial second-tier fill material and the planarization process that removes the second-tier deposition process from above the second vertically alternating sequence (232, 242) (such as from above the top surface of the second-tier insulating cap layer 270). The top surfaces of the sacrificial second-tier opening fill structures (248, 268) may be coplanar with the top surface of the second-tier insulating cap layer 270. Each of the sacrificial second-tier opening fill structures (248, 268) may, or may not, include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

According to an aspect of the present disclosure, each second-tier sacrificial material layer 242 comprises a respective locally thickened portion underneath each second-tier retro-stepped dielectric material portion 265. A subset of the second-tier contact openings can be formed through a locally thickened portion of a respective second-tier sacrificial material layer 242. The sacrificial second-tier contact opening fill structures 268 may vertically extend from a horizontal plane including a top surface of the second-tier alternating stack (232, 242) at least to a horizontal plane including a bottom surface of the second-tier alternating stack (232, 242).

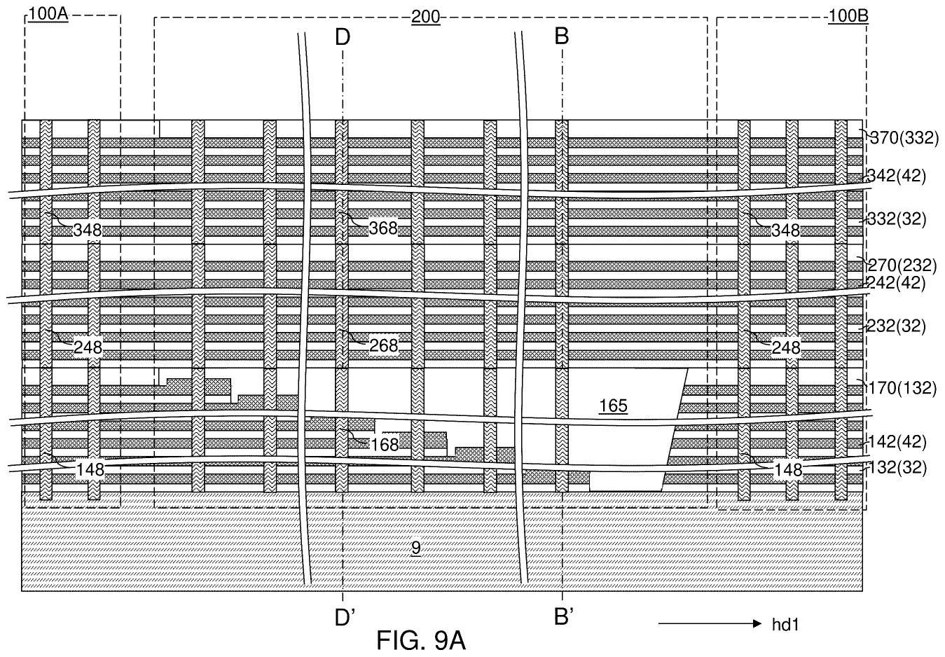

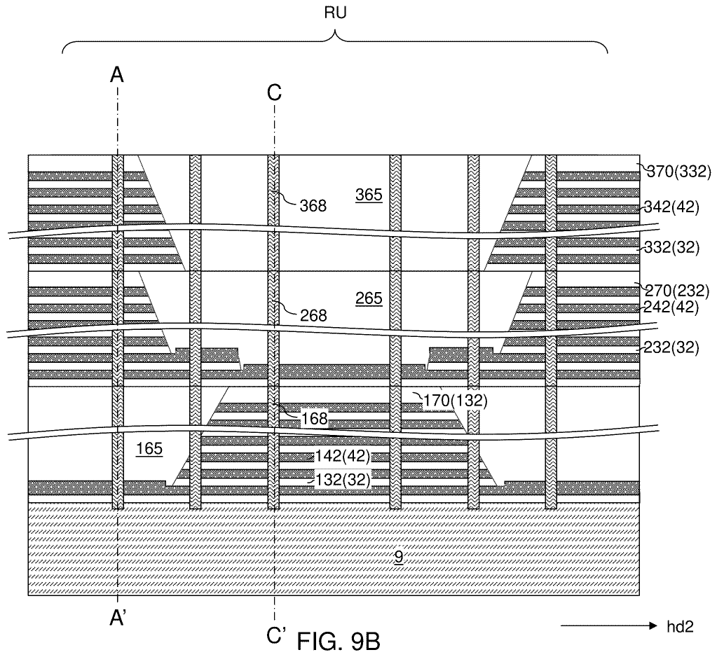

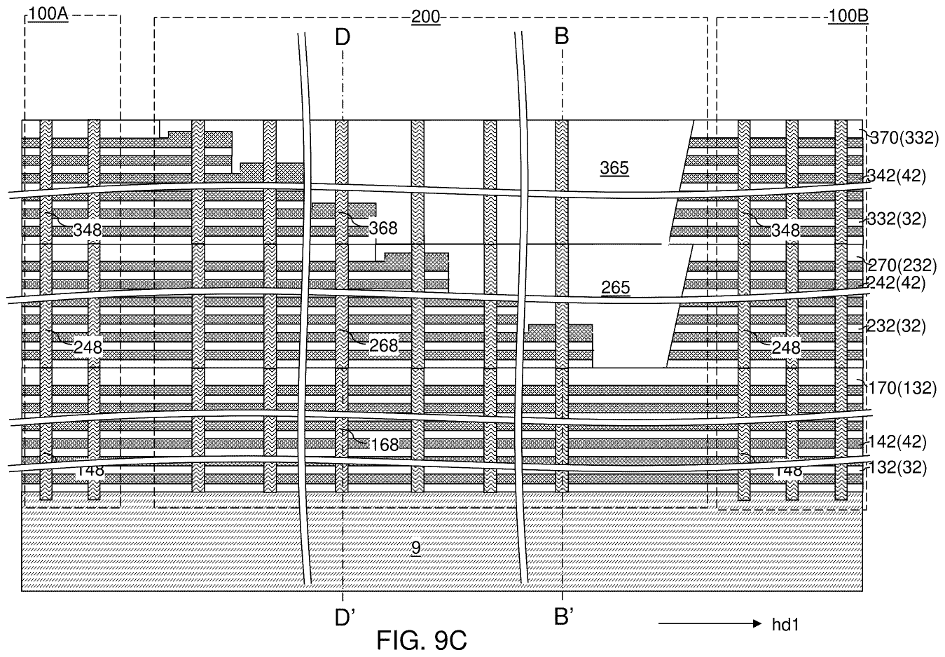

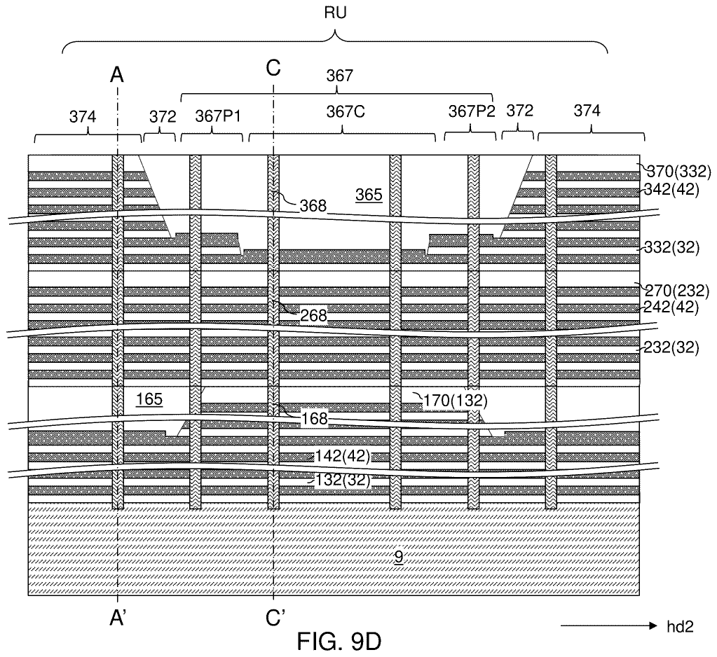

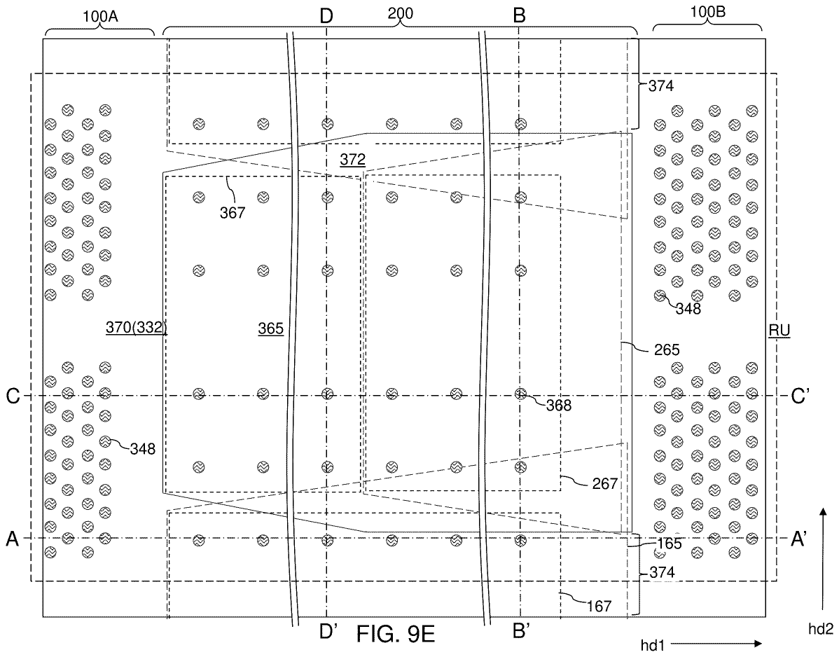

Referring to FIGS. 9A-9E, the processing steps described with reference to FIGS. 7A-7E may be performed with necessary modifications to form a vertically alternating sequence of third-tier continuous insulating layers 32 and third-tier continuous sacrificial material layers, third-tier retro-stepped dielectric material portions 365, various third-tier openings, and various third-tier sacrificial opening fill structures (348, 368). In the third vertically alternating sequence of third-tier insulating layers 332 and third-tier sacrificial material layers 342, each of the third-tier insulating layers 332 is an insulating layer 32 that continuously extends over the entire area of the substrate 9, and may have a uniform thickness throughout, and each of the third-tier sacrificial material layer 432 is a sacrificial material layer 42 that continuously extends over the entire area of the substrate 9, and may have a uniform thickness throughout. The topmost third-tier insulating layer 332 is herein referred to as a third-tier insulating cap layer 370. The third-tier insulating cap layer 370 may have a greater thickness than each of the underlying third-tier insulating layers 332.

Third stepped surfaces can be formed within each third-tier stepped cavity in the contact region 300 which will be filled with a respective third-tier retro-stepped dielectric material portions 365. For example, a combination of a sacrificial hard mask layer and a trimming mask layer may be employed to form the third stepped surfaces. Generally, the processing steps described with reference to FIG. 3A-3E can be performed with a change in the masking pattern to form third-tier stepped cavities. Each set of third stepped surfaces may be laterally offset along the second horizontal direction hd2 relative to an adjacent and underlying set of first stepped surfaces of the first vertically alternating sequence (132, 142), and may be laterally offset along the first horizontal direction hd1 relative to an adjacent and underlying set of second stepped surfaces of the second vertically alternating sequence (232, 242).

Each third-tier stepped cavity comprises a respective contiguous set of stepped surfaces of the third vertically alternating sequence (332, 342). The lateral extents of the third-tier sacrificial material layers 342 vary with a vertical distance from the substrate 9 in each third-tier stepped cavity. Each of the third-tier sacrificial material layers 342 has a respective physically exposed horizontal top surface segment within each third-tier stepped cavity. The lateral extent of the physically exposed top surface segments of the third-tier sacrificial material layers 342 along the first horizontal direction hd1 may be evenly divided among all of the third-tier sacrificial material layers 342.

In one embodiment, the lateral extent of each of the third-tier stepped cavities along the first horizontal direction hd1 may be about one half of the lateral distance between the first memory array region 100A and the second memory array region 100B. In this case, the lateral extent of each of the third-tier stepped cavities along the second horizontal direction hd2 may be about twice the lateral extent of the each of the first-tier stepped cavities 169 along the first horizontal direction hd1. For example, if the total number of the third-tier sacrificial material layers 342 is N3, the horizontal length of the physically exposed portion of the physically exposed top surface segment of each third-tier sacrificial material layer 342 may be 1/N3 times a total stepped surface length, which may be in a range from 0.45 times the lateral spacing between the first memory array region 100A and the second memory array region 100B to 0.4999 times the lateral spacing between the first memory array region 100A and the second memory array region 100B.

The sidewalls of each third-tier stepped cavity may be tapered. The area in which the physically exposed horizontal surface segments of the third-tier stepped surfaces of a third-tier stepped cavity is located within a plan view is herein referred to as a third-tier stepped surface area (e.g., third-tier staircase region) 367. According to an aspect of the present disclosure, the third-tier stepped surface areas 367 do not have any areal overlap with the first-tier stepped surface areas 167 in the plan view, and do not have any areal overlap with the second-tier stepped surface areas 267 in the plan view. In one embodiment, each third-tier stepped surface area 367 may have a rectangular shape, and the opening in the third-tier insulating cap layer 370 may have a shape of a trapezoid having a greater width for a side proximal to a physically exposed top surface segment of the bottommost third-tier sacrificial material layer 342 than for a side that is distal from the physically exposed top surface segment of the bottommost third-tier sacrificial material layer 342. The tapered surfaces of the third-tier alternating stack (332, 342) in the third-tier stepped cavity are referred to as a third-tier dummy staircase region 372. The region of the third-tier alternating stack (332, 342) extending in the second horizontal direction hd2 between adjacent third-tier stepped cavities 269 is referred to as a third-tier bridge region 374.

In one embodiment, each first-tier stepped surface area 167 may have a rectangular shape in the plan view. The lateral extent of each of the third-tier stepped surface area 367 along the first horizontal direction hd1 may be about one half of the lateral extent of each of the first-tier stepped surface area 167 along the first horizontal direction hd1. The lateral extent of each of the third-tier stepped surface area 367 along the third horizontal direction hd2 may be about twice of the lateral extent of each of the first-tier stepped surface area 167 along the third horizontal direction hd2. In this case, three staircases can be formed within each third-tier stepped cavity such that a central staircase is vertically offset from two peripheral staircases by a vertical level offset by a vertical distance that equals the sum of the thickness of a third-tier insulating layer 332 and a third-tier sacrificial material layer 342. In the illustrated example in FIG. 9D the central staircase 367C is vertically offset downward relative to the two peripheral staircases 367P1 and 367P2 by a vertical distance that equals the sum of the thickness of a third-tier insulating layer 332 and a third-tier sacrificial material layer 342. The central staircase 367C and the two peripheral staircases 367P1 and 367P2 are laterally offset from each other along the second horizontal direction (e.g., bit line direction) hd2.

Physically-exposure portions of the third-tier sacrificial material layers 342 may be locally thickened by performing a sequence of processing steps described with reference to FIGS. 3A-3C or by performing a sequence of processing steps described with reference to FIGS. 4A-4E.

Referring back to FIGS. 9A-9E, a third dielectric fill material (such as undoped silicate glass (i.e., silicon oxide) or a doped silicate glass) can be deposited in each third-tier stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third-tier stepped cavity constitutes a third-tier retro-stepped dielectric material portion 365. Generally, the third-tier retro-stepped dielectric material portions 365 can be formed in the contact region 300 located between the first memory array region 100A and the second memory array region 100B. The planar top surface of each third-tier retro-stepped dielectric material portion 365 can be located within a horizontal plane including the top surface of the third-tier insulating cap layer 370.

The processing steps described with reference to FIGS. 6A-6E may be performed with necessary changes to form various third-tier openings through the third vertically alternating sequence (332, 342). A photoresist layer (not shown) may be applied over the third vertically alternating sequence (332, 342), and may be lithographically patterned to form various openings therethrough. The pattern of openings in the photoresist layer may be transferred through the third vertically alternating sequence (332, 342) by a third anisotropic etch process to form the various third-tier openings concurrently. The various third-tier openings may include third-tier memory openings formed in the memory array regions 300 and third-tier support openings (not illustrated for the sake of reducing the complexity in the drawings) formed in the contact regions 300, and third-tier contact openings formed in the staircase regions (which are located within the contact regions 300). Each cluster of third-tier memory openings may be formed as a two-dimensional array of third-tier memory openings. The third-tier support openings are openings that are formed in the contact region 300, and are subsequently employed to form support pillar structures. Each third-tier contact opening is formed in a respective area in which a respective through-via contact structure is to be subsequently formed. A subset of the third-tier support openings may be formed through a respective horizontally-extending surface segment of the third stepped surfaces. A subset of the third-tier contact openings is formed through a respective horizontally-extending surface segment of the third stepped surfaces.

Sacrificial third-tier opening fill structures (348, 368) may be formed in the various third-tier openings. For example, a sacrificial third-tier fill material is concurrently deposited in each of the third-tier openings. The sacrificial third-tier fill material and an optional thin etch stop liner may be the same as described above. The sacrificial third-tier fill material may be formed by a non-conformal deposition or a conformal deposition method. Portions of the deposited sacrificial third-tier fill material may be removed from above the topmost layer of the third vertically alternating sequence (332, 342), such as from above the third-tier insulating cap layer 370. For example, the sacrificial third-tier fill material may be recessed to a top surface of the third-tier insulating cap layer 370 using a planarization process. The planarization process may include a recess etch, chemical mechanical planarization (CMP), or a combination thereof. The top surface of the third-tier insulating cap layer 370 may be used as an etch stop layer or a planarization stop layer.

Remaining portions of the sacrificial third-tier fill material comprise sacrificial third-tier opening fill structures (348, 368). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure (not illustrated for the sake of reducing complexity of the drawings). Each remaining portion of the sacrificial third-tier fill material in a third-tier contact opening constitutes a sacrificial third-tier contact opening fill structure 368. The various sacrificial third-tier opening fill structures (348, 368) are concurrently formed, i.e., during a same set of processes including the deposition process that deposits the sacrificial third-tier fill material and the planarization process that removes the third-tier deposition process from above the third vertically alternating sequence (332, 342) (such as from above the top surface of the third-tier insulating cap layer 370). The top surfaces of the sacrificial third-tier opening fill structures (348, 368) may be coplanar with the top surface of the third-tier insulating cap layer 370. Each of the sacrificial third-tier opening fill structures (348, 368) may, or may not, include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure.

According to an aspect of the present disclosure, each third-tier sacrificial material layer 342 comprises a respective locally thickened portion underneath each third-tier retro-stepped dielectric material portion 365. A subset of the third-tier contact openings can be formed through a locally thickened portion of a respective third-tier sacrificial material layer 342. The sacrificial third-tier contact opening fill structures 368 may vertically extend from a horizontal plane including a top surface of the third-tier alternating stack (332, 342) at least to a horizontal plane including a bottom surface of the third-tier alternating stack (332, 342).

In one embodiment, a photoresist layer (not shown) can be applied over the third-tier structure, and can be lithographically patterned to form openings over the areas of the sacrificial third-tier support opening fill structures (not illustrated). The sacrificial fill materials of the sacrificial third-tier support opening fill structures, the sacrificial second-tier support opening fill structures, and the sacrificial first-tier support opening fill structures can be removed selectively to the materials of retro-stepped dielectric material portions (165, 265, 365), the insulating layers 32, and the sacrificial material layers 42. Support pillar cavities (not illustrated) can be formed in the volumes from which the materials of the sacrificial third-tier support opening fill structures, the sacrificial second-tier support opening fill structures, and the sacrificial first-tier support opening fill structures are removed. The photoresist layer can be subsequently removed, for example, by ashing.

A dielectric fill material can be deposited in the support pillar cavities by performing a conformal deposition process. The dielectric fill material comprises a dielectric material that is different from the material of the sacrificial material layers 42. For example, the dielectric fill material may comprise undoped silicate glass or a doped silicate glass. Excess portions of the dielectric fill material can be removed from above the horizontal plane including the top surface of the topmost-tier retro-stepped dielectric material portions (such as the third-tier retro-stepped dielectric material portion 365). Each remaining portion of the dielectric fill material that fills a respective support pillar cavity constitutes a support pillar structure (not illustrated). The support pillar structures 20 can be formed in the contact region 200, and may vertically extend from the substrate 9 to a horizontal plane including the topmost surfaces of the third-tier insulating cap layer 370.

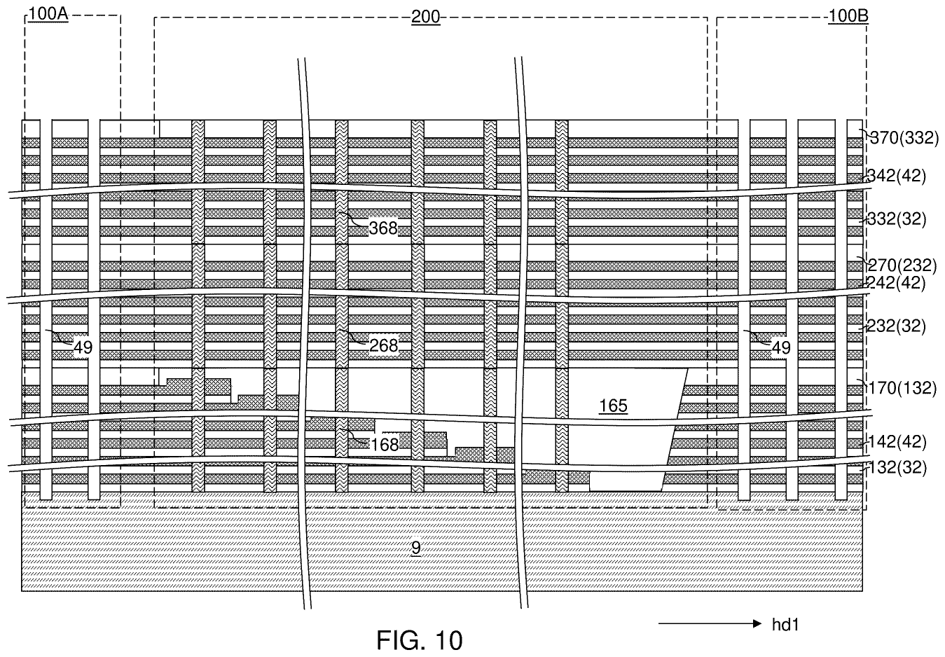

Referring to FIG. 10, a photoresist layer (not shown) can be applied over the third-tier structure, and can be lithographically patterned to cover the contact regions 200 without covering the memory array regions (100A, 100B). The sacrificial fill materials of the sacrificial memory opening fill structures (148, 248, 348) can be removed selectively to the materials of the insulating layers 32, the sacrificial material layers 42, and the substrate 9. Memory openings 49 are formed in the voids from which the sacrificial fill materials of the sacrificial memory opening fill structures (148, 248, 348) are removed.

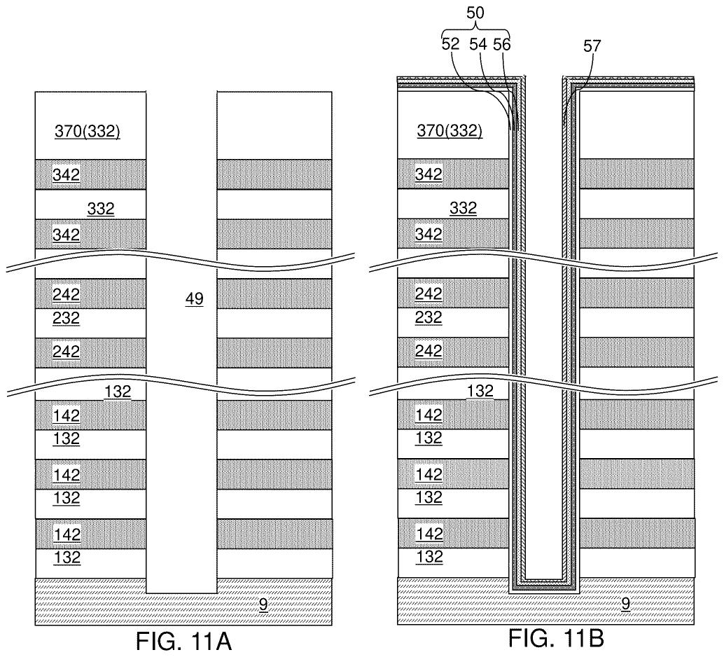

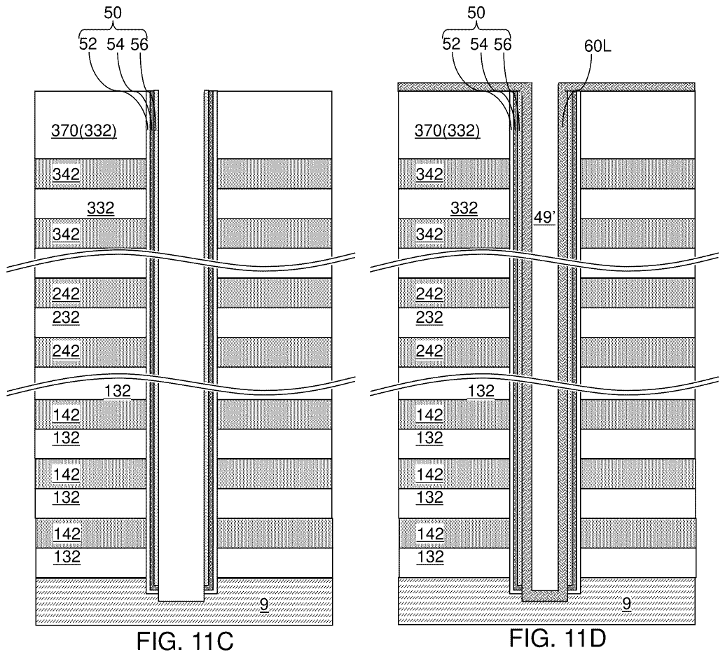

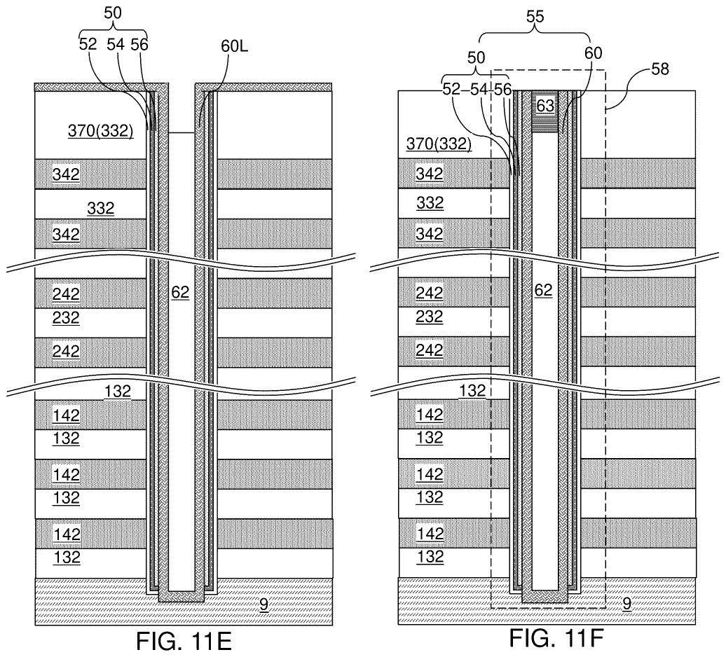

FIGS. 11A-11F illustrate sequential vertical cross-sectional views of a memory opening during formation of a memory opening fill structure according to an embodiment of the present disclosure.

Referring to FIG. 11A, a memory opening 49 in the first exemplary structure of FIG. 10 is illustrated.

Referring to FIG. 11B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 11C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 11D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 11E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 11F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions (100A, 100B) of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

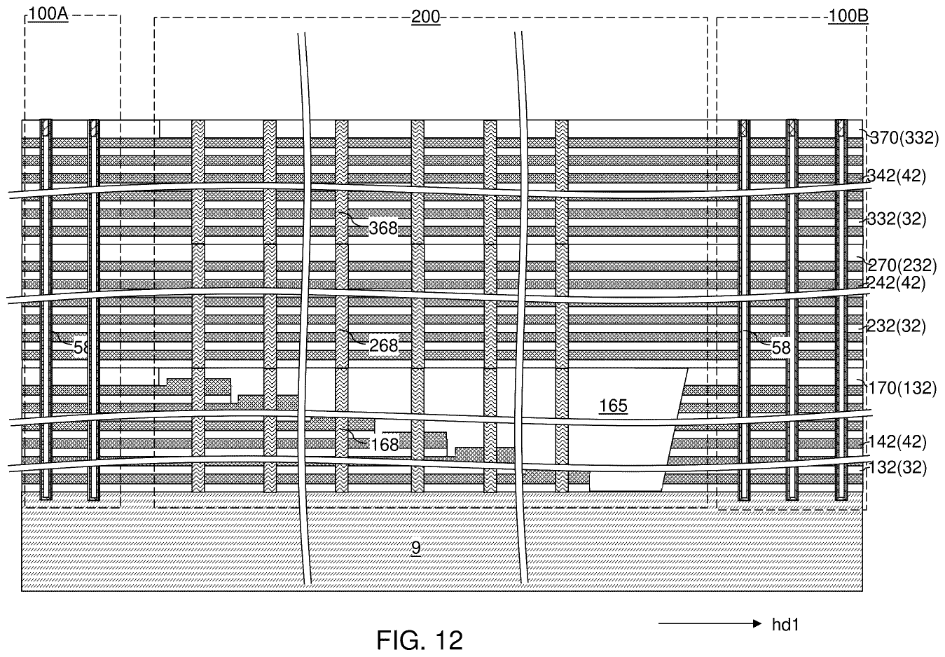

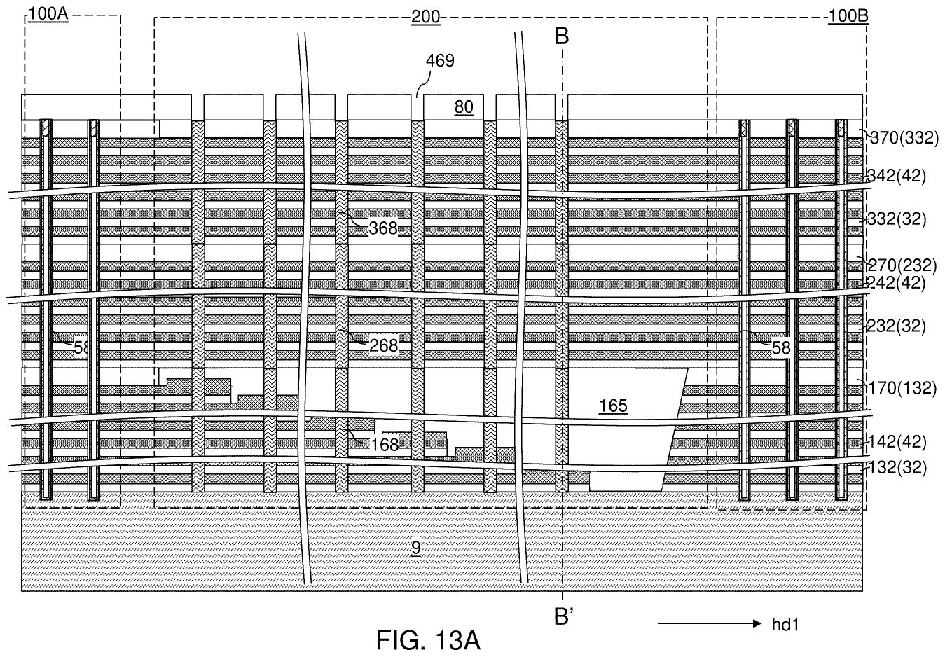

Referring to FIG. 12, the first exemplary structure is illustrated after the processing steps of FIG. 11F, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the sacrificial material layers 42 within the memory openings, and further comprises a respective vertical semiconductor channel 60 that vertically extends through the memory openings.

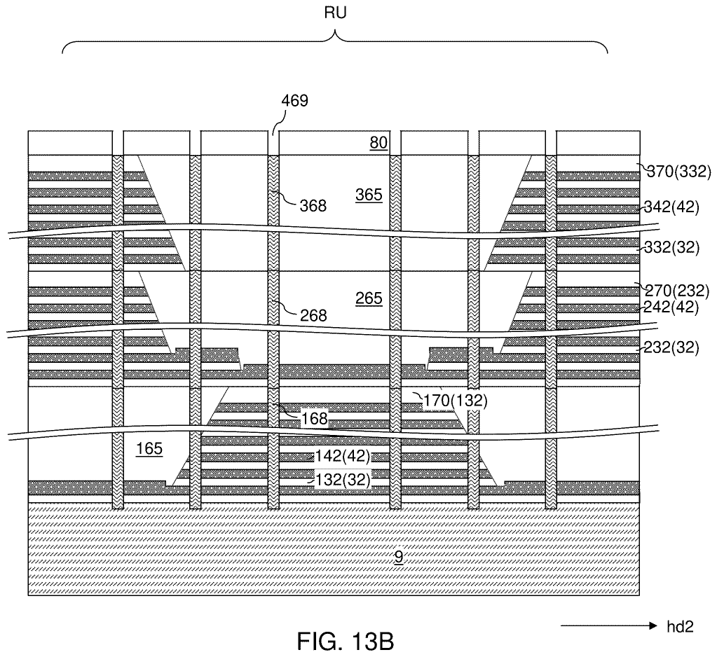

Referring to FIGS. 13A and 13B, a contact-level dielectric layer 80 can be deposited over the third-tier insulating cap layer 370 and the third-tier retro-stepped dielectric material portions 365. The contact-level dielectric layer 80 comprises a dielectric material such as silicon oxide, and may have a thickness in a range from 100 nm to 800 nm, although lesser and greater thicknesses may also be employed.

A photoresist layer (not shown) can be applied over the contact-level dielectric layer 80, and can be lithographically patterned to form openings over the areas of the sacrificial third-tier contact opening fill structures 368. An anisotropic etch process can be performed to form connection cavities 469 over the sacrificial third-tier contact opening fill structures 368. The photoresist layer may be subsequently removed, for example, by ashing.

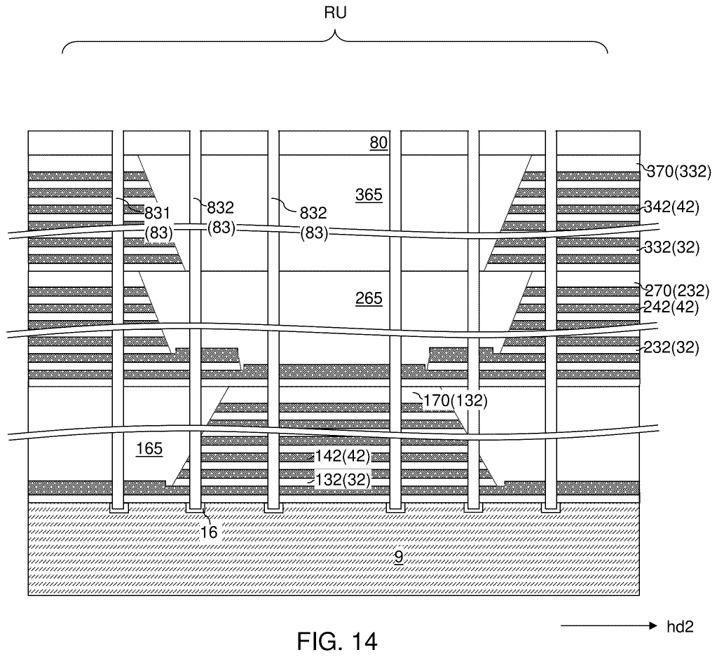

Referring to FIG. 14, the sacrificial fill materials of the sacrificial third-tier contact opening fill structures 368, the sacrificial second-tier contact opening fill structures 268, and the sacrificial first-tier contact opening fill structures 168 can be removed selectively to the materials of retro-stepped dielectric material portions (165, 265, 365), the insulating layers 32, the sacrificial material layers 42, and the support pillar structures (not shown). Contact via cavities 85 are formed in the volumes from which the materials of the sacrificial third-tier contact opening fill structures 368, the sacrificial second-tier contact opening fill structures 268, and the sacrificial first-tier contact opening fill structures 168 are removed. Each contact via cavity 85 vertically extends from the horizontal plane including the planar top surfaces of the third-tier retro-stepped dielectric material portion 365 to the substrate 9. Each contact via cavity 85 may vertically extend through a respective set of at least one insulating layer 32 and a respective set of at least one sacrificial material layer 42 of an alternating stack of insulating layers 32 and sacrificial material layers 42. Each contact via cavity 85 vertically extends through a thickened portion of the topmost sacrificial material layer within the respective set of at least one sacrificial material layer 42.

Generally, an alternating stack (32, 42) of insulating layers 32 and sacrificial material layers 42 can be formed over a substrate 9. Stepped surfaces can be formed by patterning the alternating stack (32, 42) in a staircase region (167, 267, 367). Physically exposed portions of the sacrificial material layers 42 are locally thickened after formation of the stepped surfaces. A retro-stepped dielectric material portion (165, 265, 365) is formed over the stepped surfaces. Contact via cavities 85 can be formed through a respective subset of the retro-stepped dielectric material portion (165, 265, 365) and a respective subset of the sacrificial material layers 42 within the alternating stack (32, 42). Each contact via cavity 85 may be formed through a locally thickened portion of a respective sacrificial material layer 42. Each contact via cavity 85 vertically extends through a thickened portions of only a single sacrificial material layer 42. In other words, each contact via cavity 85 vertically extends through no more than one thickened portion of the sacrificial material layers 42.

Generally, a first alternating stack of first insulating layers 32 and first sacrificial material layers 42 (which may be a first-tier alternating stack (132, 142), a second-tier alternating stack (232, 242), or a third-tier alternating stack (332, 342)) embedding a first retro-stepped dielectric material portion (which may be a first-tier retro-stepped dielectric material portion 165, a second-tier retro-stepped dielectric material portion 265, or a third-tier retro-stepped dielectric material portion 365) is formed over a substrate 9. A second alternating stack of second insulating layers 32 and second sacrificial material layers 42 (which may be a second-tier alternating stack (232, 242), a third-tier alternating stack (332, 342), or a first-tier alternating stack (132, 142)) embedding a second retro-stepped dielectric material portion (which may be a second-tier retro-stepped dielectric material portion 265, a third-tier retro-stepped dielectric material portion 365, or a first-tier retro-stepped dielectric material portion 165) can be formed over the substrate 9. The second alternating stack may overlie or underlie the first alternating stack. For example, the second alternating stack may comprise the second-tier alternating stack (232, 242) which overlies the first alternating stack which comprises the first-tier alternating stack (132, 142).

A first subset of the contact via cavities 85 vertically extends through each layer within the second alternating stack (232, 242), vertically extends through the first retro-stepped dielectric material portion, and vertically extends through a subset of the first sacrificial material layers 42 that underlie the first retro-stepped dielectric material portion. In some embodiments, the second alternating stack (232, 242) is located entirely above a horizontal plane including a topmost surface of the first alternating stack (132, 142). In one embodiment, a semiconductor material layer (which may comprise a substrate 9) may underlie the first alternating stack (132, 142) and the second alternating stack (232, 242). A bottom surface of each of the contact via cavities 85 may be located below a bottommost surface of the first alternating stack (132, 142) and the second alternating stack (232, 242).

In one embodiment, a second subset of the contact via cavities 85 may vertically extend through each layer within the first alternating stack (132, 142), may vertically extend through the second retro-stepped dielectric material portion 265, and may vertically extend through a subset of the second sacrificial material layers 242 that underlie the second retro-stepped dielectric material portion 265. In one embodiment, contact via cavities 85 may be in direct contact with the first retro-stepped dielectric material portion 165 above a horizontal plane including a topmost surface of the first subset of the first sacrificial material layers 142.

In one embodiment, a third alternating stack (32, 42) of third insulating layers 32 and third sacrificial material layers 42 (which may be a third-tier alternating stack (332, 342), a first-tier alternating stack (132, 142), or a second-tier alternating stack (232, 242)) embedding a third retro-stepped dielectric material portion (which may be a third-tier retro-stepped dielectric material portion 365, a first-tier retro-stepped dielectric material portion 165, or a second-tier retro-stepped dielectric material portion 265) may be provided over the substrate 9. The third alternating stack (32, 42) overlies or underlies the first alternating stack (32, 42), and overlies or underlies the second alternating stack (32, 42). For example, the third alternating stack comprises the third-tier alternating stack (332, 342) which overlies the first and second alternating stacks. Each contact via cavities 85 vertically extends through at least one of the third alternating stack (332, 342) and the third retro-stepped dielectric material portion 365. In one embodiment, a subset of the contact via cavities 85 vertically extends through each layer with the third alternating stack (332, 342). In one embodiment, another subset of the contact via cavities 85 vertically extends from a bottommost surface of the third retro-stepped dielectric material portion 365 to a topmost surface of the third retro-stepped dielectric material portion 365. In one embodiment, yet another subset of the contact via cavities 85 vertically extends through the third alternating stack (332, 342) and the third retro-stepped dielectric material portion 365. In one embodiment, the second alternating stack (232, 242) underlies the first alternating stack (332, 342); and the third alternating stack (332, 342) overlies the first alternating stack (332, 342). In one embodiment, the second alternating stack (232, 242) overlies the first alternating stack (132, 142); and the third alternating stack (332, 342) overlies the second alternating stack (232, 242).

If the substrate 9 comprises a semiconductor material such as silicon, an oxidation process may be performed to convert physically exposed surface portions of the substrate 9 underneath the contact via cavities 85 into semiconductor oxide (e.g., silicon oxide) spacer liners 16. The thickness of the semiconductor oxide spacer liners 16 may be in a range from 3 nm to 8 nm, although lesser and greater thicknesses may also be employed. In one embodiment, collateral oxidation of the physically exposed surfaces of the sacrificial material layers 42 may be minimized by reducing the thickness of the semiconductor oxide spacer liners 16.

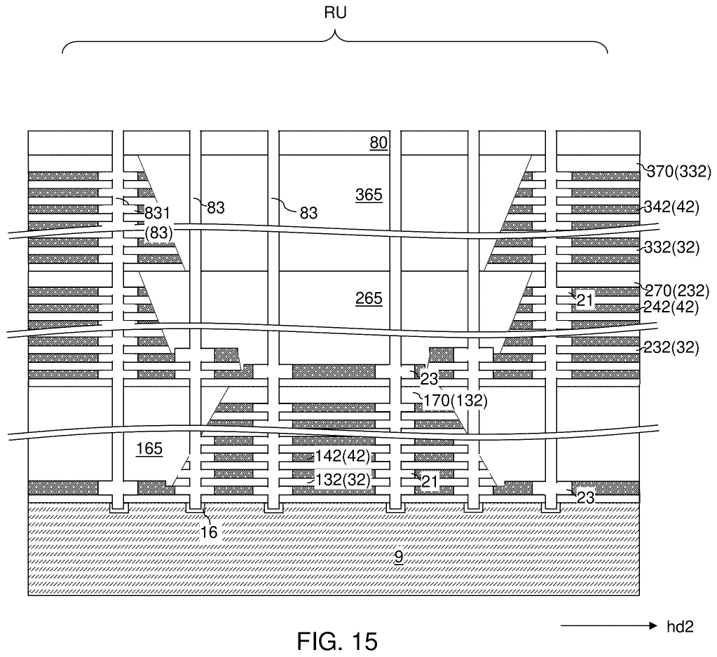

Referring to FIG. 15, a first isotropic etch process can be performed to isotropically etch proximal portions of the sacrificial material layers 42 around each contact via cavity 85 selective to the insulating layers 32 and the retro-stepped dielectric material portions (165, 265, 365). For example, if the sacrificial material layers 42 comprise silicon nitride and if the retro-stepped dielectric material portions (165, 265, 365) comprises silicon oxide, the first isotropic etch process may comprise a wet etch process employing hot phosphoric acid which etches silicon nitride selective to silicon oxide materials. The duration of the first isotropic etch process can be selected such that the lateral recess distance of the first isotropic recess etch process is in a range from 100 % to 1,000 %, such as from 200 % to 500 %, of the thickness of unthickened portions of the sacrificial material layers 42. For each contact via cavity 85 that vertically extends through at least one unthickened portion of the sacrificial material layers 42, at least one first annular recess region 21 may be formed in volumes from which material portions of sacrificial material layers-42 are removed selectively to the insulating layers 32. For each contact via cavity 85, a second annular recess region 23 can be formed by isotropically etching a proximal region of a thickened portion of a respective sacrificial material layer 23 selective to the insulating layers 32. Each contact via cavity 85 is laterally expanded at one or more levels of the sacrificial material layers 42 through formation of the annular recess regions (21, 23), and is converted into a respective laterally-expanded contact via cavity 83.

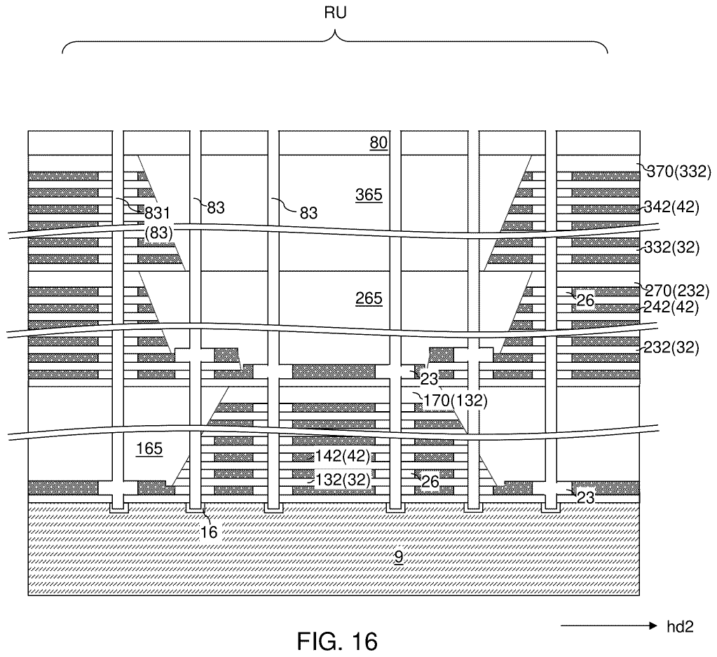

Referring to FIG. 16, a recess-fill dielectric material layer (not shown) can be formed by conformally depositing a recess-fill dielectric material, such as silicon oxide, in the first annular recess regions 21 and the second annular recess regions 23, and over sidewalls of the laterally-expanded contact via cavities 83 (i.e., contact via cavities 85 as laterally expanded by the first isotropic etch process). The thickness of the recess-fill dielectric material layer can be greater than one half of the thickness of the unthickened portions of the sacrificial material layers 42, and can be less than one half of the thickness of the thickened portions of the sacrificial material layers 42. Thus, each first annular recess region 21 is completely filled with the recess-fill dielectric material layer, while each second annular recess region 23 is only partly filled by the recess-fill dielectric material layer.

A second isotropic etch process can be performed to isotropically etch the material of the recess-fill dielectric material layer. For example, the second isotropic etch process may comprise a wet etch process employing dilute hydrofluoric acid, such as 100:1 dilute hydrofluoric acid. According to an aspect of the present disclosure, the duration of the second isotropic etch process can be selected to ensure removal of the entirety of each portion of the recess-fill dielectric material layer that fills the second annular recess regions 23 of the laterally-expanded contact via cavities 83. In one embodiment, the duration of the second isotropic etch process can be selected such that the recess etch distance of the second isotropic etch process for the material of the recess-fill dielectric material layer is in a range from 105 % to 150 %, such as from 100 % to 130 %, of the thickness of the recess-fill dielectric material layer.

The second isotropic etch process removes the recess-fill dielectric material layer from an entire volume of each second annular recess region 23. Thus, the recess-fill dielectric material layer is entirely removed from each second annular recess region 23. Each remaining portion of the recess-fill dielectric material layer that fills a respective one of the first annular recess regions 21 comprises an annular dielectric spacer 26. Thus, each first annular recess region 21 is filled within a respective annular dielectric spacer 26. For each contact via cavity 85 that vertically extends through three or more sacrificial material layers 42, a vertical stack of annular dielectric spacers 26 can be formed around the contact via cavity 85. In other words, for each laterally-expanded contact via cavity 83 that vertically extends through three or more sacrificial material layers 42, a vertical stack of annular dielectric spacers 26 can fill two or more first annular recess regions 21. For each contact via cavity 85 that vertically extends through a plurality of sacrificial material layers 42, each unthickened annular portion of the plurality of sacrificial material layers 42 around the contact via cavity 85 can be replaced with a respective annular dielectric spacer 26. Thus, the annular dielectric spacers 26 are formed within a subset of the annular recess regions (21, 23), i.e., within the first annular recess regions 21.

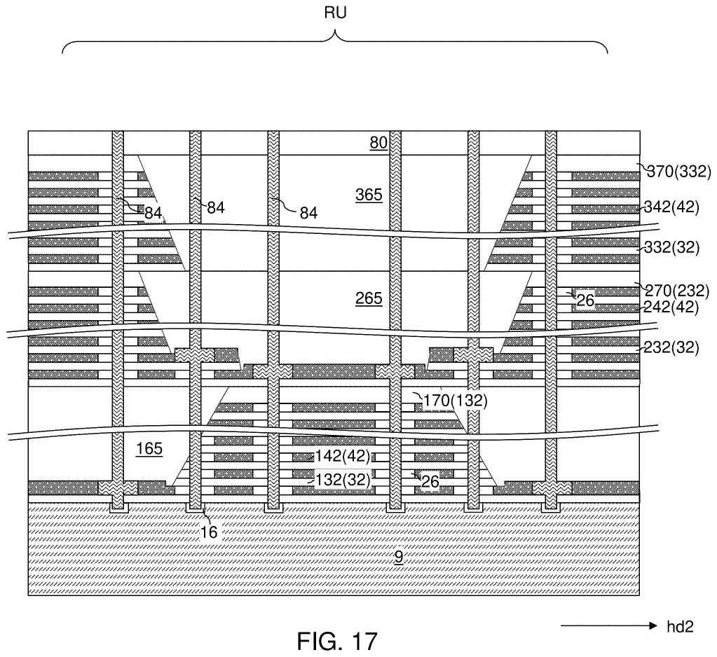

Referring to FIG. 17, a sacrificial fill material can be deposited within volumes of the laterally-expanded contact via cavities 83 that are not filled with the annular dielectric spacers 26. The sacrificial fill material may comprise any material that is different from the materials of the insulating layers 32 and the sacrificial material layers 42. For example, the sacrificial fill material may comprise a semiconductor material (e.g., amorphous silicon), organosilicate glass, a polymer material, a photoresist material, or any other sacrificial material that may be subsequently removed selective to materials of the insulating layers 32, the retro-stepped dielectric material portions (165, 265, 365), and electrically conductive layers to be subsequently formed. Excess portions of the sacrificial fill material may be removed from above the horizontal plane including the top surface of the contact-level dielectric layer 80. Each remaining portion of the sacrificial fill material that fills a respective one of the laterally-expanded contact via cavities 83 constitutes a sacrificial through-via structure 84.

Each sacrificial through-via structure 84 is in direct contact with a cylindrical sidewall of a thickened portion of a respective one of the sacrificial material layers 42, and may optionally vertically extend through one or more additional sacrificial material layers 42. Each sacrificial through-via structure 84 is in contact with at least one of the first-tier retro-stepped dielectric material portion 165, the second-tier retro-stepped dielectric material portion 265, and the third-tier retro-stepped dielectric material portion 365. Each sacrificial through-via structure 84 that vertically extends through at least one opening through at least one unthickened portion of the sacrificial material layers 42 is laterally surrounded by, and is contacted by, one or more of the annular dielectric spacers 26. A subset of the sacrificial through-via structures 84 can be laterally surrounded by a respective set of at least one annular dielectric spacer 26. In one embodiment, a subset of the sacrificial through-via structures 84 can be laterally surrounded by a respective vertical stack of annular dielectric spacers 26.

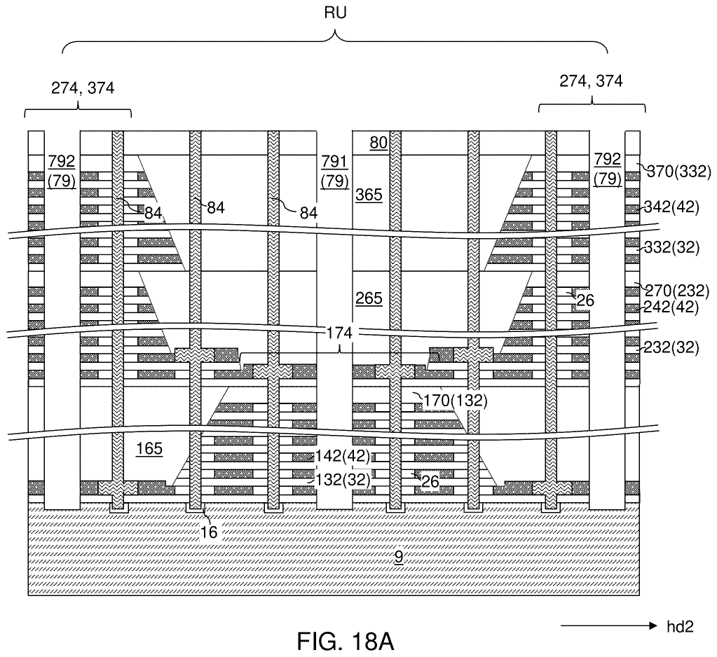

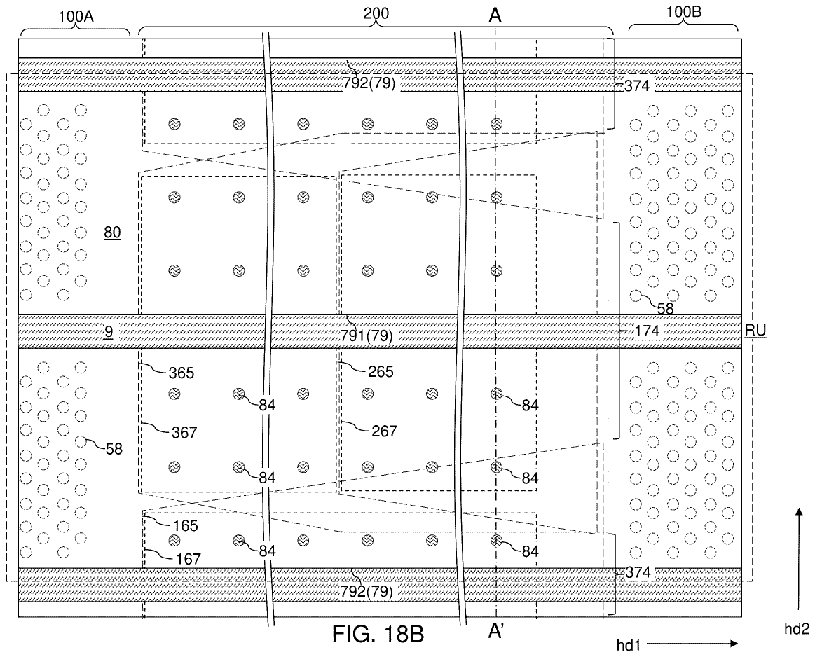

Referring to FIGS. 18A and 18B, a patterning film (not shown) can be anisotropically deposited over the contact-level dielectric layer 80. The patterning film comprises a material that may be subsequently employed as an etch mask material. For example, the patterning film may comprise amorphous carbon or diamond-like carbon. The patterning film can be deposited with a highly directional deposition method, such as plasma-enhanced chemical vapor deposition. The patterning film may be subsequently patterned, for example, by applying and lithographically patterning a photoresist layer (not shown). In one embodiment, elongated openings laterally extending along the first horizontal direction hd1 can be formed in the photoresist layer. In one embodiment, the elongated openings may comprise rectangular openings having a uniform width along the second horizontal direction hd2.

In one embodiment, the elongated openings may comprise a one-dimensional array of elongated openings laterally extending along the first horizontal direction hd1, having a uniform width along the second horizontal direction hd2, and having a uniform pitch along the second horizontal direction hd2 that is one half of the periodicity of the repetition unit RU along the second horizontal direction hd2. In one embodiment, each elongated opening may have a uniform width throughout, and may laterally extend through the entirety of the first memory array region 100A, the second memory array region 100B, and the contact region 200. The photoresist layer may be removed after patterning the patterning film, or may be collaterally removed during a subsequent anisotropic etch process that transfers the pattern in the patterning film through the alternating stacks (32, 42) and the retro-stepped dielectric material portions (165, 265, 365).

An anisotropic etch process can be performed to transfer the pattern of the elongated openings in the patterning film through the contact-level dielectric layer 80, the alternating stacks (32, 42), and the retro-stepped dielectric material portions (165, 265, 365). Lateral isolation trenches 79 can be formed in the volumes from which the materials of the contact-level dielectric layer 80, the alternating stacks (32, 42), and the retro-stepped dielectric material portions (165, 265, 365) are removed. In one embodiment, the lateral isolation trenches 79 may comprise first-type lateral isolation trenches 791 that divide a respective combination of a second-tier retro-stepped dielectric material portion 265 and a third-tier retro-stepped dielectric material portion 365 into a pair of combinations of a respective patterned portion of the second-tier retro-stepped dielectric material portion 265 and a respective patterned portion of the third-tier retro-stepped dielectric material portion 365. The first-type lateral isolation trenches 791 extend through the first bridge regions 174. Further, the lateral isolation trenches 79 may comprise second-type lateral isolation trenches 792 that divide a respective first-tier retro-stepped dielectric material portion 165 into a respective pair of patterned portions of the first-tier retro-stepped dielectric material portion 165. The second-type lateral isolation trenches 792 extend through the second and third bridge regions (274, 374). the patterning film can be subsequently removed, for example, by ashing or selective etching. The lateral isolation trenches 79 are laterally spaced from each of the contact via cavities 85. Optionally, an oxidation process may be performed to convert physically exposed surface portions of the substrate 9 into semiconductor oxide trench liners (not illustrated).

The lateral isolation trenches 79 divide each alternating stack (32, 42) of insulating layers 32 and sacrificial material layers 42 into a respective plurality of alternating stacks (32, 42) of insulating layers 32 and sacrificial material layers 42. For the purpose of distinguishing layers in the first exemplary structure prior to formation of the lateral isolation trenches 79 from layers in the first exemplary structure after formation of the lateral isolation trenches 79, each insulating layer 32 prior to formation of the lateral isolation trenches 79 may be referred to as a continuous insulating layer 32. The continuous insulating layers 32 in the first exemplary structure prior to formation of the lateral isolation trenches 79 may comprise first-tier continuous insulating layers 132, second-tier continuous insulating layers 232, and third-tier continuous insulating layers 332. Likewise, each sacrificial material layer 42 prior to formation of the lateral isolation trenches 79 may be referred to as a continuous sacrificial material layer 42. The continuous sacrificial material layers 42 in the first exemplary structure prior to formation of the lateral isolation trenches 79 may comprise first-tier continuous sacrificial material layers 142, second-tier continuous sacrificial material layers 242, and third-tier continuous sacrificial material layers 342.

Thus, the first-tier alternating stack of first-tier continuous insulating layers 132 and first-tier sacrificial material layers 142 is divided into a plurality of alternating stacks of first-tier insulating layers 132 and first-tier sacrificial material layers 142. The second-tier alternating stack of second-tier continuous insulating layers 232 and second-tier sacrificial material layers 242 is divided into a plurality of alternating stacks of second-tier insulating layers 232 and second-tier sacrificial material layers 242. The third-tier alternating stack of third-tier continuous insulating layers 332 and third-tier sacrificial material layers 342 is divided into a plurality of alternating stacks of third-tier insulating layers 332 and third-tier sacrificial material layers 342.

A vertical stack of a first-tier alternating stack (132, 142), a second-tier alternating stack (232, 242), and a third-tier alternating stack (332, 342) is formed between each neighboring pair of lateral isolation trenches 79. In some cases, the vertical stack may be referred to as an alternating stack of insulating layers 32 and sacrificial material layers 42, in which the distinction among the different tier structures is ignored. Each vertical stack of a first-tier alternating stack (132, 142), a second-tier alternating stack (232, 242), and a third-tier alternating stack (332, 342) embeds a first-tier retro-stepped dielectric material portion 165, a second-tier retro-stepped dielectric material portion 265, and a third-tier retro-stepped dielectric material portion 365. Each first-tier retro-stepped dielectric material portion 165 may comprise a respective lengthwise sidewall that is parallel to the first horizontal direction hd1 and is exposed to a respective first-type lateral isolation trench 791. Each second-tier retro-stepped dielectric material portion 265 may comprise a respective lengthwise sidewall that is parallel to the first horizontal direction hd1 and is exposed to a respective second-type lateral isolation trench 792. Each third-tier retro-stepped dielectric material portion 365 may comprise a respective lengthwise sidewall that is parallel to the first horizontal direction hd1 and is exposed to a respective second-type lateral isolation trench 792.

In one embodiment, the first-tier retro-stepped dielectric material portion 165 is not in direct contact with any other retro-stepped dielectric material portion (165, 265, 365). In one embodiment, each second-tier retro-stepped dielectric material portion 265 contacts a bottom surface of a respective overlying third-tier retro-stepped dielectric material portion 365 and does not contact any other retro-stepped dielectric material portion (165, 265, 365). In one embodiment, each third-tier retro-stepped dielectric material portion 365 contacts a top surface of a respective underling second-tier retro-stepped dielectric material portion 265 and does not contact any other retro-stepped dielectric material portion (165, 265, 365).

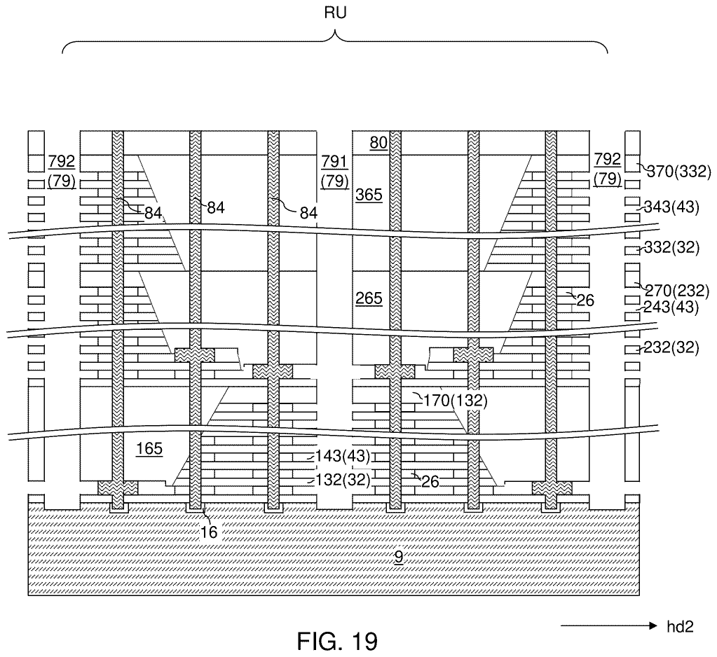

Referring to FIG. 19, laterally-extending cavities 43 can be formed by selective removal of the sacrificial material layers 42. A selective etch process can be performed to remove the sacrificial material layers 42 selectively to the insulating layers 32 employing the lateral isolation trenches 79 as conduits for transporting an isotropic etchant of the selective etch process. Specifically, the sacrificial material layers 42 may be isotropically etched selective to the insulating layers 32, the annular dielectric spacers 26, and the retro-stepped dielectric material portions (165, 265, 365) by supplying an isotropic etchant into the lateral isolation trenches 79 and into the contact via cavities 85. In one embodiment, an etchant that selectively etches the materials of the sacrificial material layers 42 with respect to the materials of the insulating layers 32, the annular dielectric spacers 26, the retro-stepped dielectric material portions (165, 265, 365), and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the annular dielectric spacers 26, the retro-stepped dielectric material portions (165, 265, 365), and the outermost layer of the memory films 50 comprise silicon oxide materials, the etch process may comprise a hot phosphoric acid etch process, which etches silicon nitride selective to silicon oxide, silicon, and various other materials used in the art.

The laterally-extending cavities 43 are formed in volumes from which the sacrificial material layers 42 are removed. The laterally-extending cavities 43 include first-tier laterally-extending cavities 143 that are formed in volumes from which the first-tier sacrificial material layers 142 are removed, second-tier laterally-extending cavities 243 that are formed in volumes from which the second-tier sacrificial material layers 242 are removed, and third-tier laterally-extending cavities 343 that are formed in volumes from which the third-tier sacrificial material layers 342 are removed. Each of the laterally-extending cavities 43 may be a laterally extending cavity having a greater lateral dimension that is greater than a vertical extent. In other words, the lateral dimension of each of the laterally-extending cavities 43 may be greater than the height of the respective laterally-extending cavity. A plurality of laterally-extending cavities 43 may be formed in the volumes from which the material of the sacrificial material layers 42 is removed. Each of the laterally-extending cavities 43 may extend substantially parallel to the top surface of the substrate 9. A laterally-extending cavity 43 may be vertically bounded by a top surface of an underlying insulating layer 32 and a bottom surface of an overlying insulating layer 32.

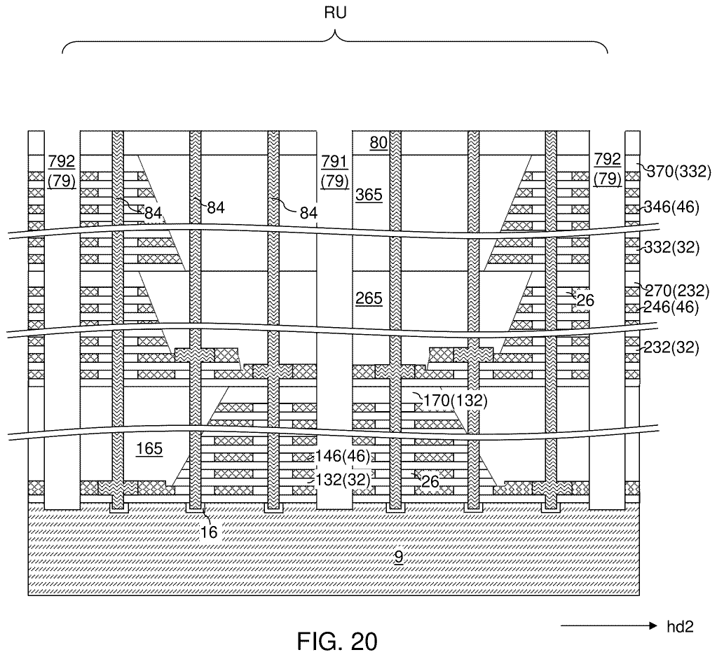

Referring to FIG. 20, an outer blocking dielectric layer (not expressly shown) may be conformally deposited in peripheral portions of the laterally-extending cavities 43, the contact via cavities 85, and the lateral isolation trenches 79. The outer blocking dielectric layer includes a dielectric material, such as a dielectric metal oxide (e.g., aluminum oxide), silicon oxide, or a combination thereof. The outer blocking dielectric layer may be formed as a continuous material layer having a uniform thickness throughout by a conformal deposition process such as an atomic layer deposition process and/or a chemical vapor deposition process. The thickness of the outer blocking dielectric layer may be in a range from 2 nm to 10 nm, such as from 3 nm to 8 nm, although lesser and greater thicknesses may also be employed.

A continuous electrically conductive material layer (not illustrated) may be deposited over the outer blocking dielectric layer to fill remaining volumes of the laterally-extending cavities 43 and peripheral portions of the lateral isolation trenches 79. The lateral isolation trenches 79 are used conduits for transporting the reactants (e.g., CVD or ALD reactants) to the volumes of the laterally-extending cavities 43. In one embodiment, the continuous electrically conductive material layer may comprise a continuous metallic barrier liner layer (not expressly shown) and a continuous metal fill material layer (not expressly shown).

Specifically, a continuous metallic barrier liner layer may be conformally deposited on the physically exposed surfaces of the outer blocking dielectric layer in peripheral portions of the laterally-extending cavities 43 and the lateral isolation trenches 79. The continuous metallic barrier liner layer comprises a metallic diffusion barrier material. For example, the continuous metallic barrier liner layer may comprise and/or may consist essentially of a conductive metal nitride material, such as TiN, TaN, WN, and/or MoN. The continuous metallic barrier liner layer may be formed as a continuous material layer having a uniform thickness throughout by a conformal deposition process such as an atomic layer deposition process and/or a chemical vapor deposition process. The thickness of the continuous metallic barrier liner layer may be in a range from 1.5 nm to 8 nm, such as from 3 nm to 6 nm, although lesser and greater thicknesses may also be employed. In one embodiment, the continuous metallic barrier liner layer extends continuously over the entirety of the outer blocking dielectric layer as a single continuous material layer.

The continuous metal fill material layer may be conformally deposited on the physically exposed surfaces of the continuous metallic barrier liner layer in remaining unfilled volumes of the laterally-extending cavities 43 and in peripheral regions of the lateral isolation trenches 79. The continuous metal fill material layer comprises a metal fill material that provides high electrical conductivity. For example, the continuous metal fill material layer comprises and/or consists essentially of an elemental metal such as W, Co, Ru, Mo, Cu, or a combination thereof. The continuous metal fill material layer may be formed by a conformal deposition process, such as a chemical vapor deposition (CVD) process or an atomic layer deposition (ALD) process. The lateral isolation trenches 79 may be used as conduits for the reactant that deposits the continuous metal fill material layer. In one embodiment, the continuous metal fill material layer extends continuously over the entirety of the continuous metallic barrier liner layer as a single continuous material layer.

The combination of the outer blocking dielectric layer, the continuous metallic barrier liner layer, and the continuous metal fill material layer fill the entirety of the laterally-extending cavities 43, and fill peripheral portions of the lateral isolation trenches 79. Generally, at least one conformal deposition process can be performed after formation of the outer blocking dielectric layer to deposit at least one first electrically conductive material of the electrically conductive material layer in remaining volumes of the laterally-extending cavities 43, and in an elongated tubular regions of each lateral isolation trench 79. Each portion of the continuous electrically conductive material layer that replaces an unthickened portion of the sacrificial material layers 42 may have a first thickness, and each portion of the continuous electrically conductive material layer that replace a thickened portion of the sacrificial material layers 42 may have a second thickness which is greater than the first thickness.

A selective etch process can be performed to etch portions of the continuous electrically conductive material layer from inside the lateral isolation trenches 79. Each remaining portion of the combination of the continuous metallic barrier liner layer and the continuous metal fill material layer that fills a respective laterally-extending cavity 43 constitutes an electrically conductive layer 46. The electrically conductive layers 46 comprise first-tier electrically conductive layers 146 that are formed in the first-tier laterally-extending cavities 143, second-tier electrically conductive layers 246 that are formed in the second-tier laterally-extending cavities 243, and third-tier electrically conductive layers 346 that are formed in the third-tier laterally-extending cavities 343. First-tier alternating stacks (132, 246) of first-tier insulating layers 132 and first-tier electrically conductive layers 146 are formed within the first-tier structure, second-tier alternating stacks (132, 246) of second-tier insulating layers 232 and second-tier electrically conductive layers 246 are formed within the second-tier structure, and third-tier alternating stacks (132, 246) of third-tier insulating layers 332 and third-tier electrically conductive layers 346 are formed within the third-tier structure.

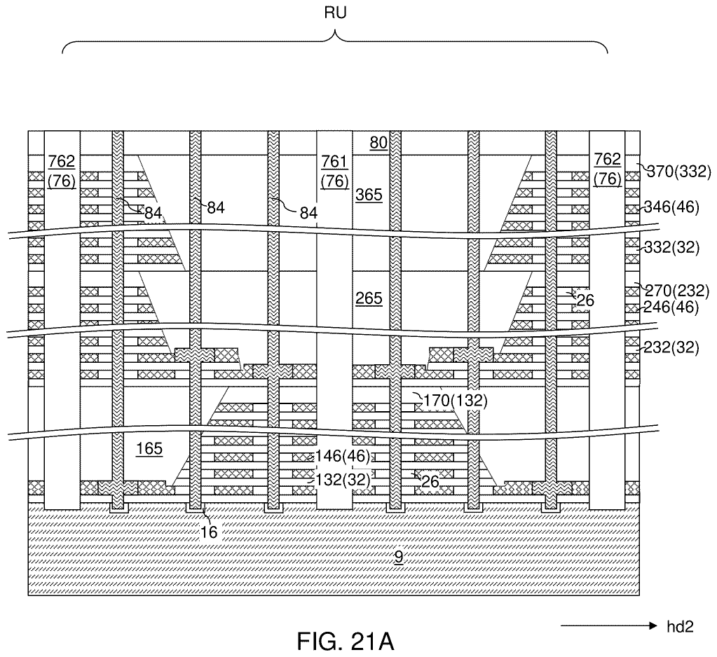

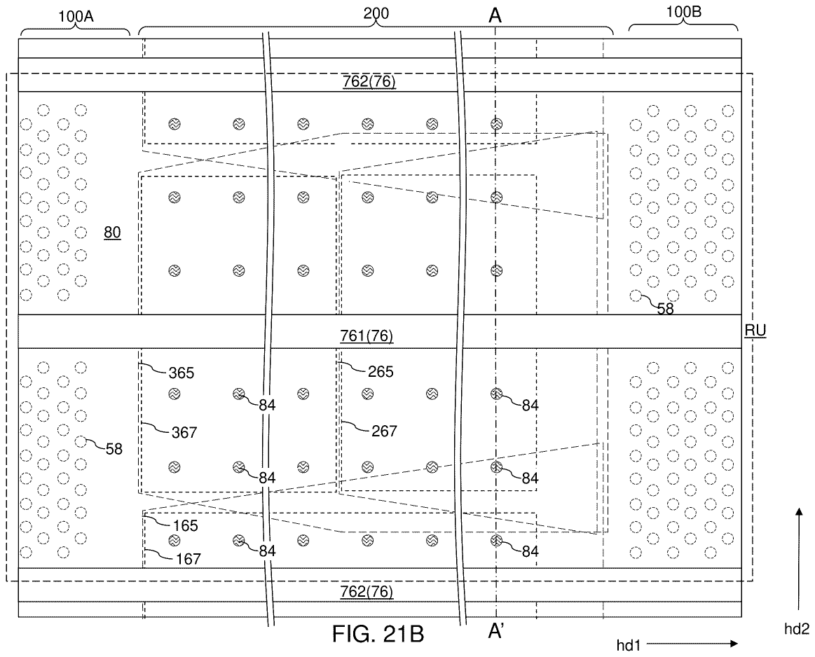

Referring to FIGS. 21A and 21B, a dielectric fill material, such as undoped silicate glass or a doped silicate glass, can be deposited in the lateral isolation trenches 79 by a conformal deposition process. Excess portions of the dielectric fill material may be removed from above the horizontal plane including the top surface of the contact-level dielectric layer 80 by a planarization process, which may comprise a recess etch process and/or a chemical mechanical polishing process. Each remaining portion of the dielectric fill material that fills a respective one of the lateral isolation trenches 79 constitute a lateral isolation trench fill structure 76. The lateral isolation trench fill structures 76 may comprise first-type lateral isolation trench fill structures 761 that are formed in the first-type lateral isolation trenches 791 and second-type lateral isolation trench fill structures 762 that are formed in the second-type lateral isolation trenches 792. The first-type lateral isolation trench fill structures 761 extend through the first bridge regions 174 and the second-type lateral isolation trench fill structures 762 extend through the second and third bridge regions 274 and 374.

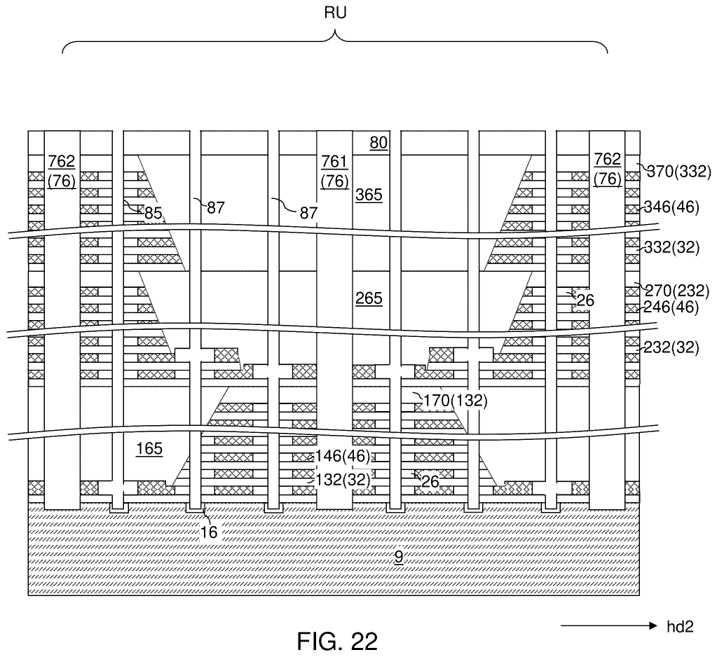

Referring to FIG. 22, a selective etch process may be performed to remove sacrificial through-via structures 84 selective to the materials of the contact-level dielectric layer 80, the retro-stepped dielectric material portions (165, 265, 365), the insulating layers 32, and the electrically conductive layers 46. Through-via cavities 87 can be formed in the volumes from which the sacrificial through-via structures 84 are removed. An isotropic etch process may be performed to remove any physically exposed portion of the outer blocking dielectric layers (not shown) from around the through-via cavities 87. Each through-via cavity 87 is a contact via cavity to which a surface of a respective electrically conductive layer 46 is physically exposed. In one embodiment, each through-via cavity 87 comprises a respective annular recess region to which a cylindrical sidewall of a respective electrically conductive layer 46 is physically exposed.

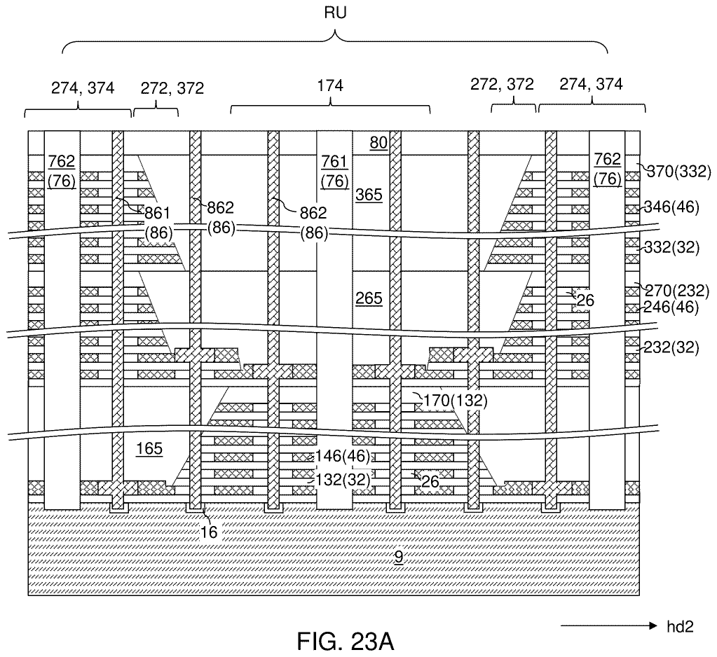

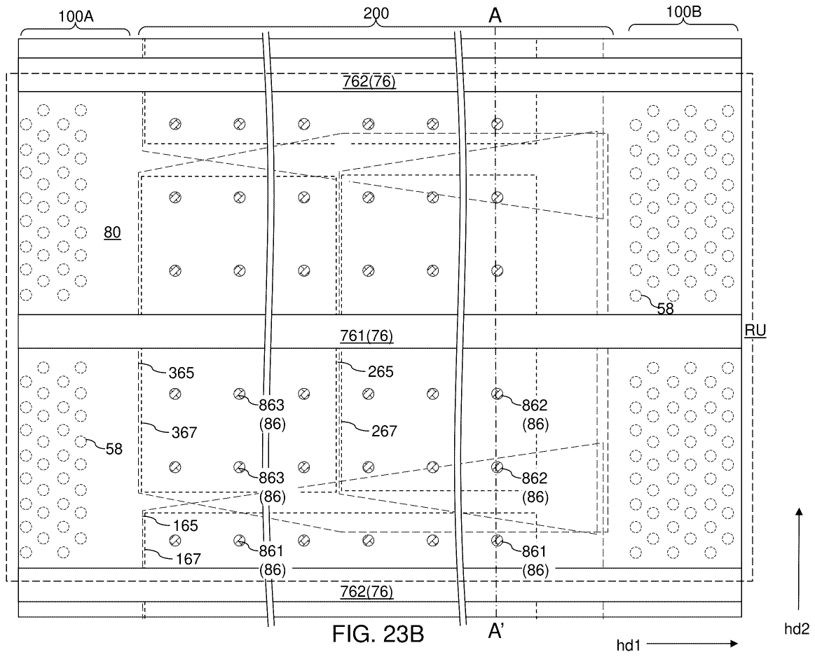

Referring to FIGS. 23A and 23B, at least one electrically conductive material, such as a combination of a metallic barrier liner material and a metal fill material, can be conformally deposited in the through-via cavities 87 directly on physically exposed surface segments of the electrically conductive layers 46. Excess portions of the at least one electrically conductive material may be removed from above the horizontal plane including the top surface of the contact-level dielectric layer 80 by a planarization process, which may comprise a recess etch process and/or a chemical mechanical polishing process. Each remaining portion of the at least one electrically conductive material filling a respective one of the through-via cavities 87 constitute a through-via contact structure 86. The through-via contact structures 86 comprise first-tier-contact through-via contact structures 861 that contact a respective one of the first-tier electrically conductive layers 146, second-tier-contact through-via contact structures 862 that contact a respective one of the second-tier electrically conductive layers 246, and third-tier-contact through-via contact structures 863 that contact a respective one of the third-tier electrically conductive layers 346.

In one embodiment, the first-tier-contact through-via contact structures 861 extend through the second and third bridge regions (274, 374) and the first-tier retro-stepped dielectric material portion 165. The second-tier through-via contact structures 862 extend through the first bridge portion 174 and/or through the first dummy staircase region 172, and through the second and third-tier retro-stepped dielectric material portions (265, 365). The third-tier through-via contact structures 863 extend through the first bridge portion 174 and/or through the first dummy staircase region 172, and through the third-tier retro-stepped dielectric material portion 365.

Each through-via contact structure 86 vertically extends through a respective retro-stepped dielectric material portion (165, 265, or 365) and a set of at least one electrically conductive layer 46 located within a same tier structure as the respective retro-stepped dielectric material portion (165, 265, or 365) and underlies the respective retro-stepped dielectric material portion (165, 265, or 365). Each through-via contact structure 86 is electrically connected to, and is in direct contact with, a topmost electrically conductive layer 46 within the set of at least one electrically conductive layer 46. If the set of at least one electrically conductive layer 46 comprises a plurality of electrically conductive layers 46, the through-via contact structure 86 is laterally spaced from, and is electrically isolated from, each electrically conductive layer 46 within the set except the topmost electrically conductive layer 46 within the set by at least one annular dielectric spacer 26. In case the through-via contact structure 86 vertically extends through any opening in any other electrically conductive layer 46 that overlies the tier structure or underlies the tier structure, the through-via contact structure 86 is laterally spaced from, and is electrically isolated from, any such electrically conductive layer 46 by a respective annular dielectric spacer 26.

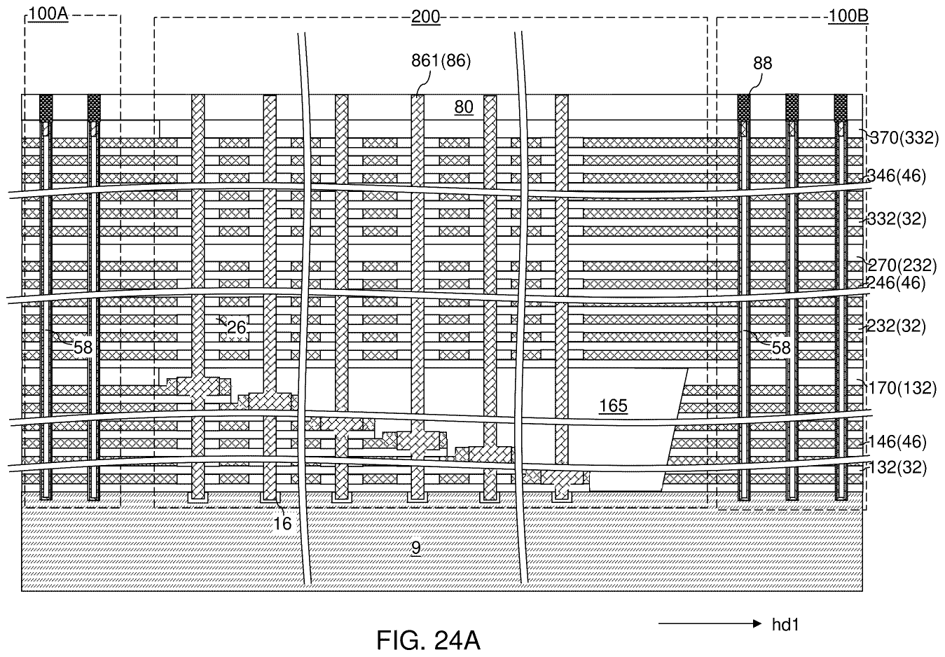

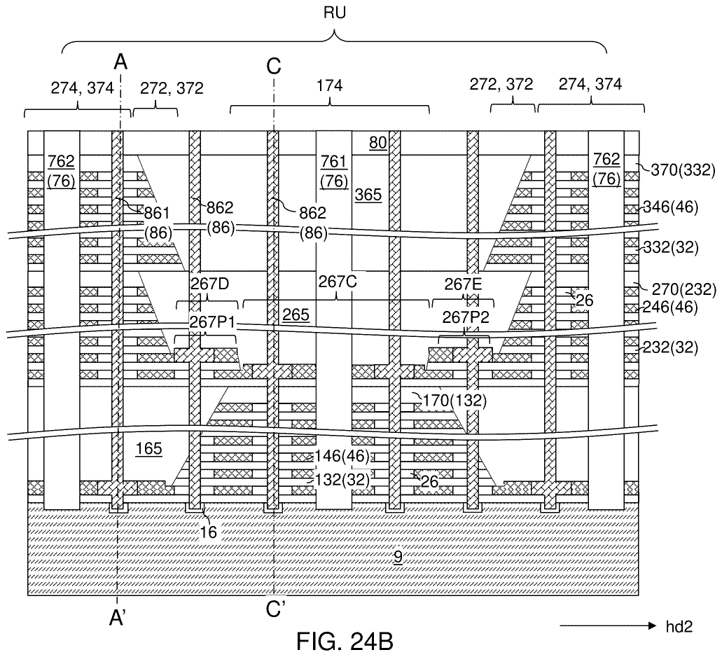

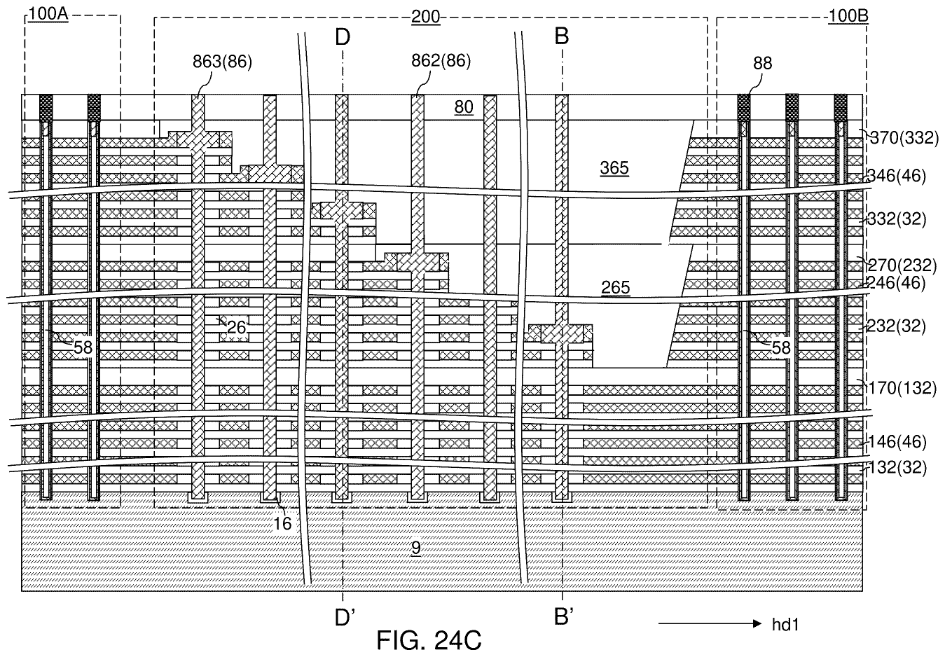

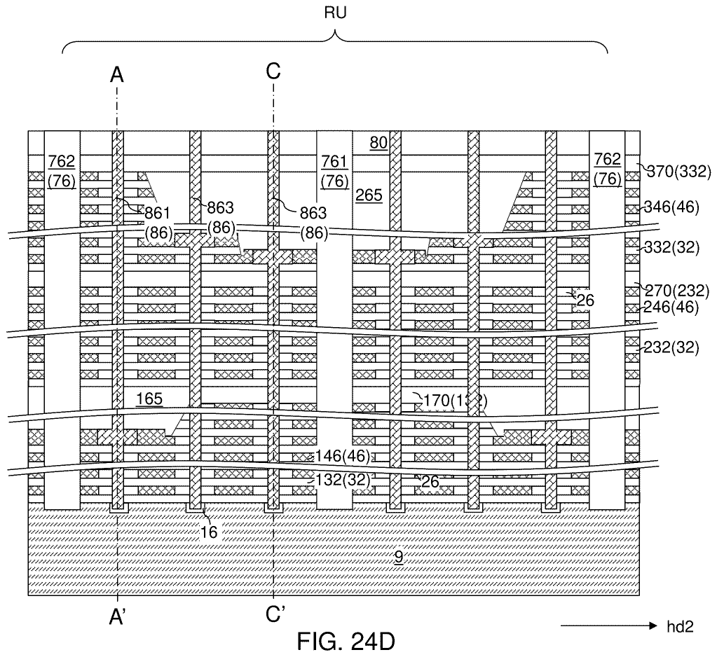

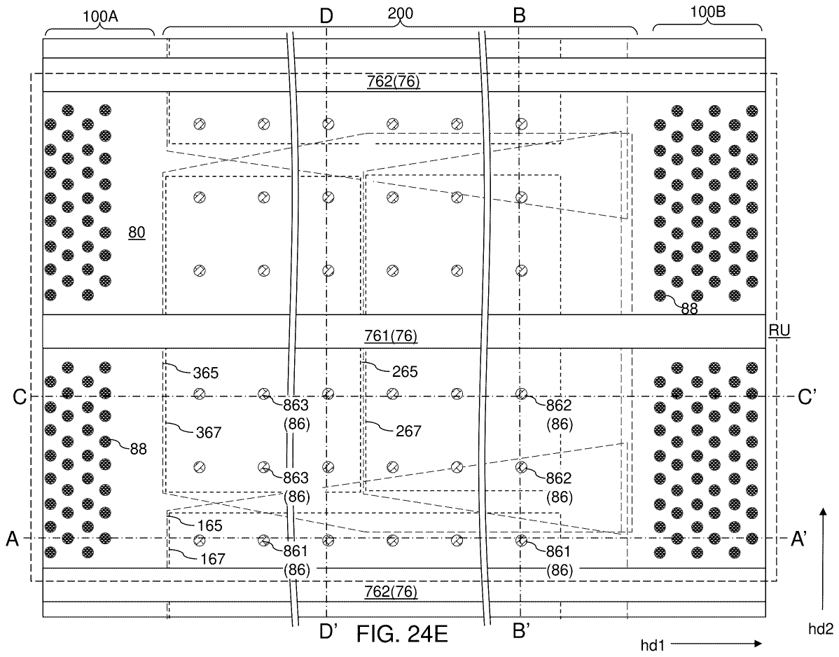

Referring to FIGS. 24A-24E, drain contact via structures 88 can be formed through the contact-level dielectric layer 80 on the drain regions 63 within the memory opening fill structures 58. Each drain region 634 may be contacted by a respective one of the drain contact via structures 88.

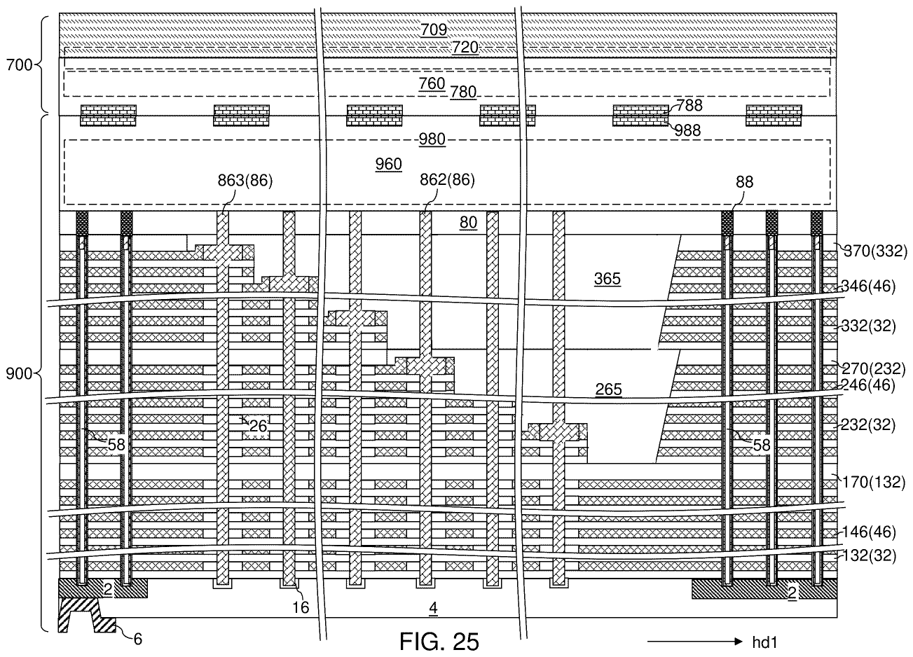

Referring to FIG. 25, additional dielectric material layers can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer of the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

Further, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-die bonding process, or by a die-to-wafer bonding process. The logic-side bonding pads 788 within each logic die 700 can be bonded to the memory-side bonding pads 988 within a respective memory die 900.

The substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selective to dielectric materials of the memory films 50. In an illustrative example, if the substrate 9 comprises silicon, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures (not shown) can be physically exposed upon removal of the substrate 9.

An end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

At least one source structure 2 (e.g., a source region and/or source line) can be formed in contact vertical semiconductor channels 60. The at least one source structure 2 may comprise a heavily doped semiconductor material and/or a metallic material (e.g., a metal and/or an electrically conductive metal nitride or silicide). A backside dielectric layer 4 and backside contact structures 6 can be subsequently formed.

In the embodiment of FIGS. 1-25, the first-tier staircase region 167 laterally overlaps the second-tier staircase region 267 and the third-tier staircase region 367. In other words, the first-tier staircase region 167 is located between two vertical planes which extend along the second horizontal direction hd2 and which are separated from each other along the first horizontal direction hd1. Likewise, the combination of the second-tier staircase region 267 and the third-tier staircase region 367 is located between the same two vertical planes. However, the first-tier staircase region 167 is laterally offset along the second horizontal direction (e.g., bit line direction) hd2 from the second-tier and third-tier staircase regions (267, 367) by width of one memory block. A memory block may comprise an area between adjacent lateral isolation trench fill structures 76 (i.e., between adjacent structures 761 and 762) located in adjacent lateral isolation trenches 79 (i.e., 791 and 792).

The first tier staircase region 167 includes one row of horizontal surface segments (i.e., one row of steps) located below the second-tier and third-tier bridge regions (274, 374). The second-tier staircase region 267 includes three rows of horizontal surface segments (i.e., three row of steps 267P1, 267C, 267P2) located above the first bridge region 174 and/or over the first dummy staircase regions 172. The third-tier staircase region 367 includes three rows of horizontal surface segments (i.e., three row of steps 367P1, 367C, 367P2) located above the first bridge region 174 and/or over the first dummy staircase regions 172. The horizontal surface segments in the first-tier staircase region 167 have length along the first horizontal direction hd1 that is twice as long as the length of horizontal surface segments in the second-tier staircase region 267 and in the third-tier staircase region 367.

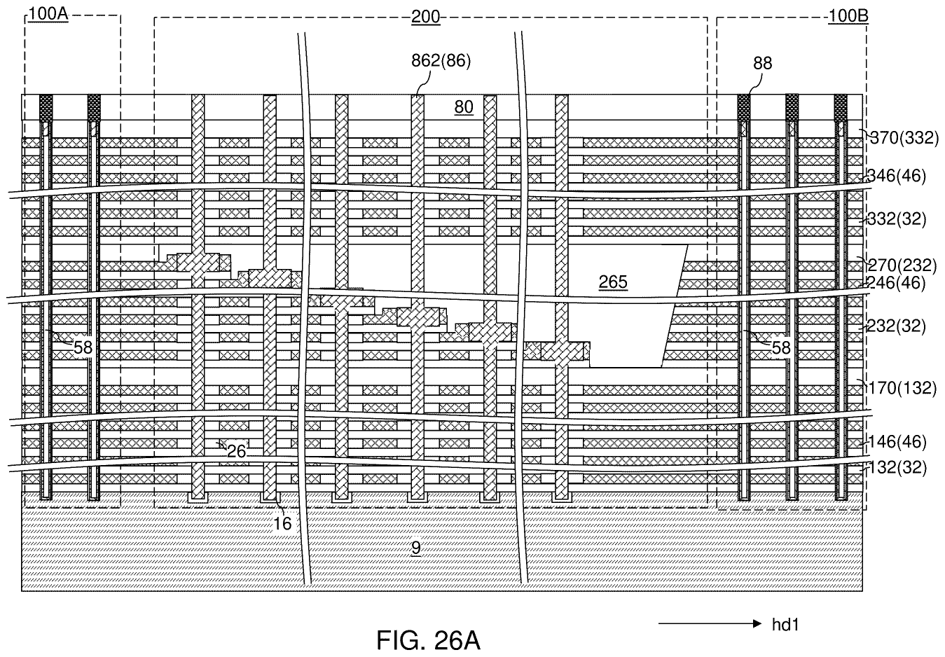

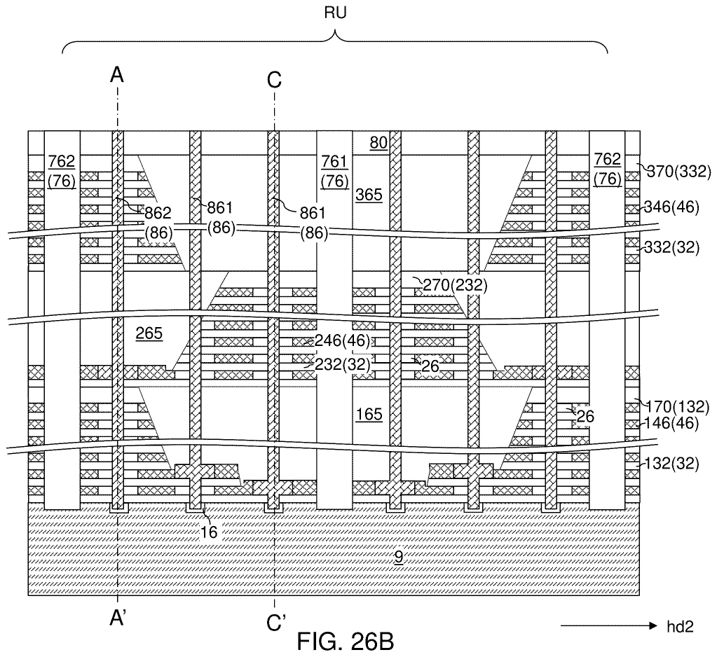

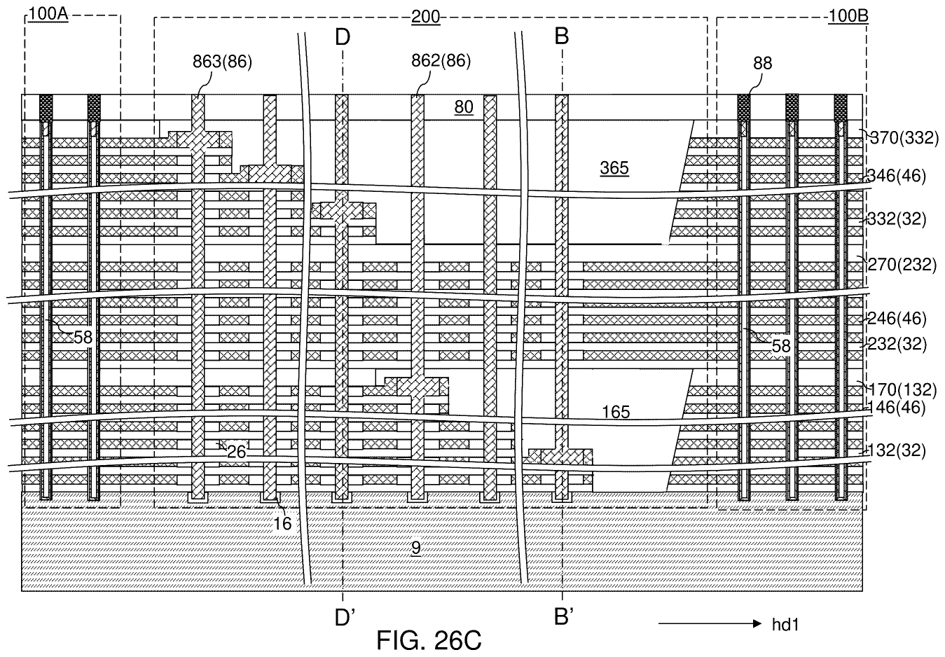

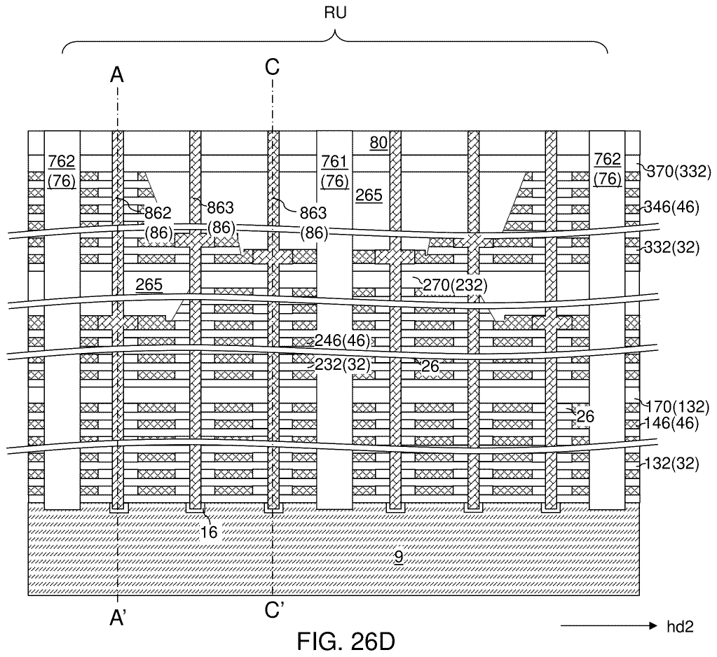

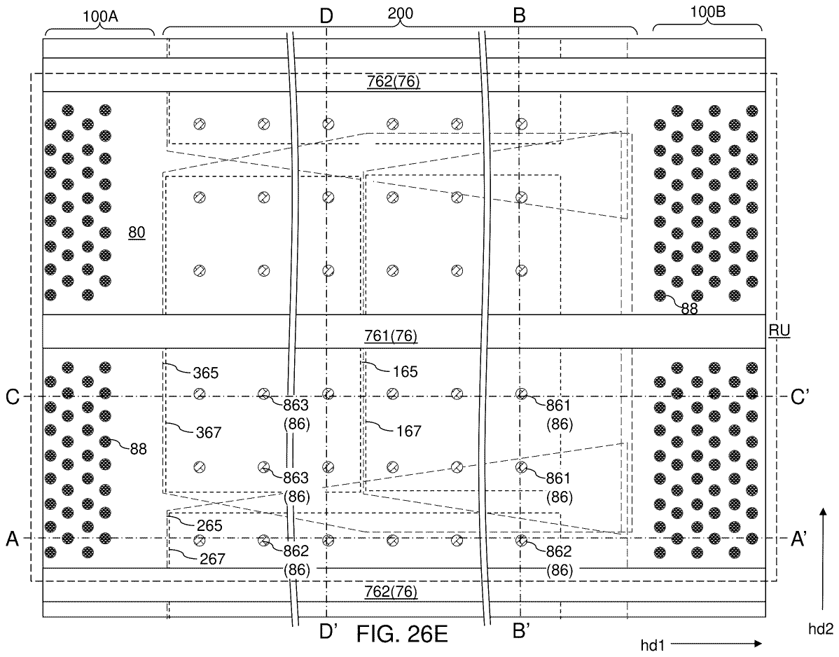

However, in alternative embodiments described below with respect to FIGS. 26A 26E and 27A-27E, the second-tier staircase region 267 may laterally overlap the first-tier staircase region 167 and the third-tier staircase region 367, or the third-tier staircase region 367 may laterally overlap the first-tier staircase region 167 and the second-tier staircase region 267. By forming laterally overlapping staircase regions, the lateral size of the memory device is decreased and device density on the growth substrate 9 is increased.

Generally, the first-tier structure has a first layout for the first-tier stepped surfaces and the first-tier retro-stepped dielectric material portions 165, the second-tier structure has a second layout for the second-tier stepped surfaces and the second-tier retro-stepped dielectric material portions 265, and the third-tier structure has a third layout for the third-tier stepped surfaces and the third-tier retro-stepped dielectric material portions 365. According to an aspect of the present disclosure, the first layout, the second layout, and the third layout may be randomly exchanged to provide alternative sets of layouts for the first-tier structure, the second-tier structure, and the third-tier structure.

FIGS. 26A-26E illustrate a second exemplary structure that may be derived from the first exemplary structure by having the second-tier staircase region 267 laterally overlap the combination of the first-tier staircase region 167 and the third-tier staircase region 267. The second exemplary structure illustrates an example of changing the patterns for the retro-stepped dielectric material portions (165, 265, 365) among the multiple tier structures. The layout for the first-tier stepped surfaces and the first-tier retro-stepped dielectric material portions 165 in the first exemplary structure is employed for the second-tier structure to form second-tier stepped surfaces and the second-tier retro-stepped dielectric material portions 265 in the second exemplary structure. Further, the layout for the second-tier stepped surfaces and the second-tier retro-stepped dielectric material portions 265 in the first exemplary structure is employed for the first-tier structure to form first-tier stepped surfaces and the first-tier retro-stepped dielectric material portions 165 in the second exemplary structure.

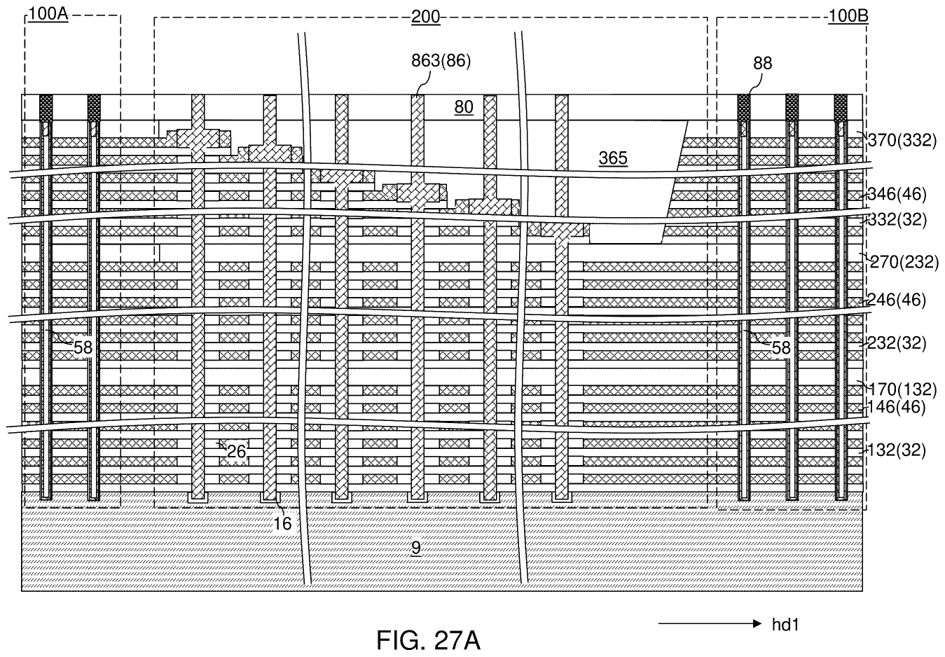

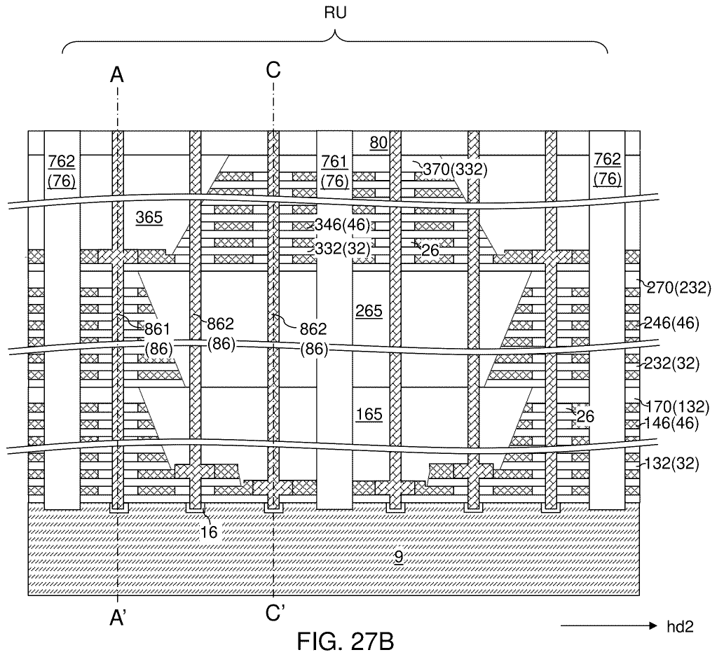

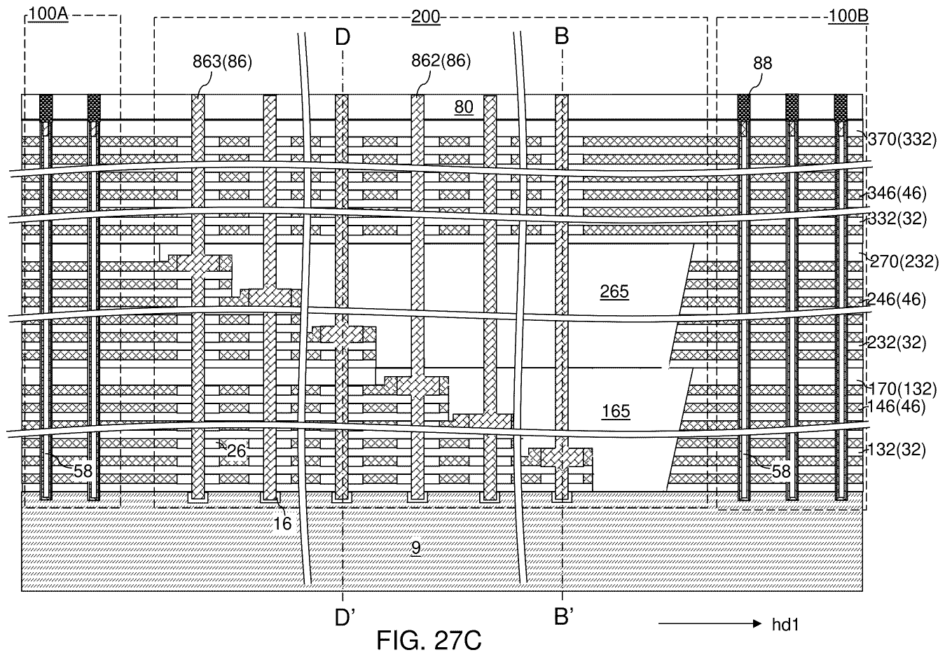

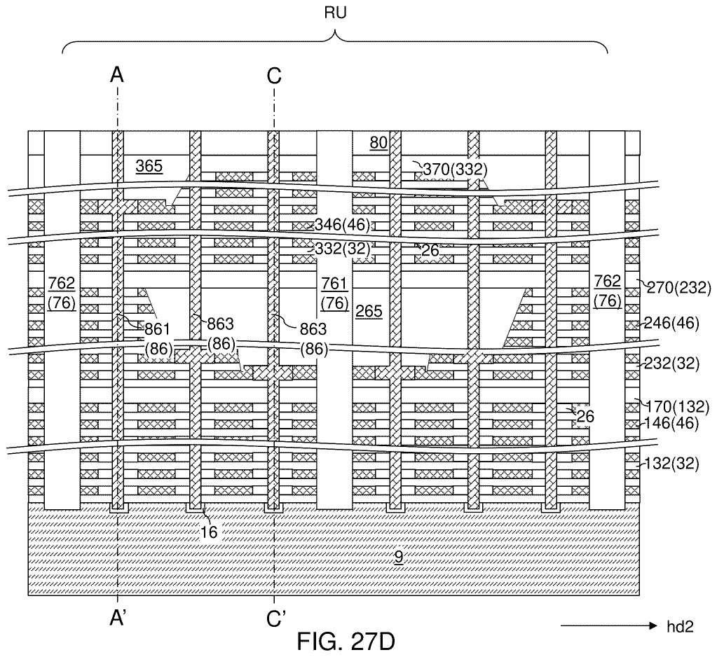

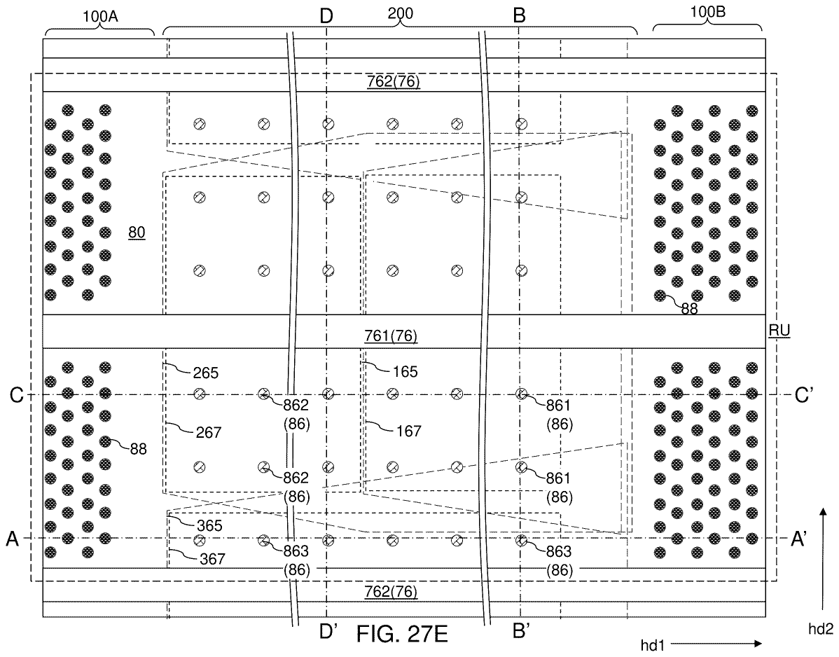

FIGS. 27A-27E illustrate a third exemplary structure that may be derived from the first exemplary structure by having the third-tier staircase region 367 laterally overlap the combination of the first-tier staircase region 167 and the second-tier staircase region 267. The layout for the first-tier stepped surfaces and the first-tier retro-stepped dielectric material portions 165 in the first exemplary structure is employed for the third-tier structure to form third-tier stepped surfaces and the third-tier retro-stepped dielectric material portions 365 in the second exemplary structure. Further, the layout for the second-tier stepped surfaces and the second-tier retro-stepped dielectric material portions 265 in the first exemplary structure is employed for the first-tier structure to form first-tier stepped surfaces and the first-tier retro-stepped dielectric material portions 165 in the third exemplary structure. In addition, the layout for the third-tier stepped surfaces and the third-tier retro-stepped dielectric material portions 365 in the first exemplary structure is employed for the second-tier structure to form second-tier stepped surfaces and the second-tier retro-stepped dielectric material portions 365 in the third exemplary structure.

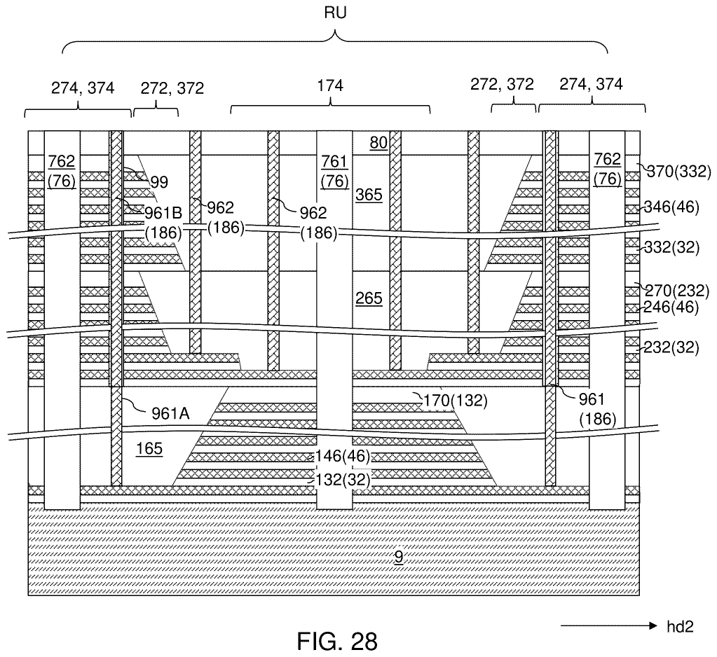

FIG. 28 illustrates a fourth exemplary structure that may be derived from the first exemplary structure shown in FIG. 24B. In the fourth exemplary structure, the through-via contact structures 86 which extend all the way to the growth substrate 9 are replaced with contact via structures 186 which extend down only to a respective electrically conductive layer 46 that they contact. In this embodiment, the first contact via structures 961 which extend to and contact the first-tier electrically conductive layers 146 are formed in two different steps. The lower portions 961A of the first contact via structures 961 are formed prior to formation of the second-tier alternating stack (232, 242). Via cavities are then formed through the second-tier and third-tier alternating stacks {(232, 242)(332, 342)} to expose the lower portions 961A of the first contact via structures 961. A cylindrical dielectric spacer 99 is then formed on the sidewall of the via cavities by deposition of a dielectric layer in the via cavities followed by an anisotropic sidewall spacer etch. The upper portions 961B of the first contact via structures 961 are then formed on the dielectric spacers 99 in the respective via cavities such that they contact the lower portions 961A of the first contact via structures 961. The second contact via structures 962 are also formed in contact with respective second-tier electrically conductive layers 246. Likewise, third contact via structures (not shown) are formed in contact with respective third-tier electrically conductive layers 246.

Referring collectively to all drawings and according to various embodiments of the present disclosure, a device structure comprises a first alternating stack (132, 146) of first insulating layers (132) and first electrically conductive layers (146) comprising a first staircase region 167 comprising a first row of stepped surfaces extending along a first horizontal direction hd1 and comprising first horizontal surface segments separated by first vertical surface segments. The device structure also comprises a second alternating stack (232, 246) of second insulating layers 232 and second electrically conductive layers 246 located over or under the first alternating stack (132, 146), the second alternating stack comprising a pair of second staircase regions 267 that are laterally separated from each other along a second horizontal direction hd2 perpendicular to the first horizontal direction hd1 by a bridge region 274. Each of the second staircase regions 267 comprise a second row of stepped surfaces extending along the first horizontal direction hd1 and comprising second horizontal surface segments separated by second vertical surface segments. First electrically conductive contacts (861, 961) contact the first electrically conductive layers 146 in the first staircase region 167, and second electrically conductive contacts (862, 962) contact the second electrically conductive layers 246 in the second staircase regions 267. The first staircase region 167 laterally overlaps the pair of second staircase regions 267 along the first horizontal direction hd1. The first staircase region 167 is laterally offset from the pair of second staircase regions 267 along the second horizontal direction hd2. The first staircase region 167 is located above or below the bridge region 274 of the second alternating stack (232, 246).

In one embodiment, the device structure comprises a three-dimensional memory device which further comprises memory opening fill structures 58 each comprising a vertical semiconductor channel 60 and a memory film 50 which extend vertically through the first alternating stack and the second alternating stack. The first staircase region 167 is laterally offset from the pair of second staircase regions 267 along the second horizontal direction hd2 by a width of one memory block.

In one embodiment, the first staircase region 167 and the pair of second staircase regions 267 are located between two vertical planes which extend along the second horizontal direction hd2 and which are separated from each other along the first horizontal direction hd1.

In one embodiment, a first retro-stepped dielectric material portion 165 is located over the first staircase region 167, and second retro-stepped dielectric material portions 265 are located over the pair of second staircase regions 267.

In one embodiment shown in FIGS. 7B and 24B, each of the second staircase regions 267 further comprises a third row 267D of stepped surfaces 267P1 extending along the first horizontal direction hd1 and comprising third horizontal surface segments separated by third vertical surface segments, and a fourth row 267E of stepped surfaces 267P2 extending along the first horizontal direction hd1 and comprising fourth horizontal surface segments separated by fourth vertical surface segments. The second row of stepped surfaces 267C is located between the third row 267D and fourth row 267E of stepped surfaces (267P1, 267P2) along the second horizontal direction. The second row of stepped surfaces 267C is vertically offset relative to the third and fourth rows of stepped surfaces (267P1, 267P2) along the second horizontal direction hd2. The second, third and fourth horizontal surface segments are contacted by a respective one of the second electrically conductive contacts (862, 962).

In one embodiment, the first staircase region 167 includes only the first row of stepped surfaces, and a length of the first horizontal surface segments in the first staircase region along first horizontal direction is different (e.g., greater than, such as two time greater) from a length of the second, third and fourth horizontal surface segments in the second staircase region 267 along the first horizontal direction hd1.

In one embodiment, the bridge region 274 of the second alternating stack comprises tapered sidewalls located adjacent to the pair of the second staircase regions, and the tapered sidewalls form dummy staircase regions 272. The first electrically conductive contacts (861, 961) vertically extend through the first retro-stepped dielectric material portion 165 and through at least one of the bridge region 274 or the dummy staircase regions 272 in the second alternating stack (232, 246).

In the fourth embodiment of FIG. 28, a dielectric liner 99 surrounds portions 961B of the first conductive contacts 961 which extend through the at least one of the bridge region 274 or the dummy staircase regions 272 in the second alternating stack.

In the first through third embodiment of FIGS. 1-27E, each of the first conductive contacts 861 comprises a first through-via contact structure 86 that vertically extends through each layer within the second alternating stack (232, 426) and is laterally spaced from each of the second electrically conductive layers 246 by annular dielectric spacers 26, vertically extends through the first retro-stepped dielectric material portion 165, and vertically extending through a subset of the first electrically conductive layers 146 that underlie the first retro-stepped dielectric material portion 164 and electrically connected to a topmost first electrically conductive layer 146 within the subset of the first electrically conductive layers 146.

In various embodiments, the first alternating stack of first insulating layers 32 and first electrically conductive layers 46 may be a first-tier alternating stack (132, 146), a second-tier alternating stack (232, 246), or a third-tier alternating stack (332, 346)). Accordingly, the first retro-stepped dielectric material portion may be a first-tier retro-stepped dielectric material portion 165, a second-tier retro-stepped dielectric material portion 265, or a third-tier retro-stepped dielectric material portion 365). The second alternating stack of second insulating layers 32 and second electrically conductive layers 46 may be a second-tier alternating stack (232, 246), a third-tier alternating stack (332, 346), or a first-tier alternating stack (132, 146). Accordingly, the second retro-stepped dielectric material portion may be a second-tier retro-stepped dielectric material portion 265, a third-tier retro-stepped dielectric material portion 365, or a first-tier retro-stepped dielectric material portion 165. The second alternating stack may overlie or underlie the first alternating stack.

In the first embodiment shown in FIGS. 1-25, the second alternating stack (232, 246) is located above the first alternating stack (132, 146). In one embodiment, the first through-via contact structure 861 is electrically isolated from each first electrically conductive layer 146 within the subset except the topmost first electrically conductive layer 146 by additional annular dielectric spacers 26.

In one embodiment, each of the annular dielectric spacers 26 is located entirety within a recess in a respective one of the second electrically conductive layers 246. In one embodiment, each of the annular dielectric spacers 26 comprises a respective annular top surface contacting a respective overlying one of the second insulating layers 232 and a respective annular bottom surface contacting a respective underlying one of the second insulating layers 232.

In one embodiment, a bottom surface of the first through-via contact structure 86 is located below a bottommost surface of the first alternating stack (132, 146) and the second alternating stack (232, 246).

In the first through third embodiments, each of the second conductive contacts 862 comprises a second through-via contact structure 8 that vertically extends through each layer within the first alternating stack (132, 146), vertically extends through the second retro-stepped dielectric material portion 265, and vertically extending through a subset of the second electrically conductive layers 246 that underlie the second retro-stepped dielectric material portion 265 and electrically connected to a topmost second electrically conductive layer 246 within the subset of the second electrically conductive layers 246. In one embodiment, the second through-via contact structure 862 is laterally spaced from each of the first electrically conductive layers 146 by additional annular dielectric spacers 26. In one embodiment, the second through-via contact structure 862 is laterally spaced from a first subset of the first electrically conductive layers 146 by additional annular dielectric spacers 26, and is in direct contact with the first retro-stepped dielectric material portion 165 above the first subset of the first electrically conductive layers 146.

In one embodiment, the device structure further comprises: a first lateral isolation trench fill structure 761 laterally extending along a first horizontal direction hd1 and contacting a first lengthwise sidewall of the first alternating stack (132, 146), a first lengthwise sidewall of the second alternating stack (232, 246), and the second retro-stepped dielectric material portion 265 and not in direct contact with the first retro-stepped dielectric material portion 165, and a second lateral isolation trench fill structure 762 laterally extending along the first horizontal direction hd1 and contacting a second lengthwise sidewall of the first alternating stack (132, 146), a second lengthwise sidewall of the second alternating stack (232, 246), and the first retro-stepped dielectric material portion 165, and not in direct contact with the second retro-stepped dielectric material portion 265.

In one embodiment, the device structure further comprises a third alternating stack (332, 346) of third insulating layers 332 and third electrically conductive layers 346 that overlies or underlies the first alternating stack (132, 146) and overlies or underlies the second alternating stack (232, 246) and embeds a third retro-stepped dielectric material portion 365, wherein the first through-via contact structure 861 vertically extends through at least one of the third alternating stack (332, 346) and the third retro-stepped dielectric material portion 365.

In various embodiments, the third alternating stack of third insulating layers 32 and third electrically conductive layers 46 may be a third-tier alternating stack (332, 346), a second-tier alternating stack (232, 246), or a first-tier alternating stack (132, 146). Accordingly, the third retro-stepped dielectric material portion may be a third-tier retro-stepped dielectric material portion 365, a second-tier retro-stepped dielectric material portion 265, or a first-tier retro-stepped dielectric material portion 165. The third alternating stack may overlie or underlie the second alternating stack, and may overlie or underlie the first alternating stack.

In one embodiment, the first conductive contact (e.g., the first through-via contact structure 861) vertically extends through each layer with the third alternating stack (332, 346), and is electrically isolated from each of the third electrically conductive layers 346 by additional annular dielectric spacers 26. In one embodiment, the first through-via contact structure 861 vertically extends from a bottommost surface of the third retro-stepped dielectric material portion 365 to a topmost surface of the third retro-stepped dielectric material portion (165, 265, or 365).

In the second embodiment of FIGS. 26A-26E, the second alternating stack may be the first-tier alternating stack (132, 146) that underlies the first alternating stack which comprises a second-tier alternating stack (232, 246); and the third alternating stack may comprise the third-tier alternating stack (332, 346) that overlies the first alternating stack.

In the third embodiment of FIGS. 27A-27E, the second alternating stack may be the second-tier alternating stack (232, 246) that overlies the first alternating stack which comprises the first-tier alternating stack (132, 146); and the third alternating stack comprises the third-tier alternating stack (332, 346) that overlies the second alternating stack.

In one embodiment, a pair of third staircase regions 367 are located in the third alternating stack (332, 346) and are laterally separated from each other along the second horizontal direction hd1 perpendicular to the first horizontal direction by an additional bridge region 374; and third electrically conductive contacts (86, 186) contact the third electrically conductive layers 346 in the third staircase regions 367. In one embodiment, the first staircase region 167 laterally overlaps the pair of third staircase regions 367 along the first horizontal direction hd1; the first staircase region 167 is laterally offset from the pair of third staircase regions 367 along the second horizontal direction hd2; and the first staircase region 167 is located above or below the additional bridge region 374 of the third alternating stack.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
a first alternating stack of first insulating layers and first electrically conductive layers comprising a first staircase region comprising a first row of stepped surfaces extending along a first horizontal direction and comprising first horizontal surface segments separated by first vertical surface segments;
a second alternating stack of second insulating layers and second electrically conductive layers located over or under the first alternating stack, the second alternating stack comprising a pair of second staircase regions that are laterally separated from each other along a second horizontal direction perpendicular to the first horizontal direction by a bridge region, wherein each of the second staircase regions comprise a second row of stepped surfaces extending along the first horizontal direction and comprising second horizontal surface segments separated by second vertical surface segments;
first electrically conductive contacts contacting the first electrically conductive layers in the first staircase region; and
second electrically conductive contacts contacting the second electrically conductive layers in the second staircase regions,
wherein:
the first staircase region laterally overlaps the pair of second staircase regions along the first horizontal direction;
the first staircase region is laterally offset from the pair of second staircase regions along the second horizontal direction; and
the first staircase region is located above or below the bridge region of the second alternating stack.

2. The device structure of claim 1, further comprising memory opening fill structures each comprising a vertical semiconductor channel and a memory film which extend vertically through the first alternating stack and the second alternating stack, wherein the first staircase region is laterally offset from the pair of second staircase regions along the second horizontal direction by a width of one memory block.

3. The device structure of claim 1, wherein the first staircase region and the pair of second staircase regions are located between two vertical planes which extend along the second horizontal direction and which are separated from each other along the first horizontal direction.

4. The device structure of claim 1, further comprising:
a first retro-stepped dielectric material portion located over the first staircase region; and
second retro-stepped dielectric material portions located over the pair of second staircase regions.

5. The device structure of claim 4, wherein:
each of the second staircase regions further comprises a third row of stepped surfaces extending along the first horizontal direction and comprising third horizontal surface segments separated by third vertical surface segments, and a fourth row of stepped surfaces extending along the first horizontal direction and comprising fourth horizontal surface segments separated by fourth vertical surface segments;
the second row of stepped surfaces is located between the third and fourth rows of stepped surfaces along the second horizontal direction;
the second row of stepped surfaces is vertically offset relative to the third and fourth rows of stepped surfaces along the second horizontal direction; and
the second, third and fourth horizontal surface segments are contacted by a respective one of the second electrically conductive contacts.

6. The device structure of claim 5, wherein:
the first staircase region includes only the first row of stepped surfaces; and
a length of the first horizontal surface segments in the first staircase region along first horizontal direction is different from a length of the second, third and fourth horizontal surface segments in the second staircase region along the first horizontal direction.

7. The device structure of claim 5, wherein:
the bridge region of the second alternating stack comprises tapered sidewalls located adjacent to the pair of the second staircase regions, and the tapered sidewalls form dummy staircase regions; and
the first electrically conductive contacts vertically extend through the first retro-stepped dielectric material portion and through at least one of the bridge region or the dummy staircase regions in the second alternating stack.

8. The device structure of claim 7, wherein a dielectric liner surrounds portions of the first conductive contacts which extend through the at least one of the bridge region or the dummy staircase regions in the second alternating stack.

9. The device structure of claim 4, wherein each of the first conductive contacts comprises a first through-via contact structure that:
vertically extends through each layer within the second alternating stack;
is laterally spaced from each of the second electrically conductive layers by annular dielectric spacers;
vertically extends through the first retro-stepped dielectric material portion;
vertically extends through a subset of the first electrically conductive layers that underlie the first retro-stepped dielectric material portion; and
is electrically connected to a topmost first electrically conductive layer within the subset of the first electrically conductive layers.

10. The device structure of claim 9, wherein:
the second alternating stack is located above the first alternating stack;
the first through-via contact structure is electrically isolated from each first electrically conductive layer within the subset except the topmost first electrically conductive layer by additional annular dielectric spacers;
each of the annular dielectric spacers is located entirety within a recess in a respective one of the second electrically conductive layers;
each of the annular dielectric spacers comprises a respective annular top surface contacting a respective overlying one of the second insulating layers and a respective annular bottom surface contacting a respective underlying one of the second insulating layers; and
a bottom surface of the first through-via contact structure is located below a bottommost surface of the first alternating stack and the second alternating stack.

11. The device structure of claim 10, each of the second conductive contacts comprises a second through-via contact structure that:
vertically extends through each layer within the first alternating stack;
vertically extends through the second retro-stepped dielectric material portion;
vertically extends through a subset of the second electrically conductive layers that underlie the second retro-stepped dielectric material portion; and
is electrically connected to a topmost second electrically conductive layer within the subset of the second electrically conductive layers.

12. The device structure of claim 11, wherein:
the second through-via contact structure is laterally spaced from each of the first electrically conductive layers by additional annular dielectric spacers;
the second through-via contact structure is laterally spaced from a first subset of the first electrically conductive layers by additional annular dielectric spacers, and is in direct contact with the first retro-stepped dielectric material portion above the first subset of the first electrically conductive layers.

13. The device structure of claim 1, further comprising:
a first lateral isolation trench fill structure laterally extending along a first horizontal direction and contacting a first lengthwise sidewall of the first alternating stack, a first lengthwise sidewall of the second alternating stack, and the second retro-stepped dielectric material portion and not in direct contact with the first retro-stepped dielectric material portion; and
a second lateral isolation trench fill structure laterally extending along the first horizontal direction and contacting a second lengthwise sidewall of the first alternating stack, a second lengthwise sidewall of the second alternating stack, and the first retro-stepped dielectric material portion and not in direct contact with the second retro-stepped dielectric material portion.

14. The device structure of claim 1, further comprising a third alternating stack of third insulating layers and third electrically conductive layers that overlies or underlies the first alternating stack and overlies or underlies the second alternating stack, wherein the first conductive contacts vertically extend through at least one of the third alternating stack and the third retro-stepped dielectric material portion.

15. The device structure of claim 14, wherein:
the second alternating stack underlies the first alternating stack; and
the third alternating stack overlies the first alternating stack.

16. The device structure of claim 14, wherein:
the second alternating stack overlies the first alternating stack; and
the third alternating stack overlies the second alternating stack.

17. The device structure of claim 14, further comprising:
a pair of third staircase regions are located in the third alternating stack and are laterally separated from each other along the second horizontal direction perpendicular to the first horizontal direction by an additional bridge region; and
third electrically conductive contacts contacting the third electrically conductive layers in the pair of third staircase regions.

18. The device structure of claim 17, wherein:
the first staircase region laterally overlaps the pair of third staircase regions along the first horizontal direction;
the first staircase region is laterally offset from the pair of third staircase regions along the second horizontal direction; and
the first staircase region is located above or below the additional bridge region of the third alternating stack.

19. A method of forming a device structure, comprising:
forming a first-tier structure including a first-tier alternating stack of first-tier insulating layers and first-tier sacrificial material layers embedding a first-tier retro-stepped dielectric material portion;
forming a second-tier structure including a second-tier alternating stack of second-tier insulating layers and second-tier sacrificial material layers embedding a second-tier retro-stepped dielectric material portion;
forming a first sacrificial through-via structure through the second-tier alternating stack and through the first-tier retro-stepped dielectric material portion and through a subset of the first-tier sacrificial material layers;
forming a second sacrificial through-via structure through the first-tier alternating stack and through the second-tier retro-stepped dielectric material portion and through a subset of the second-tier sacrificial material layers;
replacing the first-tier sacrificial material layers and the second-tier sacrificial material layers with first-tier electrically conductive layers and second-tier electrically conductive layers, respectively; and
replacing the first sacrificial through-via structure and the second sacrificial through-via structure with a first through-via contact structure and a second through-via contact structure, respectively, wherein the first through-via contact structure is electrically connected to a first electrically conductive layer that replaces a topmost first-tier sacrificial material layer within the subset of the first-tier sacrificial material layers, and the second through-via contact structure is electrically connected to a second electrically conductive layer that replaces a topmost second-tier sacrificial material layer within the subset of the second-tier sacrificial material layers.

20. The method of claim 19, further comprising:
forming contact via cavities vertically extending through the second-tier structure and the first-tier via structure;
laterally recessing the first-tier sacrificial material layers and the second-tier sacrificial material layers selectively to materials of the first-tier insulating layers, the second-tier insulating layers, the first-tier retro-stepped dielectric material portion, and the second-tier retro-stepped dielectric material portion around the contact via cavities, to form laterally-expanded contact via cavities comprising annular recess regions;
forming annular dielectric spacers within a subset of the annular recess regions, wherein the first sacrificial through-via structure and the second sacrificial through-via structure are formed within volumes of the laterally-expanded contact via cavities that are not filled with the annular dielectric spacers; and
forming a dielectric liner that surrounds portions of the first through-via contact structure.
